(19) United States
(12) Patent Application Publication
(10) Pub. No.: US 2026/0035589 A1
(43) Pub. Date: Feb. 5, 2026

(54) METHOD FOR MANUFACTURING NON-CHEMICALLY AMPLIFIED RESIST COMPOSITION AND PATTERNING PROCESS

(71) Applicant: SHIN-ETSU CHEMICAL CO., LTD., Tokyo (JP)

(72) Inventors: Satoshi KUSAMA, Joetsu-shi (JP); Shun Kikuchi, Joetsu-shi (JP); Kousuke Ohyama, Joetsu-shi (JP); Ryo Nishikawa, Joetsu-shi (JP); Masaki Ohashi, Joetsu-shi (JP)

(73) Assignee: SHIN-ETSU CHEMICAL CO., LTD., Tokyo (JP)

(21) Appl. No.: 19/269,117

(22) Filed: Jul. 15, 2025

(30) Foreign Application Priority Data
Jul. 30, 2024 (JP) 2024-123132

(51) Int. Cl. C09D 133/02; G03F 7/00; G03F 7/004; G03F 7/038; G03F 7/039

(52) U.S. Cl. CPC C09D 133/02; G03F 7/0045; G03F 7/0046; G03F 7/0388; G03F 7/039; G03F 7/70033; G03F 7/70383

(57) ABSTRACT

The present invention is a method for manufacturing a non-chemically amplified resist composition, including, in the following order, the steps of: (i) placing a carboxy-group-containing polymer, a hypervalent iodine compound, and a solvent in a container and mixing together to prepare a fundamental resist composition; (ii) collecting part of the fundamental resist composition, forming a resist film on a test substrate by using the collected fundamental resist composition, and evaluating a film physical property of the resist film; and (iii) adding an additional material to the fundamental resist composition and mixing together to achieve a target film physical property based on an evaluation result of the step (ii). This can provide: a method for manufacturing a non-chemically amplified resist composition whose quality is controlled to be constant; and a patterning process.

### TECHNICAL FIELD

The present invention relates to: a method for manufacturing a non-chemically amplified resist composition; and a patterning process.

### BACKGROUND ART

While a higher integration density, higher operating speed and lower power consumption of LSIs are demanded to comply with the expanding IOT market, the effort to reduce the pattern rule is in rapid progress. In particular, logic devices drive forward the miniaturization technology. As the advanced miniaturization technology, devices of 10-nm node are manufactured in a mass scale by the double, triple or quadro-patterning version of the immersion ArF lithography. Furthermore, the experimental mass-scale manufacture of 7-nm node devices by the next-generation extreme ultraviolet ray (EUV) lithography of wavelength 13.5 nm has started.

As miniaturization advances, image blurs due to acid diffusion are regarded as a problem (Non Patent Document 1). In order to ensure resolution for fine patterns with a post-45 nm size, it is suggested that not only the enhancement of dissolution contrast, which has been proposed previously, but also the controlling of acid diffusion is important (Non Patent Document 2). In chemically amplified resist compositions, however, the sensitivity and the contrast are enhanced by acid diffusion. Accordingly, an attempt to minimize acid diffusion by lowering the temperature of post-exposure baking (PEB) and shortening the PEB time lowers the sensitivity and contrast markedly.

It is effective to control the acid diffusion by adding an acid generator that generates a bulky acid. Accordingly, it has been proposed to copolymerize a polymer with an acid generator in the form of an onium salt having polymerizable olefin. In post-16 nm size patterning of resist films, however, it is considered that patterning is impossible with chemically amplified resist compositions in view of the acid diffusion. Accordingly, development of a non-chemically amplified resist composition is desired.

Examples of materials for a non-chemically amplified resist composition include polymethyl methacrylate (PMMA). PMMA is a positive resist material whose solubility in an organic solvent developer increases due to decreased molecular weight caused by scission of the main chain by EUV irradiation.

Hydrogensilsesquioxane (HSQ) is a negative resist material which turns insoluble in an alkaline developer through crosslinking by condensation reaction of silanol generated by EUV irradiation. Calixarene substituted with chlorine also functions as a negative resist material. These negative resist materials have a small molecular size prior to crosslinking and are free from causing blurs due to acid diffusion, and therefore, exhibit smaller edge roughness and very high resolution. Accordingly, the materials have been used as a pattern transfer material to show the resolution limit of the exposure apparatus. These materials, however, are insufficient in sensitivity, and further improvement is required.

The number of photons in EUV exposure being small is a factor that causes difficulties in developing materials for EUV lithography. The energy of EUV is much higher than that of an ArF excimer laser beam, and the number of photons in EUV exposure is 1/14 of that of ArF exposure. Furthermore, the size of the pattern formed by EUV exposure is half of that in ArF exposure or less. Therefore, EUV exposure is easily affected by variation in the number of photons. The variation in the number of photons in a radiation light region of extremely short wavelengths is the physical phenomenon of shot noise, and it is impossible to eliminate the influence of the variation. Therefore, so-called probability theory (stochastics) is attracting attention. The influence of shot noise cannot be eliminated, but there is discussion of how to reduce this influence. Due to the influence of shot noise, not only are critical dimension uniformity (CDU) and line width roughness (LWR) increased, a phenomenon that a hole gets blocked at a probability of one to several millions is observed. If a hole gets blocked, conduction failure occurs and the transistor does not function, and the performance of the entire device is adversely affected. Considering sensitivity in practical terms, resist compositions that mainly contain PMMA or HSQ are greatly affected by stochastics, and cannot achieve the desired resolution performance.

In view of such circumstances, the introduction of an element that greatly absorbs EUV light is attracting attention as a means for reducing the influence of shot noise on the side of the resist. Patent Document 1 proposes a non-chemically amplified resist composition containing a tin compound. This composition mainly contains the element tin, which greatly absorbs EUV light, and therefore, stochastics is improved, and high sensitivity and high resolution can be realized.

When a non-chemically amplified resist composition is prepared, materials for a resist composition, including the above-described main material, are dissolved in a solvent to obtain a coating solution, and furthermore, micro-filtering for removing particles is performed as necessary, and thus, the resist composition is completed. In this preparation of the resist composition, materials whose purity has been tested are used, and materials whose mass has been precisely weighed are added. However, due to the slight difference in the purity of the used materials or the difference in the atmosphere during production, the prepared non-chemically amplified resist compositions are finished to have slightly different qualities depending on the product lot in some cases. However, it is not favorable for a product always to require a quality test before use when a resist composition is used, and it is desirable for the quality to be controlled to be constant at the point when the resist composition is completed as a product.

In the case of a chemically amplified resist, a resist composition is constituted by multiple functional components, such as a resin whose solubility is altered by the action of an acid, an acid generator, and a quencher, and therefore, as proposed in Patent Document 2, the quality can be adjusted by adjusting the mixing ratios of the functional components, and the quality can be controlled to be constant. On the other hand, a non-chemically amplified resist composition, exemplified by Patent Document 1, is usually constituted by only a single functional component and a solvent, and therefore, such adjustment of quality cannot be performed.

### CITATION LIST

### Patent Literature

Patent Document 1: JP2021-503482A

Patent Document 2: WO2021/172172A1

### Non Patent Literature

Non Patent Document 1: SPIE Vol. 5039 p 1 (2003)

Non Patent Document 2: SPIE Vol. 6520 p 65203L-1 (2007)

### SUMMARY OF INVENTION

### Technical Problem

The present invention has been made in view of the above-described circumstances, and an object thereof is to provide: a method for manufacturing a non-chemically amplified resist composition whose quality is controlled to be constant; and a patterning process.

### Solution to Problem

To achieve the object, the present invention provides a method for manufacturing a non-chemically amplified resist composition, comprising, in the following order, the steps of:
(i) placing a carboxy-group-containing polymer, a hypervalent iodine compound, and a solvent in a container and mixing together to prepare a fundamental resist composition;
(ii) collecting part of the fundamental resist composition, forming a resist film on a test substrate by using the collected fundamental resist composition, and evaluating a film physical property of the resist film; and
(iii) adding an additional material to the fundamental resist composition and mixing together to achieve a target film physical property based on an evaluation result of the step (ii).

According to such a method for manufacturing a non-chemically amplified resist composition, it is possible to manufacture a non-chemically amplified resist composition whose quality is controlled to be constant.

In the present invention, the film physical property is preferably sensitivity.

In the present invention, such a film physical property can be used as an evaluation item.

In the present invention, the additional material is preferably at least one of the carboxy-group-containing polymer, the hypervalent iodine compound, and the solvent.

Such additional materials are preferable, since the quality of the non-chemically amplified resist composition can be easily controlled to be constant.

In the present invention, the hypervalent iodine compound preferably includes at least one of compounds represented by the following general formulae (1) and (2),

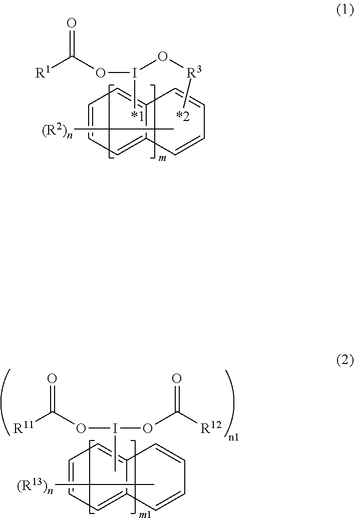

wherein “m” and “ml” each represent an integer of 0 to 2;
“n” represents an integer of 0 to 4 when “m” is 0, an integer of 0 to 6 when “m” is 1, and an integer of 0 to 8 when “m” is 2;
when “m1” is 0, “n1” represents an integer of 1 to 3, “n2” represents an integer of 0 to 5, and 1≤(n1+n2)≤6 is satisfied;
when “m1” is 1, “n1” represents an integer of 1 to 3, “n2” represents an integer of 0 to 7, and 1≤(n1+n2)≤8 is satisfied;
when “ml” is 2, “n1” represents an integer of 1 to 3, “n2” represents an integer of 0 to 9, and 1≤(n1+n2)≤10 is satisfied;
R¹ represents a halogen atom or a hydrocarbyl group having 1 to 10 carbon atoms and optionally containing a heteroatom;
R² represents a halogen atom or a hydrocarbyl group having 1 to 40 carbon atoms and optionally containing a heteroatom, when “n” is 2 to 8, the R²s being identical to or different from each other, and the R²s optionally being bonded to each other to form a ring together with the carbon atoms of the aromatic ring bonded thereto;
R³ represents a carbonyl group or a hydrocarbylene group having 1 to 10 carbon atoms and optionally containing a heteroatom;
“*1” and “*2” each represent an attachment point to a carbon atom of the aromatic ring in the formula, provided that “*1” and “*2” are bonded to adjacent carbon atoms of the aromatic ring;
R¹¹ and R¹² each independently represent a halogen atom or a hydrocarbyl group having 1 to 10 carbon atoms and optionally containing a heteroatom, the R¹¹ and the R¹² optionally being bonded to each other to form a ring together with the carbon atoms bonded thereto and the atoms between the carbon atoms; and
R¹³ represents a halogen atom or a hydrocarbyl group having 1 to 40 carbon atoms and optionally containing a heteroatom, when “n2” is 2 to 9, the R¹³s being identical to or different from each other, and the R¹³s optionally being bonded to each other to form a ring together with the carbon atoms of the aromatic ring bonded thereto.

In the present invention, it is preferable to use such a hypervalent iodine compound.

In the present invention, the carboxy-group-containing polymer preferably includes a repeating unit represented by the following general formula (3),

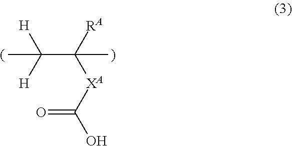

wherein R^{A} represents a hydrogen atom, a halogen atom, a methyl group, or a trifluoromethyl group; and
X^{A} represents a single bond, a phenylene group, a naphthylene group, or *—C(═O)—O—X^{A1}—, X^{A1} represents a saturated hydrocarbylene group having 1 to 10 carbon atoms, a phenylene group, or a naphthylene group, the saturated hydrocarbylene group optionally containing at least one selected from a hydroxy group, an ether bond, an ester bond, and a lactone ring, and “*” represents an attachment point to the carbon atom of the main chain.

In the present invention, it is preferable to use such a carboxy-group-containing polymer.

The present invention also provides a patterning process comprising the steps of:
forming a resist film by using a resist composition manufactured by the above-described manufacturing method on a substrate or on an underlayer film of a substrate on which the underlayer film has been laminated;
exposing the resist film by using a high-energy beam; and
developing the exposed resist film by using a developer.

A non-chemically amplified resist composition manufactured by the inventive manufacturing method can be used for such a patterning process.

### Advantageous Effects of Invention

The inventive manufacturing method is extremely useful in manufacturing a non-chemically amplified resist composition whose quality is controlled to be constant. Furthermore, a non-chemically amplified resist composition obtained by the inventive manufacturing method can be used in a patterning process in a process of manufacturing a semiconductor device and so forth.

### DESCRIPTION OF EMBODIMENTS

As described above, there have been demands for the development of: a method for manufacturing a non-chemically amplified resist composition whose quality is controlled to be constant; and a patterning process.

To achieve the object, the present inventors have studied earnestly and found out that a non-chemically amplified resist composition mainly containing a hypervalent iodine compound, a carboxy-group-containing polymer, and a solvent can be controlled to have a constant quality by adjusting the proportions of the components, and achieved the present invention.

That is, the present invention is a method for manufacturing a non-chemically amplified resist composition, comprising, in the following order, the steps of:
(i) placing a carboxy-group-containing polymer, a hypervalent iodine compound, and a solvent in a container and mixing together to prepare a fundamental resist composition;
(ii) collecting part of the fundamental resist composition, forming a resist film on a test substrate by using the collected fundamental resist composition, and evaluating a film physical property of the resist film; and
(iii) adding an additional material to the fundamental resist composition and mixing together to achieve a target film physical property based on an evaluation result of the step (ii).

Hereinafter, the present invention will be described in detail, but the present invention is not limited thereto.

### [Method for Manufacturing Non-Chemically Amplified Resist Composition]

The inventive method for manufacturing a non-chemically amplified resist composition includes, in the following order, the steps of:
(i) placing a carboxy-group-containing polymer, a hypervalent iodine compound, and a solvent in a container and mixing together to prepare a fundamental resist composition;
(ii) after the step (i), collecting part of the fundamental resist composition, forming a resist film on a test substrate by using the collected fundamental resist composition, and evaluating a film physical property of the resist film; and
(iii) adding an additional material to the fundamental resist composition and mixing together to achieve a target film physical property based on an evaluation result of the step (ii).

In the following, each step will be described in detail.

[Step (i)]

The step (i) is a step of placing a carboxy-group-containing polymer, a hypervalent iodine compound, and a solvent in a container and mixing together to prepare a fundamental resist composition. The container in the step (i) is not particularly limited, and, for example, it is possible to use a known container that is used when manufacturing a resist composition. The container may be capable of containing the above-described components, and may or may not have a lid. The container may or may not be sealed. The material of the container is not particularly limited. The size of the container is not limited, and may be about the size of a container used in a normal laboratory, or may be a size suitable for industrial production. The container may be one that allows the contained components to be subjected to operations such as heating, pressurizing, and stirring. For example, a reaction container, a vessel (e. g. a reaction vessel), a tank (e. g. a stirred tank), etc. can be used as the container. As the container, it is preferable to use a stirred tank for mixing the fundamental resist composition.

The manufacturing apparatus used in the inventive manufacturing method is not particularly limited as long as it has at least a container, and, for example, it is possible to use a known manufacturing apparatus used when manufacturing a resist composition. For example, the manufacturing apparatus may be provided with a mechanism for placing the components in the container (e. g. introduction piping), a mechanism for discharging from the container (e. g. discharging piping), a mechanism for introducing the matter discharged from the container into the container again (e. g. a circulating mechanism), a mechanism for removing impurities in the resist composition (e. g. a filter), a mechanism for stirring the resist composition (e. g. stirring blades), a mechanism for cleaning the apparatus (e. g. a cleaning nozzle), etc. The material of the manufacturing apparatus is not particularly limited, but wetted parts in the apparatus are preferably lined or coated with fluororesin or the like.

In the step (i), the method for placing the components in the container is not particularly limited. Examples include a method of charging the components through a material charging port of the container. When the components are charged, the components may be charged successively or may be charged at once. Furthermore, when one component is charged, the component may be charged in multiple batches. Furthermore, when the components are charged into the stirred tank successively, the charging order is not particularly limited.

In the step (i), the atmosphere in the container is not particularly limited. For example, the inside may be filled with the air, or may be filled with a different gas (nitrogen, argon, etc.). Furthermore, the inside of the container may be of normal pressure, under pressure, or under reduced pressure.

In the step (i), the method for mixing the components is not particularly limited, but mixing by stirring is preferable, and mixing with stirring blades is particularly preferable. When mixing is performed with stirring blades, the size and material of the stirring blades are not particularly limited. The rotational rate of the stirring blades is not particularly limited, but is preferably 20 to 500 rpm, more preferably 40 to 350 rpm, and further preferably 50 to 300 rpm. When mixing is performed by stirring, the inside of the container may be stirred from before the components are charged, or stirring may be started after at least one component has been charged.

The mixing time in the step (i) is not particularly limited, but is preferably 30 minutes or more, more preferably 1 hour or more, further preferably 2 hours or more, even more preferably 4 hours or more, and particularly preferably 8 hours or more. The upper limit of the mixing time is not particularly limited, but, from the viewpoint of productivity, the mixing time is preferably 24 hours or less, more preferably 18 hours or less, and further preferably 12 hours or less.

The temperature (the temperature of the contents of the container) when performing the mixing is not particularly limited, but is preferably 15 to 35° C., more preferably 20 to 25° C. Furthermore, when the mixing is performed, the temperature of the contents of the container is preferably kept constant, and is preferably within ±10° C. from the set temperature, more preferably within ±5° C., and further preferably within ±1° C. When terminating the mixing, it is preferable to check that the components are dissolved or uniformly dispersed in the solvent. During the mixing, ultrasonic waves may be applied to the contents of the container.

In the following, the hypervalent iodine compound, the carboxy-group-containing polymer, and the solvent used in the step (i) will be described in detail.

### [Hypervalent Iodine Compound]

Hypervalent iodine compound is a general term for iodine compounds having valence electrons formally exceeding the octet rule. The hypervalent iodine compound used in the present invention is not particularly limited, and examples include three-coordinate hypervalent iodine compounds, having an oxidation number of +3, and five-coordinate hypervalent iodine compounds, having an oxidation number of +5.

As the hypervalent iodine compound, it is preferable to use a three-coordinate hypervalent iodine compound including at least one of compounds represented by the following general formulae (1) and (2).

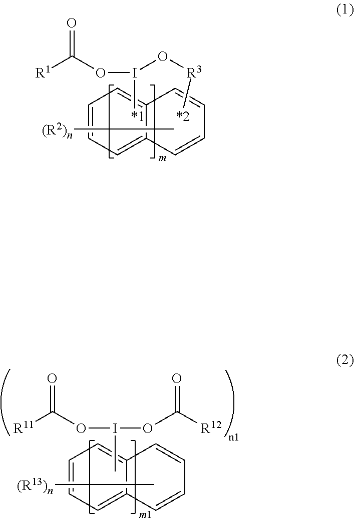

In the formulae, “m” and “ml” each represent an integer of 0 to 2;
“n” represents an integer of 0 to 4 when “m” is 0, an integer of 0 to 6 when “m” is 1, and an integer of 0 to 8 when “m” is 2;
when “m1” is 0, “n1” represents an integer of 1 to 3, “n2” represents an integer of 0 to 5, and 1≤(n1+n2)≤6 is satisfied;
when “m1” is 1, “n1” represents an integer of 1 to 3, “n2” represents an integer of 0 to 7, and 1≤(n1+n2)≤8 is satisfied;
when “m1” is 2, “n1” represents an integer of 1 to 3, “n2” represents an integer of 0 to 9, and 1≤(n1+n2)≤10 is satisfied;
R¹ represents a halogen atom or a hydrocarbyl group having 1 to 10 carbon atoms and optionally containing a heteroatom;
R² represents a halogen atom or a hydrocarbyl group having 1 to 40 carbon atoms and optionally containing a heteroatom, when “n” is 2 to 8, the R²s being identical to or different from each other, and the R²s optionally being bonded to each other to form a ring together with the carbon atoms of the aromatic ring bonded thereto;
R³ represents a carbonyl group or a hydrocarbylene group having 1 to 10 carbon atoms and optionally containing a heteroatom;
“*1” and “*2” each represent an attachment point to a carbon atom of the aromatic ring in the formula, provided that “*1” and “*2” are bonded to adjacent carbon atoms of the aromatic ring;
R¹¹ and R¹² each independently represent a halogen atom or a hydrocarbyl group having 1 to 10 carbon atoms and optionally containing a heteroatom, the R¹¹ and the R¹² optionally being bonded to each other to form a ring together with the carbon atoms bonded thereto and the atoms between the carbon atoms; and
R¹³ represents a halogen atom or a hydrocarbyl group having 1 to 40 carbon atoms and optionally containing a heteroatom, when “n2” is 2 to 9, the R¹³s being identical to or different from each other, and the R¹³s optionally being bonded to each other to form a ring together with the carbon atoms of the aromatic ring bonded thereto.

In the general formula (1), “m” represents an integer of 0 to 2. “n” represents an integer of 0 to 4 when “m” is 0, an integer of 0 to 6 when “m” is 1, and an integer of 0 to 8 when “m” is 2. “n” is preferably 0, 1, 2, 3, or 4, more preferably 0, 1, 2, or 3, further preferably 0, 1, or 2, and most preferably 0 or 1.

In the general formula (1), RI represents a halogen atom or a hydrocarbyl group having 1 to 10 carbon atoms and optionally containing a heteroatom. Specific examples of the halogen atom include a fluorine atom, a chlorine atom, a bromine atom, and an iodine atom. The hydrocarbyl group having 1 to 10 carbon atoms may be saturated or unsaturated, and may be linear, branched, or cyclic. Specific examples thereof include: alkyl groups having 1 to 10 carbon atoms, such as a methyl group, an ethyl group, an n-propyl group, an isopropyl group, an n-butyl group, an isobutyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups having 3 to 10 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, and an adamantyl group; alkenyl groups having 2 to 10 carbon atoms, such as a vinyl group and an allyl group; aryl groups having 6 to 10 carbon atoms, such as a phenyl group and a naphthyl group; and groups obtained by combining these groups. Furthermore, part or all of the hydrogen atoms of the hydrocarbyl groups may be substituted with a group containing a heteroatom, such as an oxygen atom, a sulfur atom, a nitrogen atom, or a halogen atom, and part of the —CH₂— of the hydrocarbyl groups may be substituted with a group containing a heteroatom such as an oxygen atom, a sulfur atom, or a nitrogen atom. The resulting hydrocarbyl groups may contain a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, a carboxylic acid anhydride (—C(═O)—O—C(═O)—), etc. As R¹, a hydrocarbyl group having 1 to 4 carbon atoms or a fluorinated hydrocarbyl group having 1 to 4 carbon atoms is preferable, and a hydrocarbyl group having 1 to 4 carbon atoms is more preferable.

In the general formula (1), Re represents a halogen atom or a hydrocarbyl group having 1 to 40 carbon atoms and optionally containing a heteroatom. Specific examples of the halogen atom include a fluorine atom, a chlorine atom, a bromine atom, and an iodine atom. The hydrocarbyl group having 1 to 40 carbon atoms may be saturated or unsaturated, and may be linear, branched, or cyclic. Specific examples thereof include: alkyl groups having 1 to 40 carbon atoms, such as a methyl group, an ethyl group, an n-propyl group, an isopropyl group, an n-butyl group, an isobutyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups having 3 to 40 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group, and an adamantylmethyl group; and aryl groups having 6 to 40 carbon atoms, such as a phenyl group, a naphthyl group, and an anthracenyl group. Furthermore, part or all of the hydrogen atoms of the hydrocarbyl groups may be substituted with a group containing a heteroatom, such as an oxygen atom, a sulfur atom, a nitrogen atom, or a halogen atom, and part of the —CH₂— of the hydrocarbyl groups may be substituted with a group containing a heteroatom such as an oxygen atom, a sulfur atom, or a nitrogen atom. The resulting hydrocarbyl groups may contain a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, a carboxylic acid anhydride (—C(═O)—O—C(═O)—), etc. When “n” is 2 to 8, the Res may be identical to or different from each other, and the Res may be bonded to each other to form a ring together with the carbon atoms of the aromatic ring bonded thereto.

In the general formula (1), R³ represents a carbonyl group or a hydrocarbylene group having 1 to 10 carbon atoms and optionally containing a heteroatom. The hydrocarbylene group having 1 to 10 carbon atoms may be saturated or unsaturated, and may be linear, branched, or cyclic. Specific examples thereof include alkylene groups having 1 to 10 carbon atoms, such as a methanediyl group, an ethane-1,1-diyl group, an ethane-1,2-diyl group, a propane-1,1-diyl group, a propane-1,2-diyl group, a propane-1,3-diyl group, a propane-2,2-diyl group, a butane-2,3-diyl group, a butane-1,4-diyl group, a 2-methylpropane-1,2-diyl group, a pentane-1,5-diyl group, a hexane-1,6-diyl group, a heptane-1,7-diyl group, an octane-1,8-diyl group, a nonane-1,9-diyl group, and a decane-1,10-diyl group; cyclic saturated hydrocarbylene groups having 3 to 10 carbon atoms, such as a cyclopentanediyl group, a cyclohexanediyl group, a norbornanediyl group, an adamantanediyl group, and a tricyclo[5.2.1.0^{2,6}]decanediyl group; alkenylene groups having 2 to 10 carbon atoms, such as a vinylene group and a propynylene group; arylene groups having 6 to 10 carbon atoms, such as a phenylene group, a methylphenylene group, an ethylphenylene group, an n-propylphenylene group, an isopropylphenylene group, an n-butylphenylene group, and a naphthylene group; and groups obtained by combining these groups. Furthermore, part or all of the hydrogen atoms of the hydrocarbylene groups may be substituted with a group containing a heteroatom, such as an oxygen atom, a sulfur atom, a nitrogen atom, or a halogen atom, and part of the —CH₂— of the hydrocarbylene groups may be substituted with a group containing a heteroatom such as an oxygen atom, a sulfur atom, or a nitrogen atom. The resulting hydrocarbylene groups may contain a hydroxy group, a cyano group, a halogenated alkyl group, a halogen atom, a carbonyl group, an ether bond, a thioether bond, an ester bond, a sulfonic acid ester bond, a carbonate bond, a carbamate bond, a lactone ring, a sultone ring, a carboxylic acid anhydride (—C(═O)—O—C(═O)—), etc. As R³, a carbonyl group, a hydrocarbylene group having 1 to 4 carbon atoms, or a fluorinated hydrocarbylene group having 1 to 4 carbon atoms is preferable.

In the general formula (1), “*1” and “*2” each represent an attachment point to a carbon atom of the aromatic ring in the formula, provided that “*1” and “*2” are bonded to adjacent carbon atoms of the aromatic ring. As combinations of such “*1”, “*2”, and “m”, the seven cases shown below are possible.

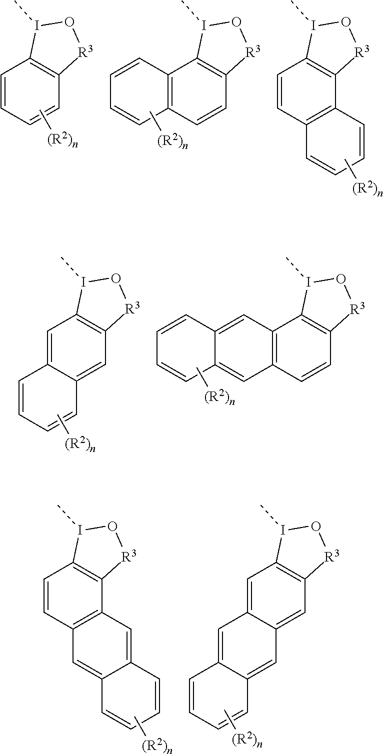

In the formulae, “n”, R², and R³ are as defined above. A broken line represents an attachment point to R¹—C(═O)—O—.

Specific examples of the hypervalent iodine compound represented by the general formula (1) include the following, but are not limited thereto. Note that, in the following formulae, Me represents a methyl group.

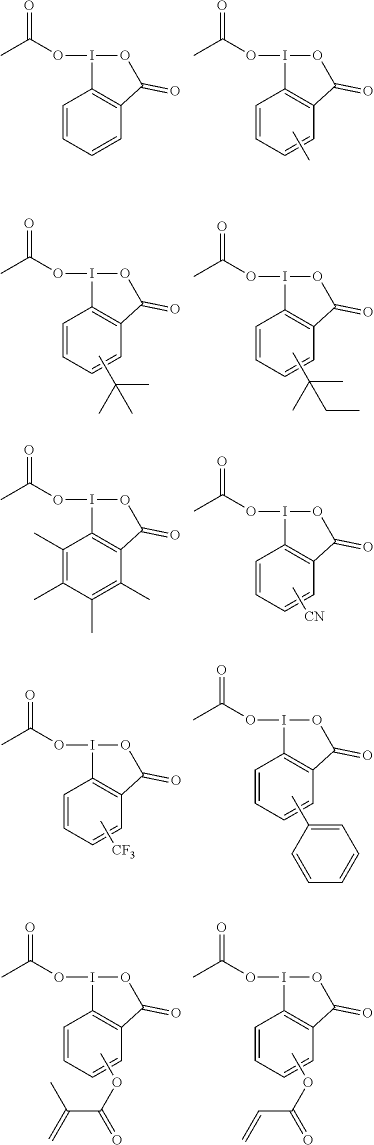

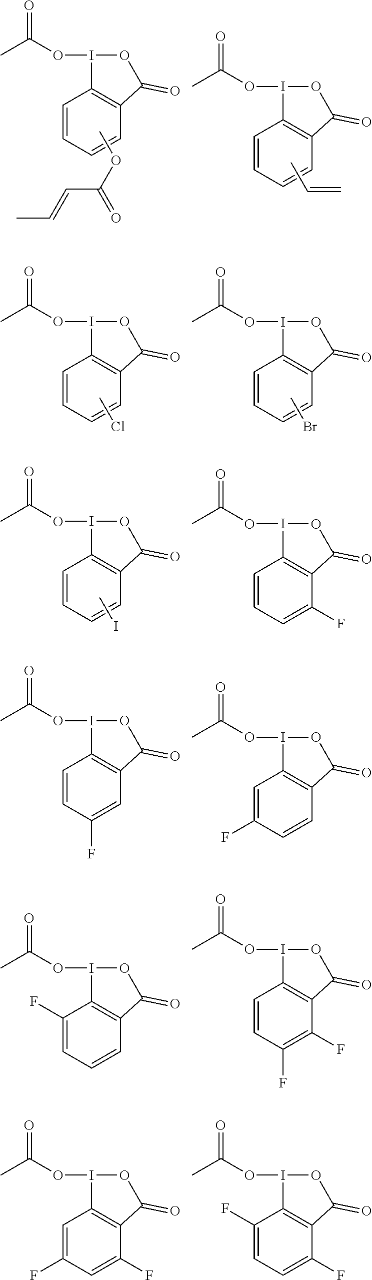

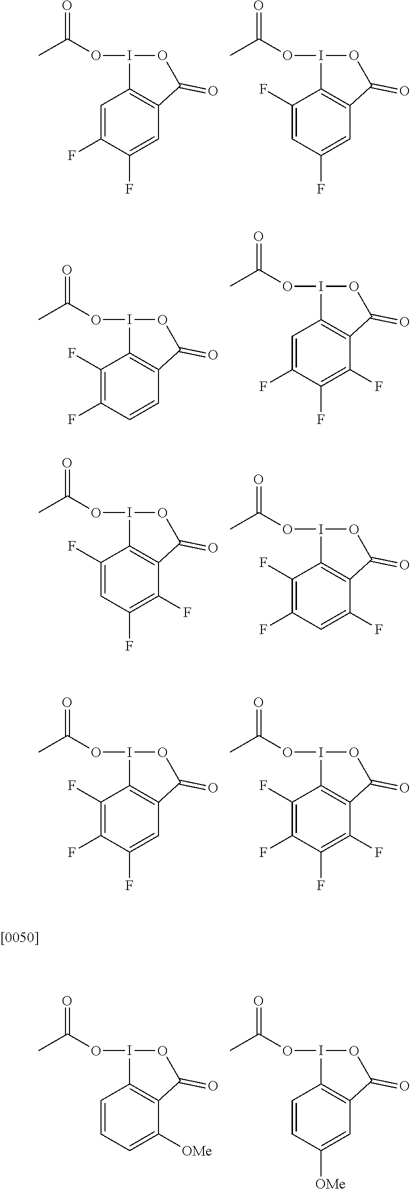

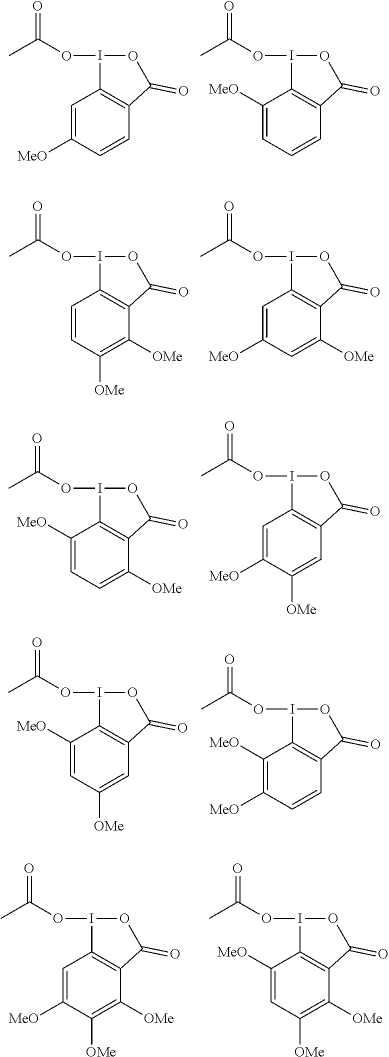

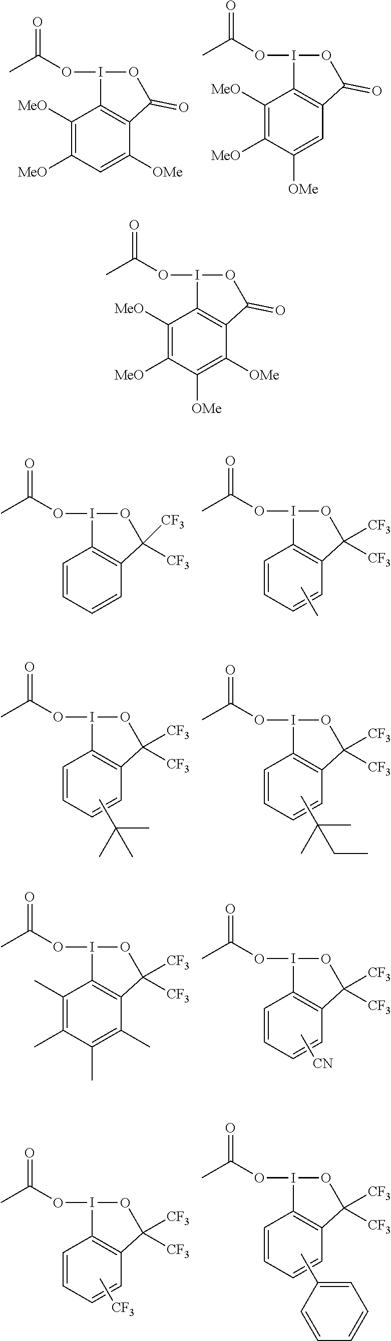

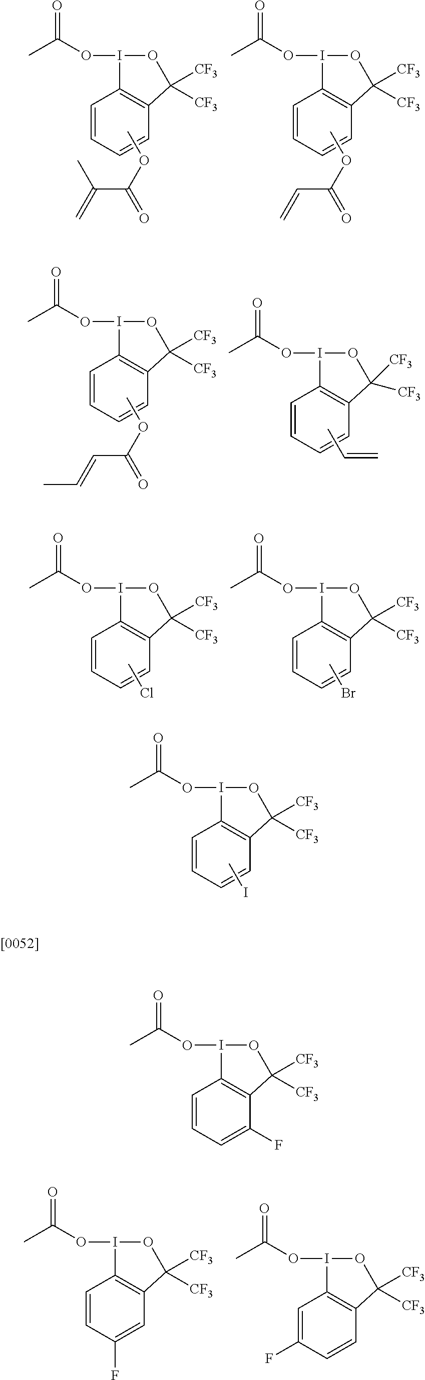

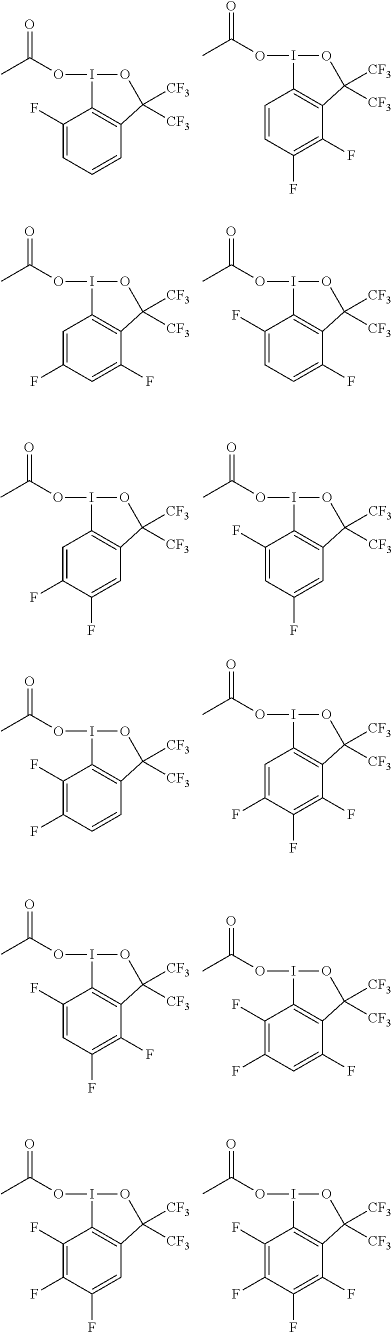

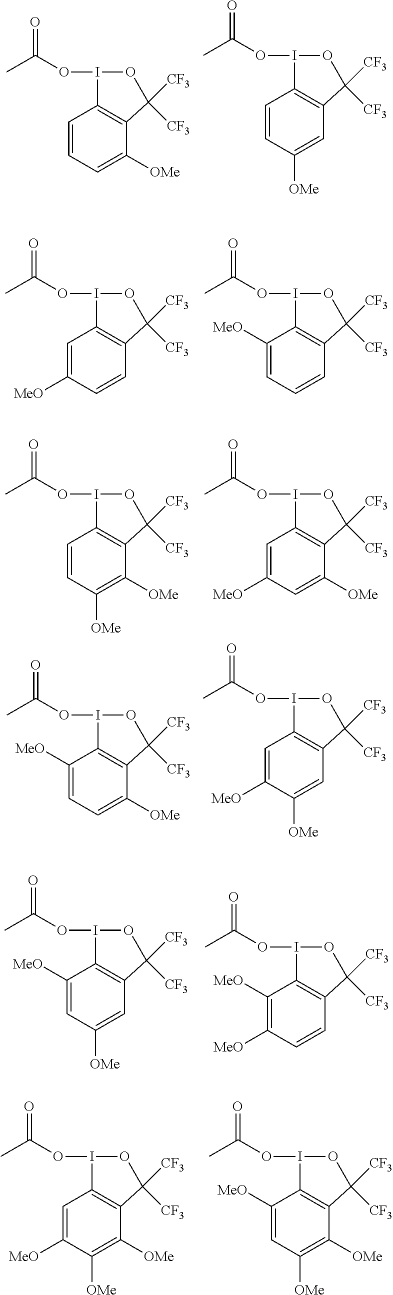

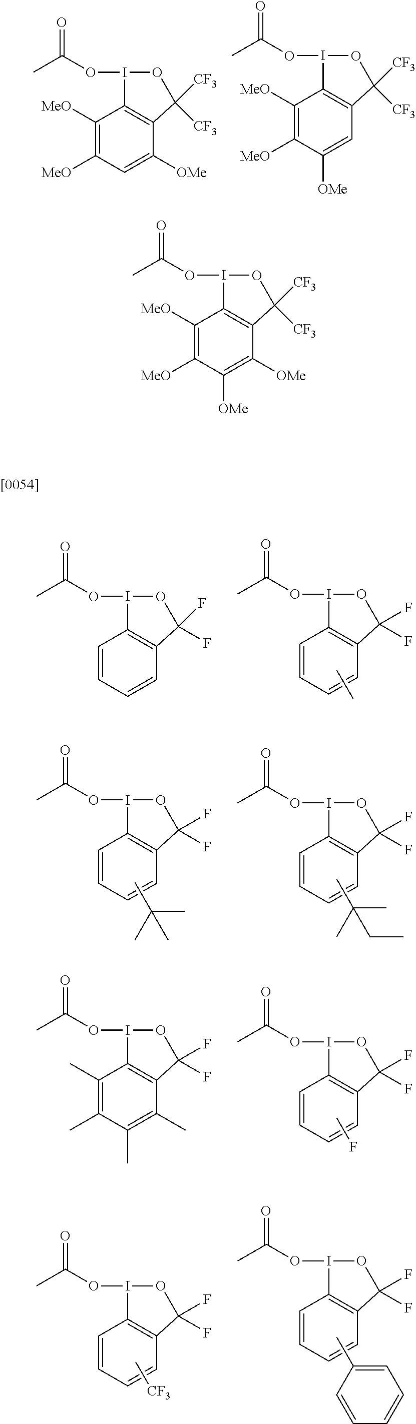

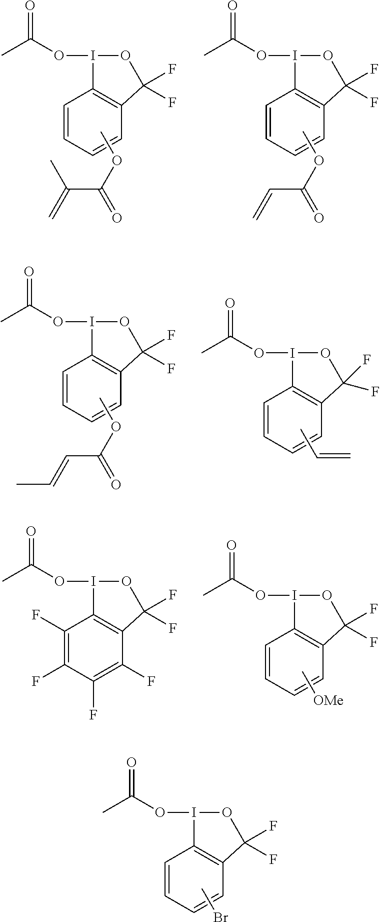

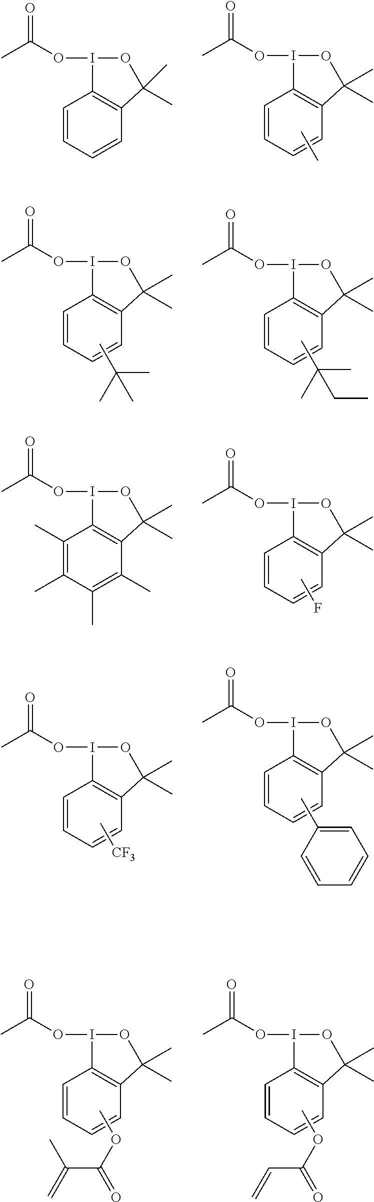

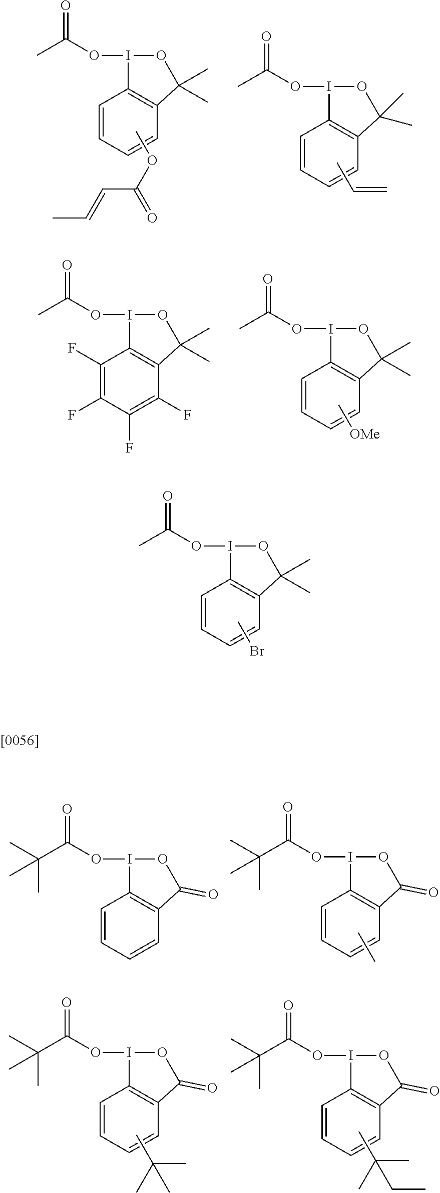

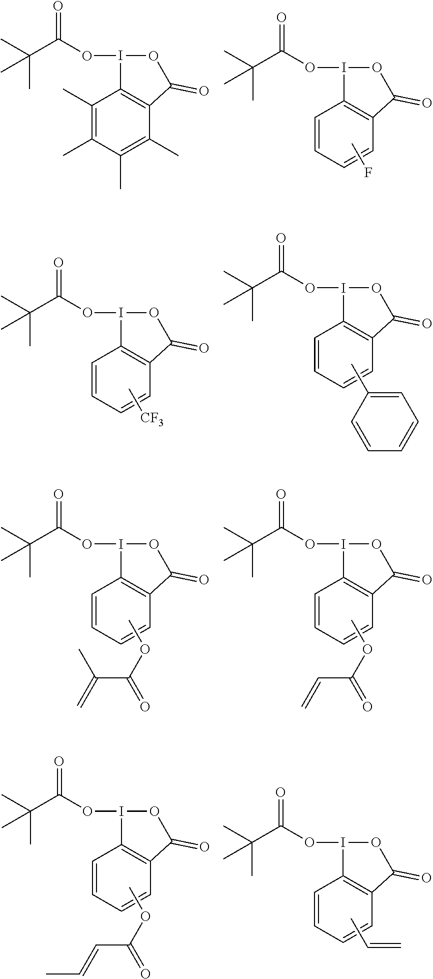

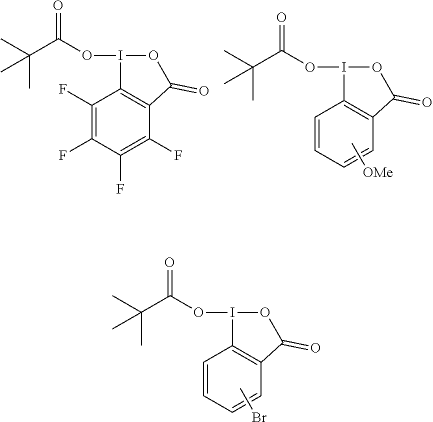

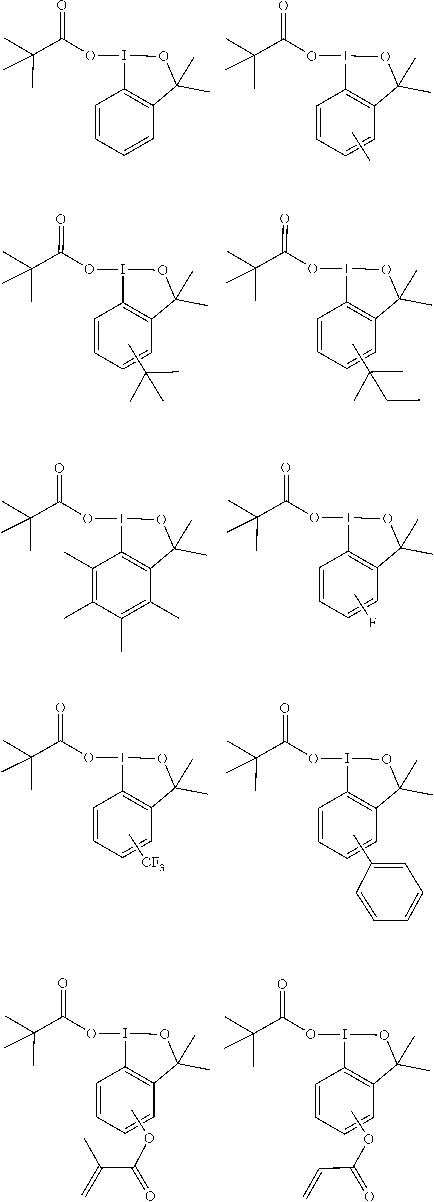

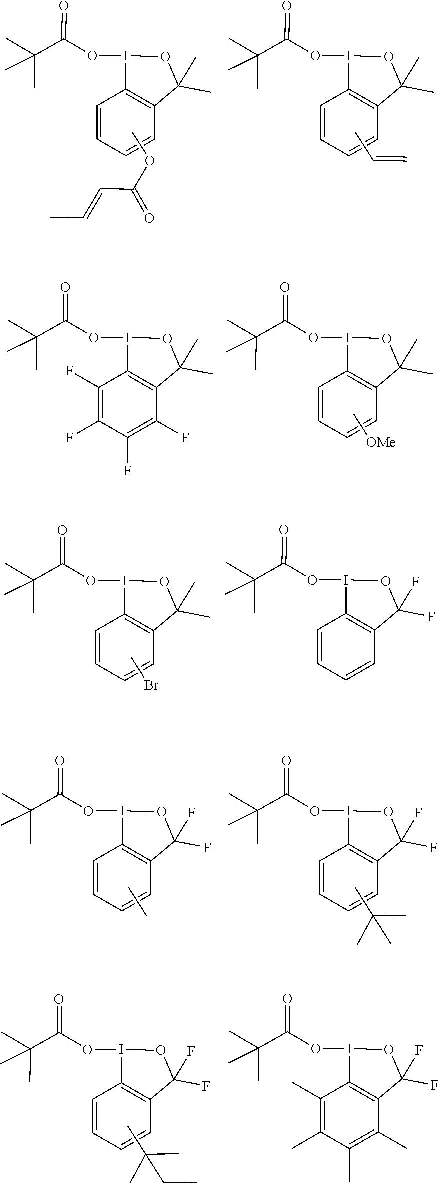

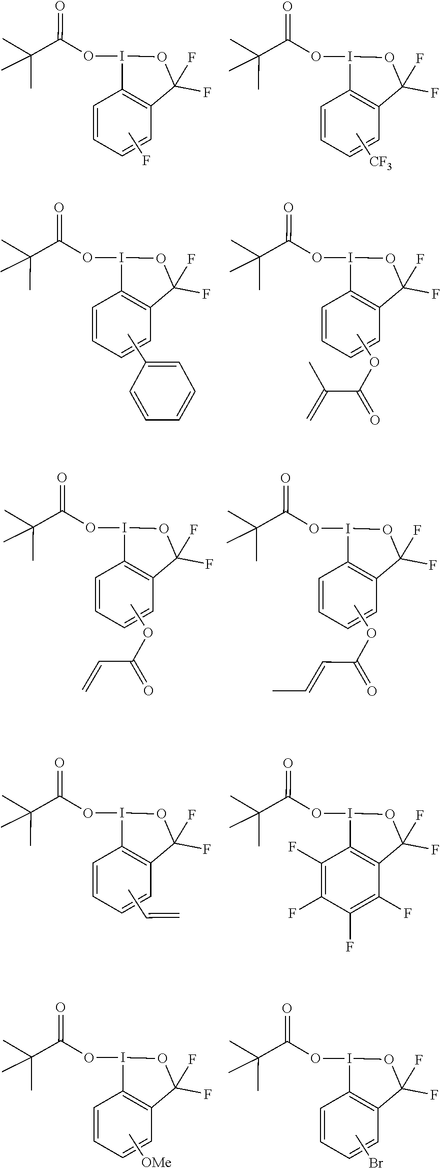

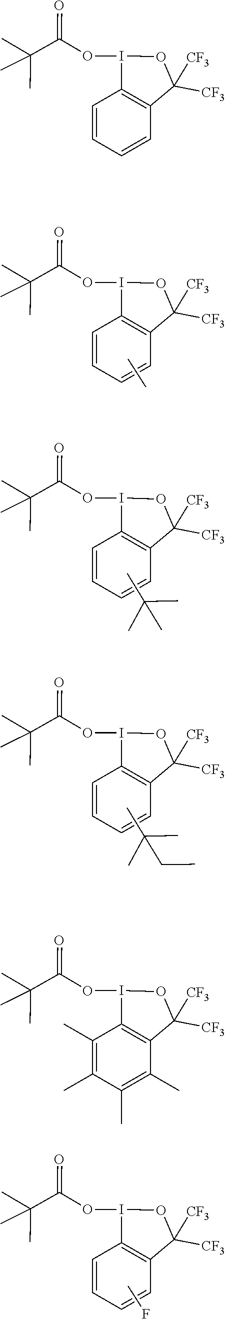

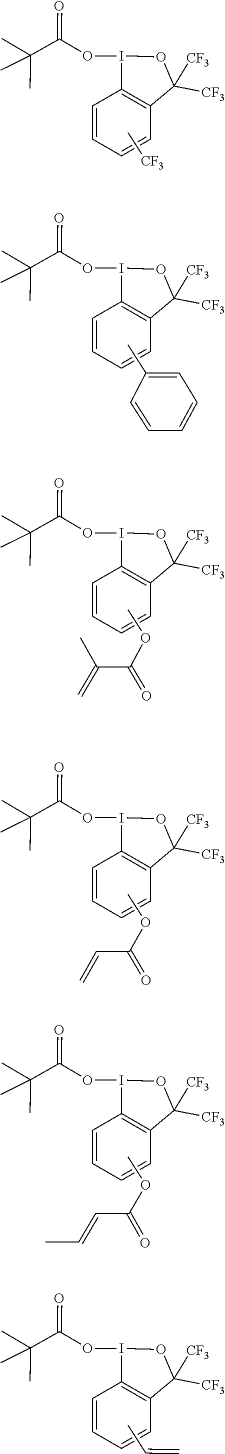

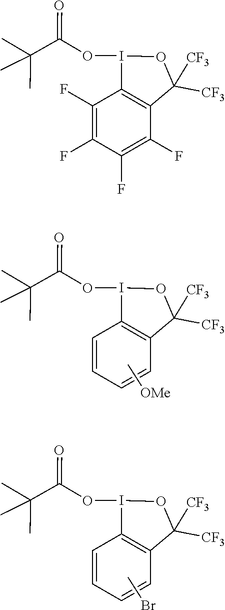

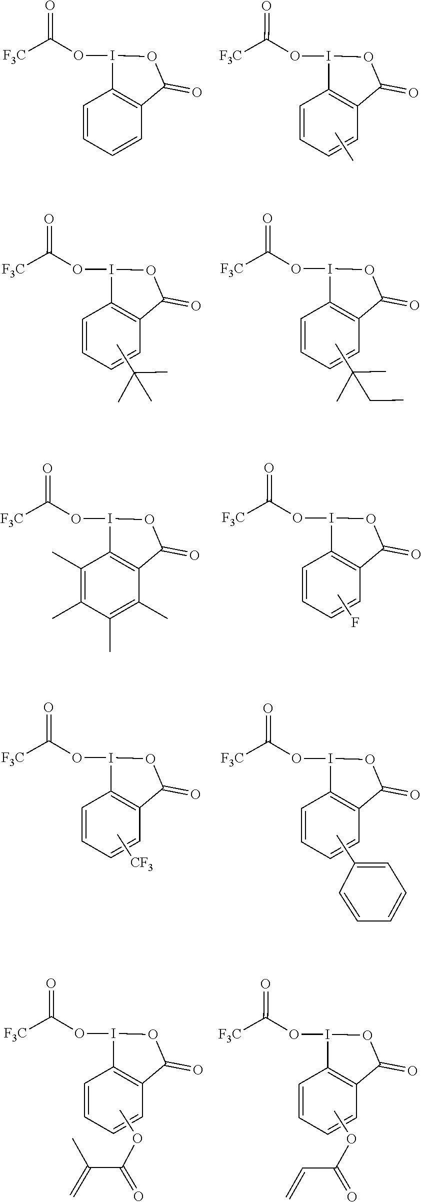

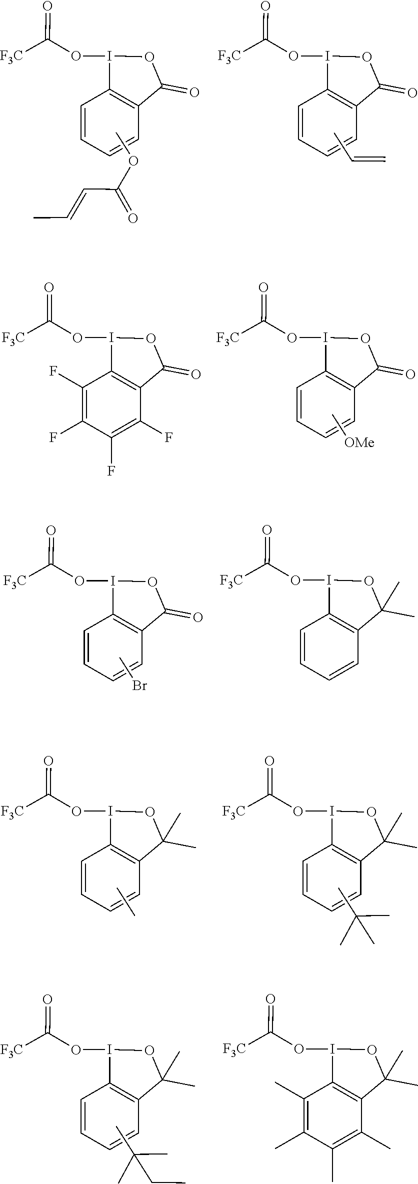

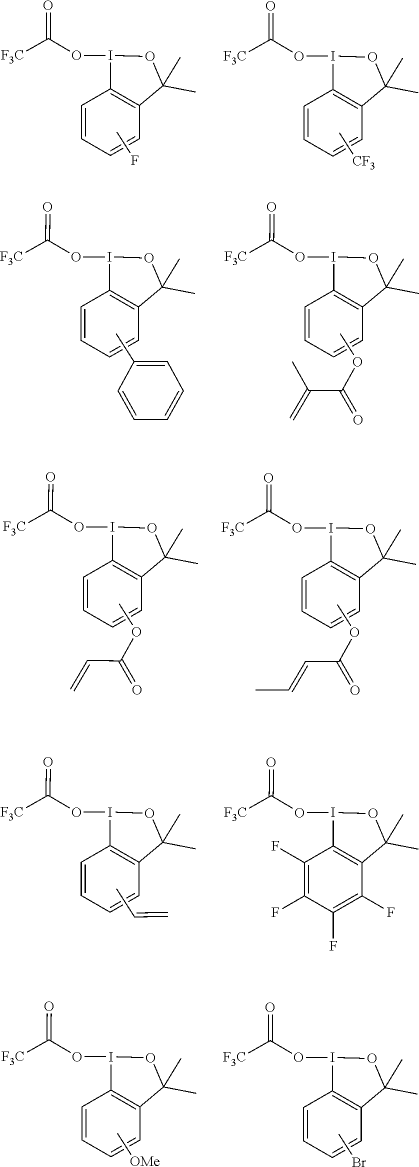

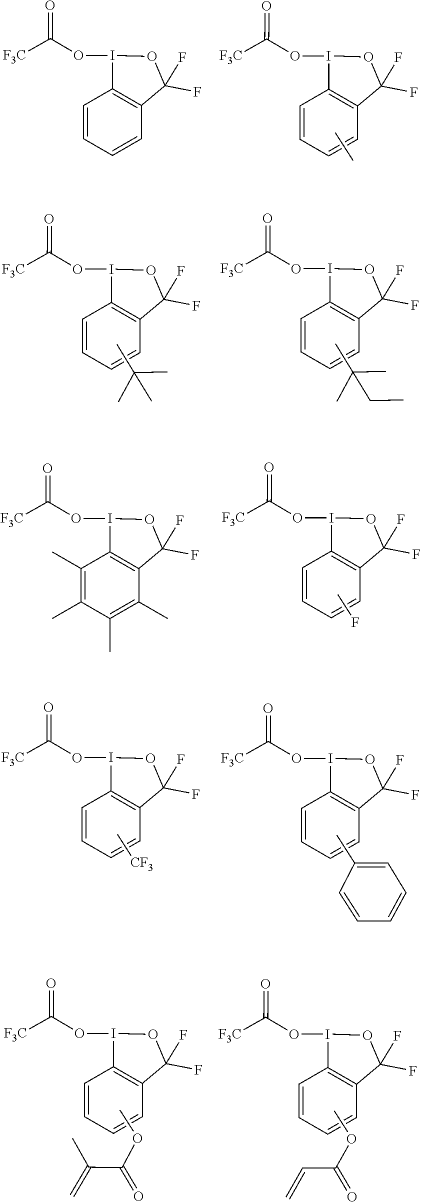

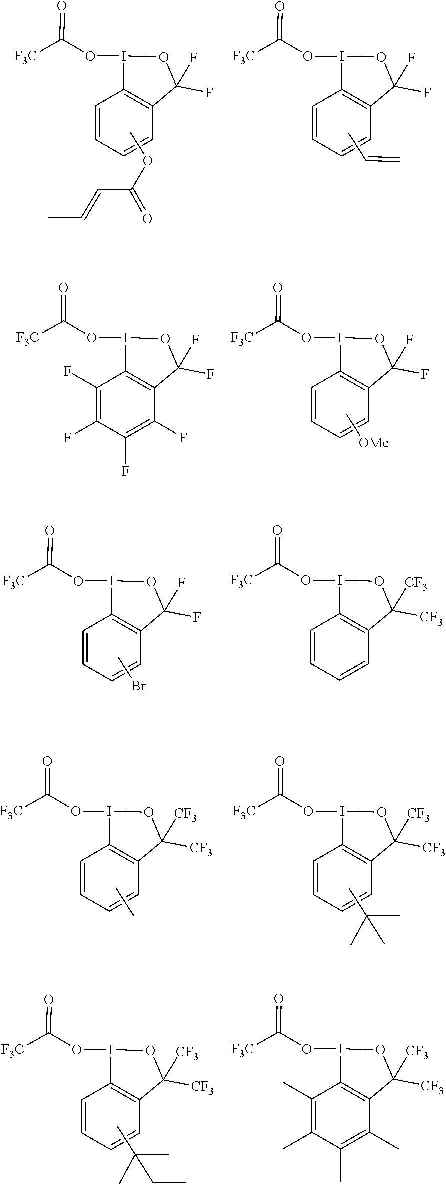

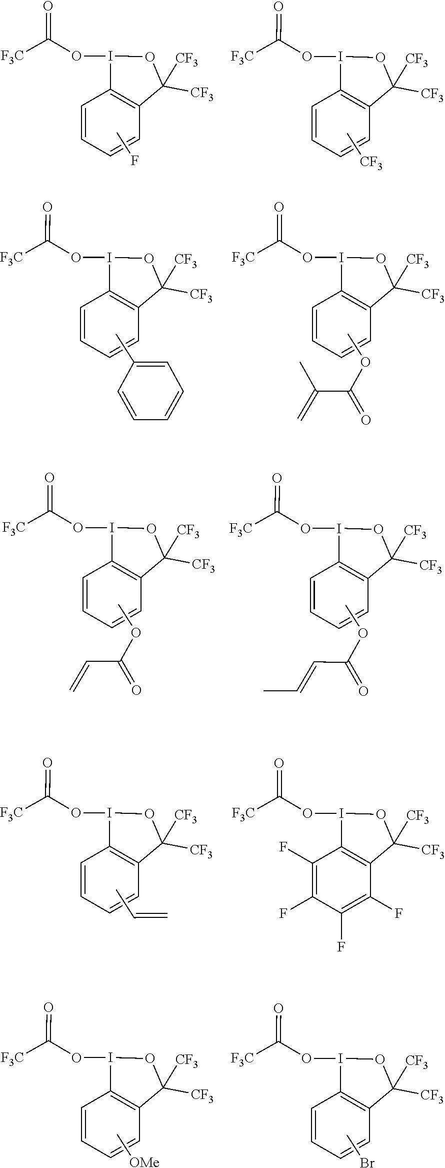

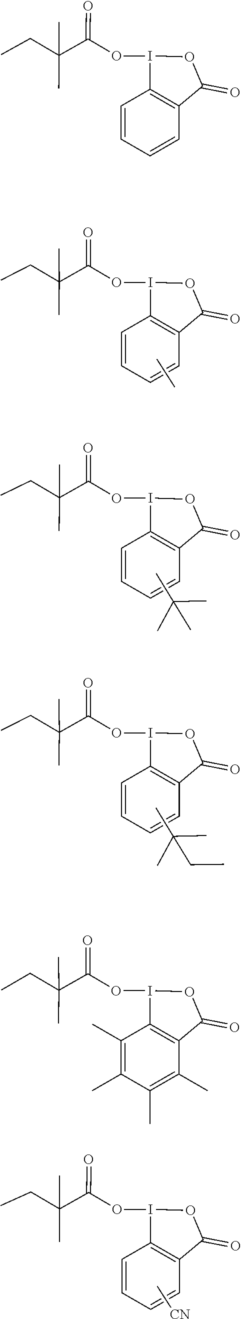

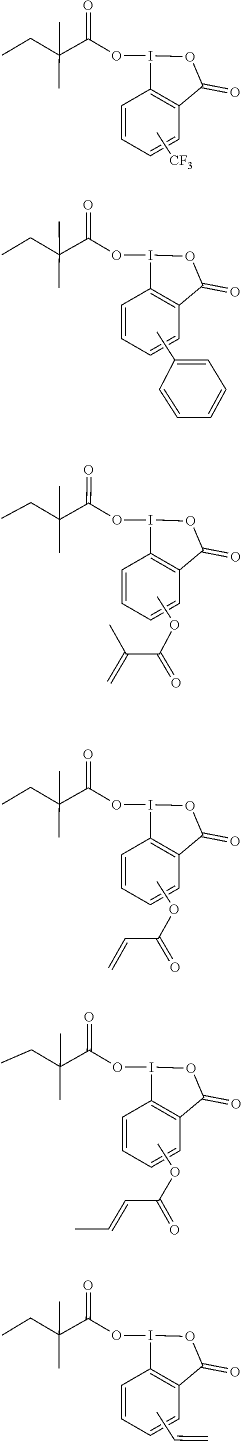

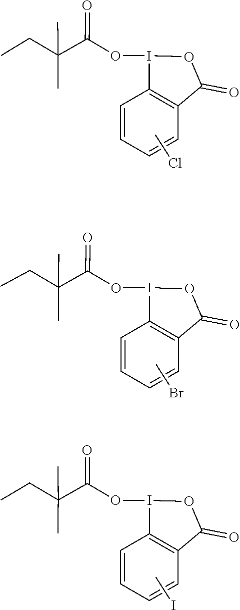

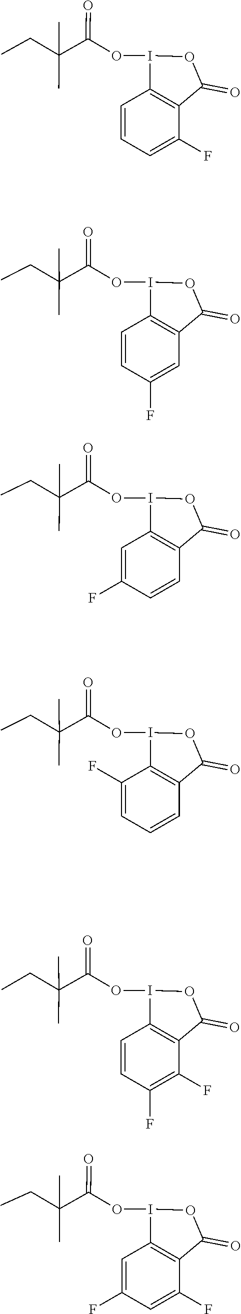

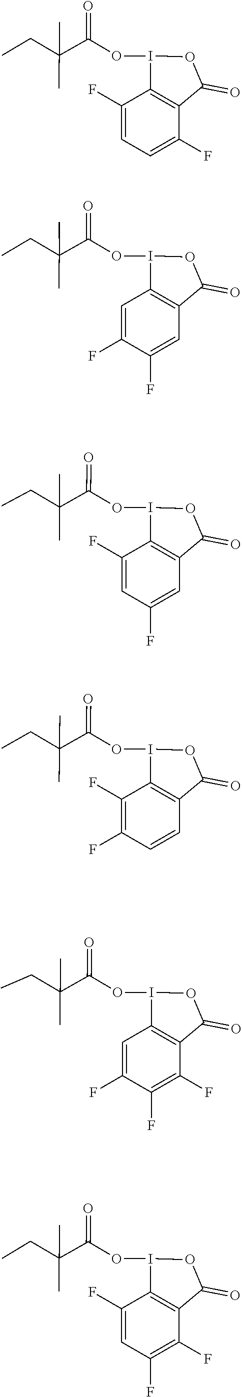

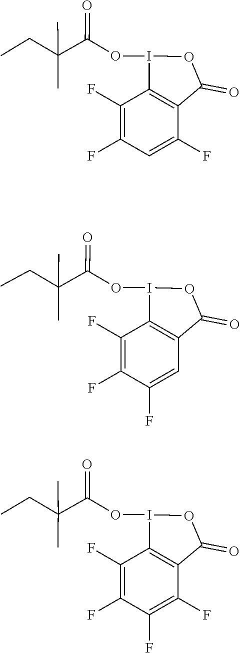

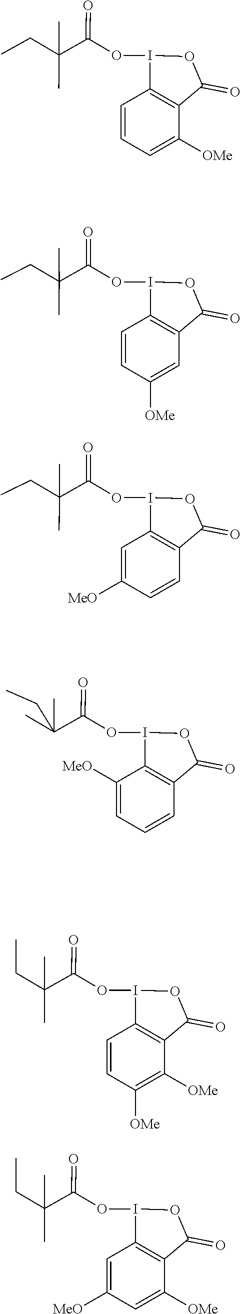

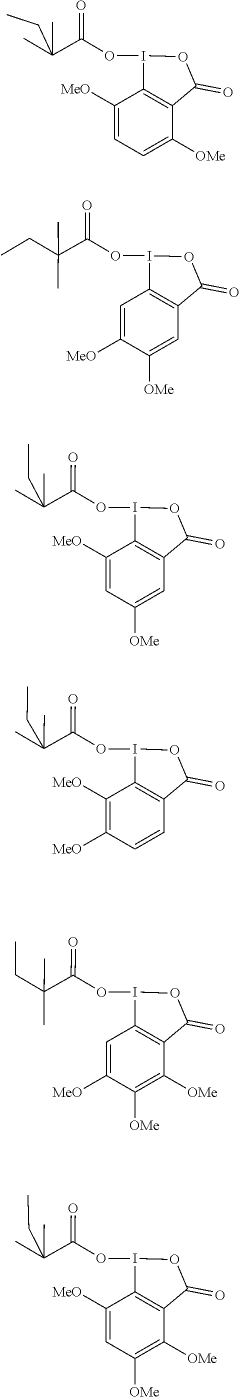

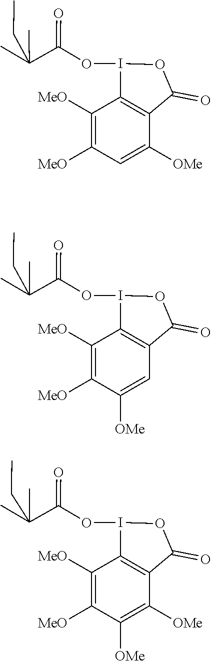

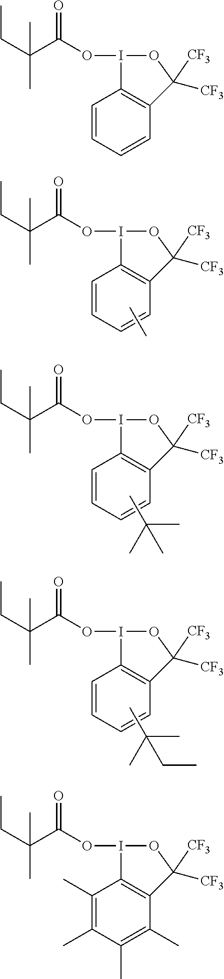

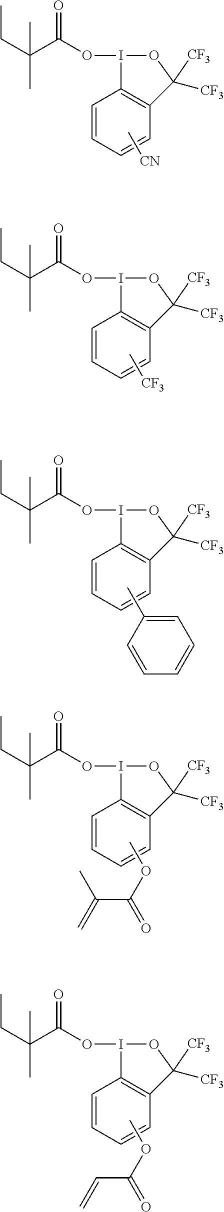

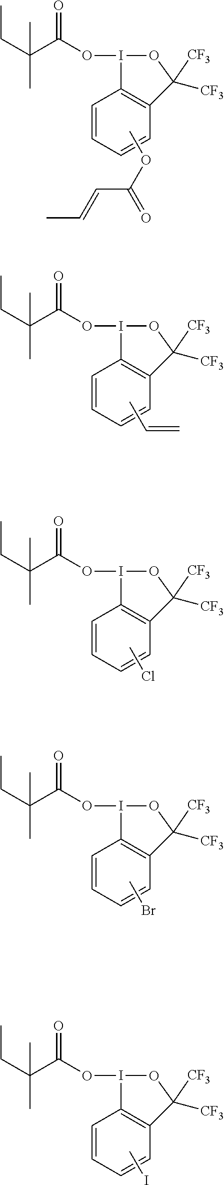

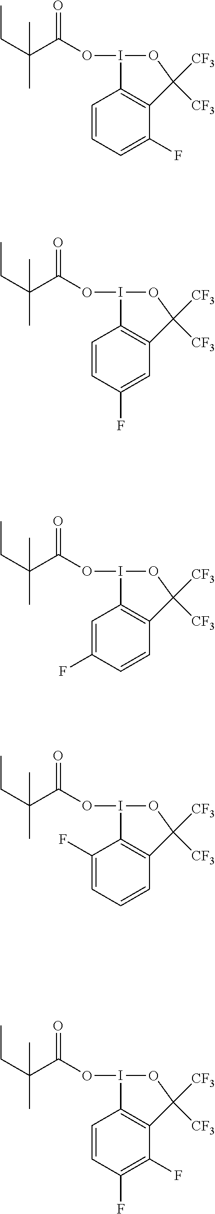

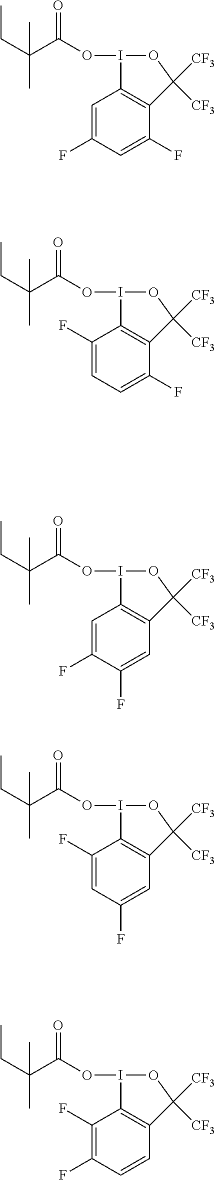

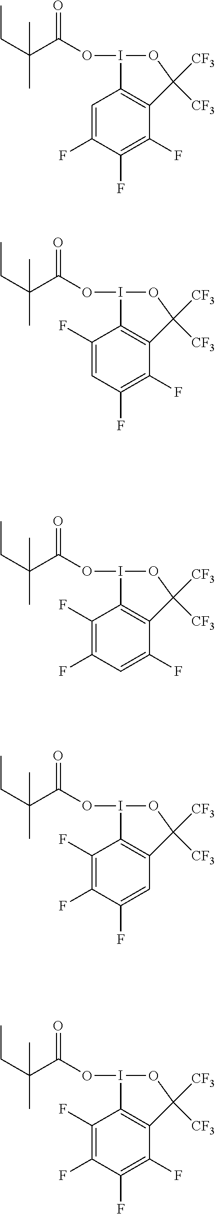

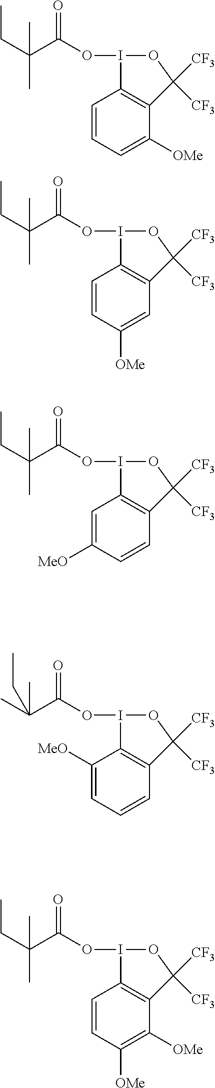

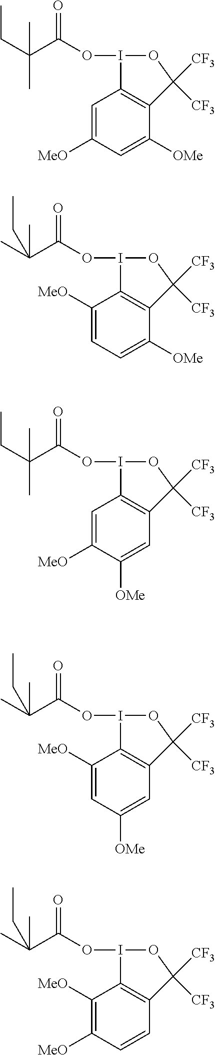

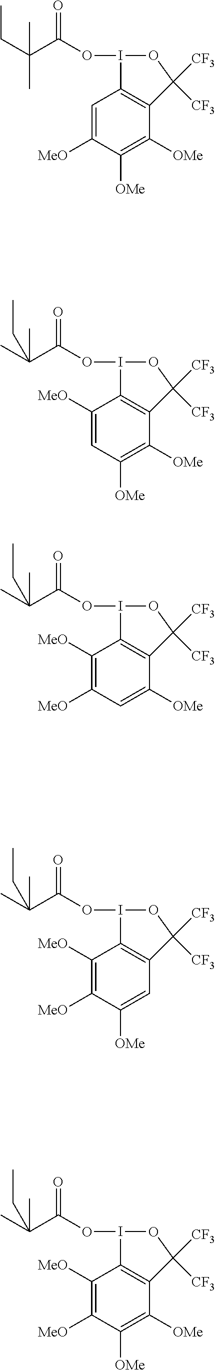

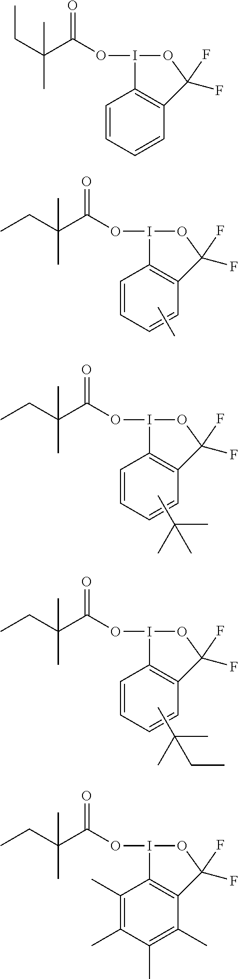

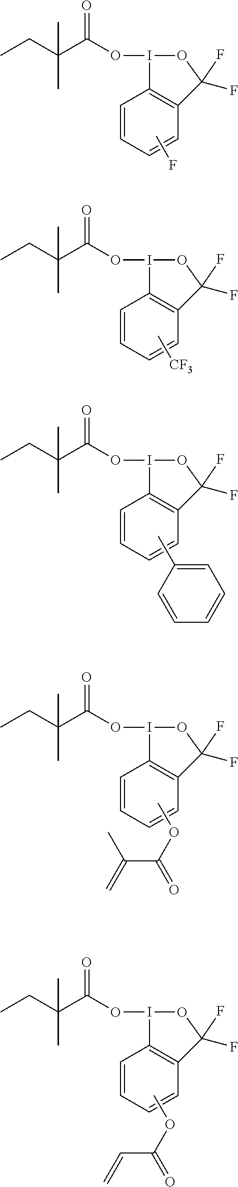

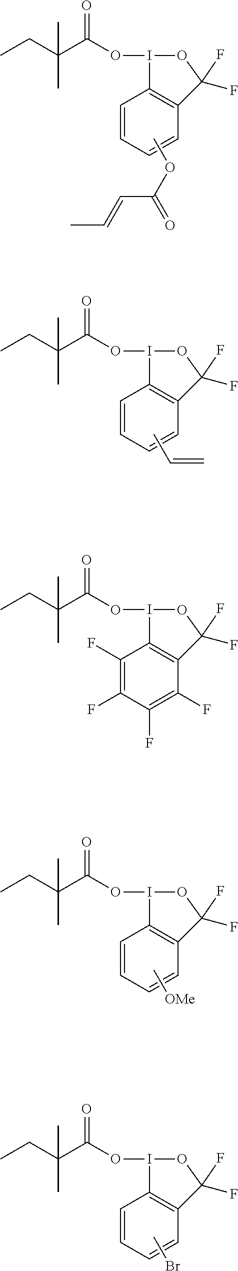

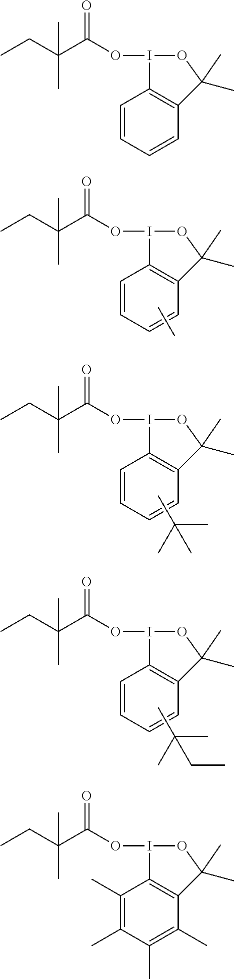

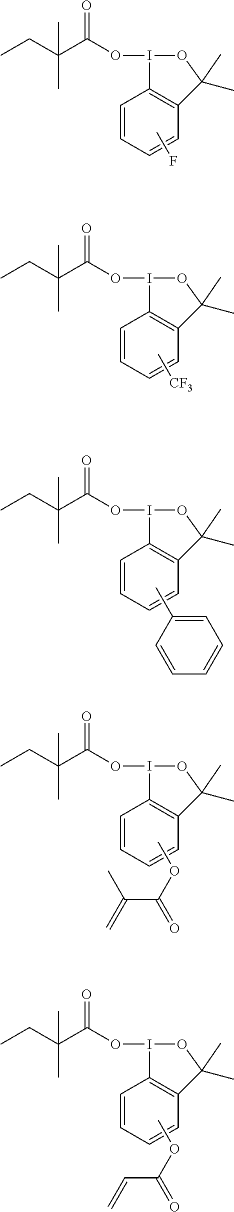

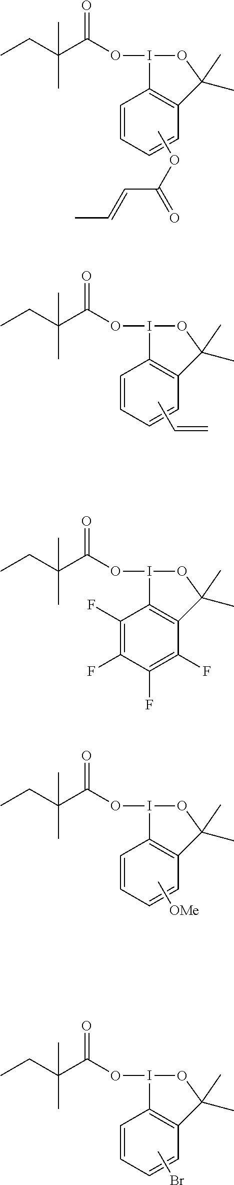

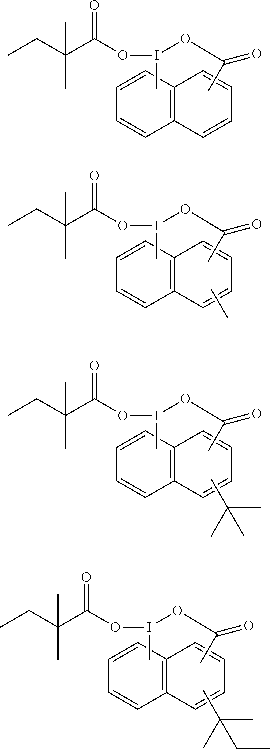

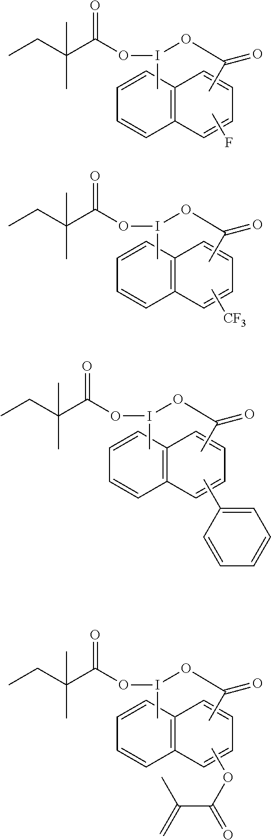

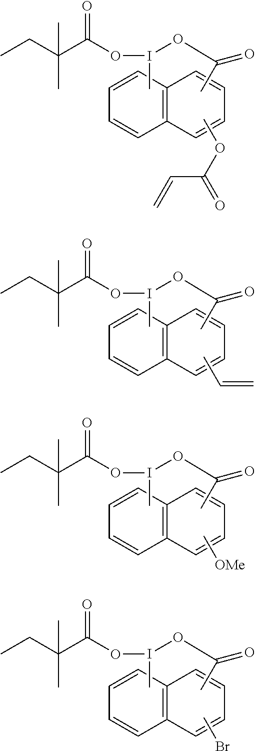

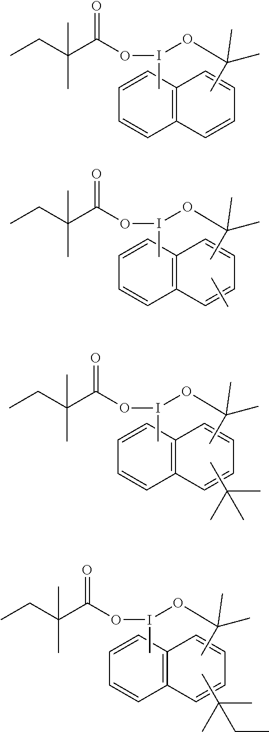

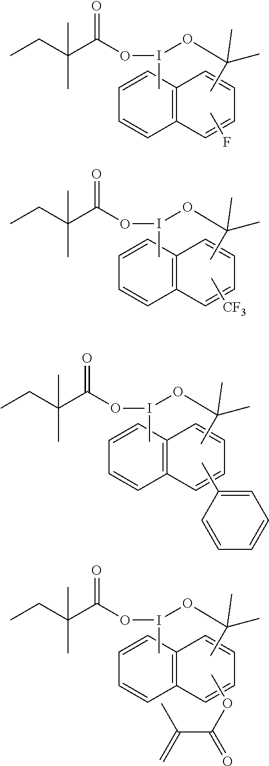

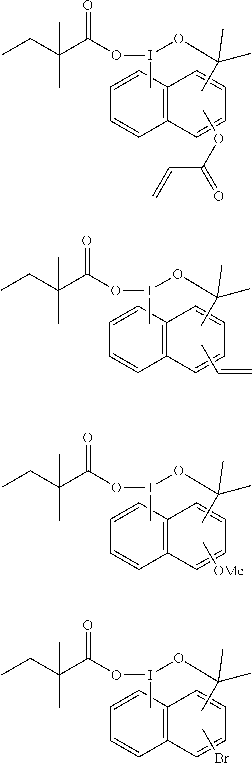

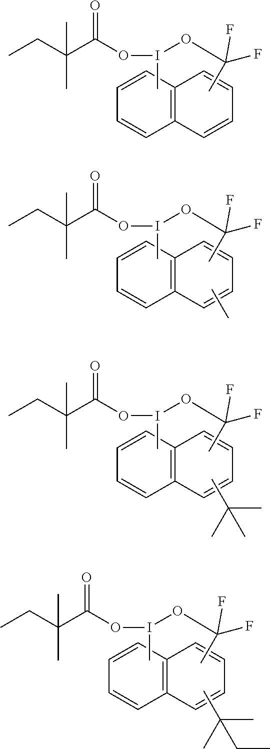

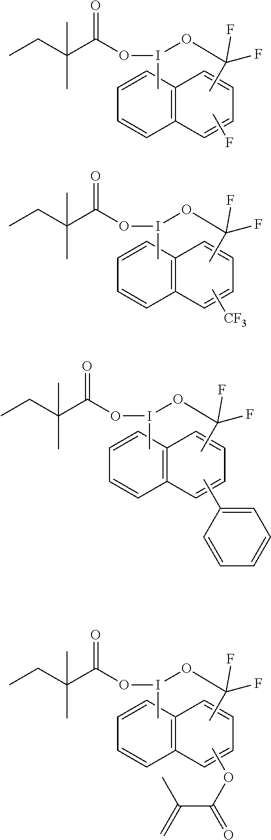

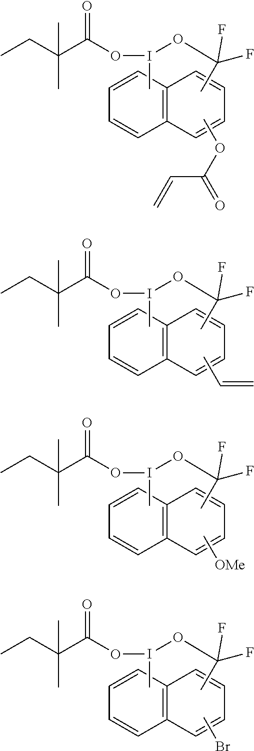

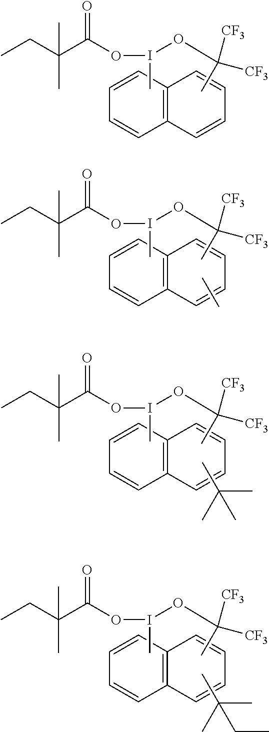

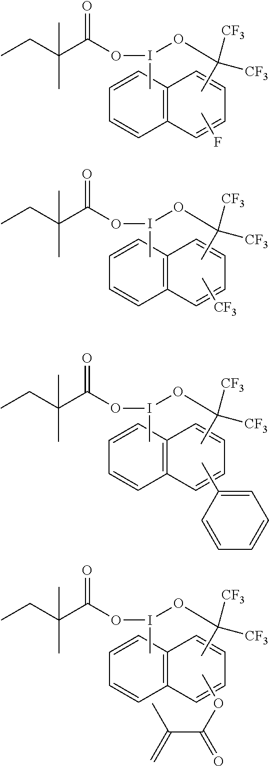

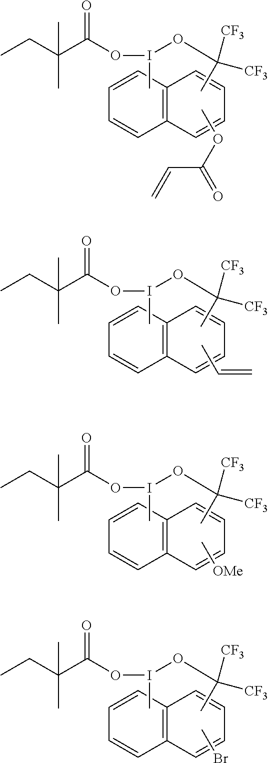

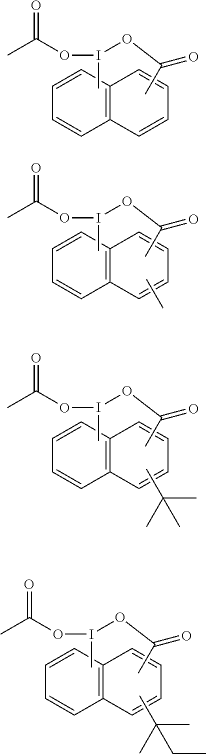

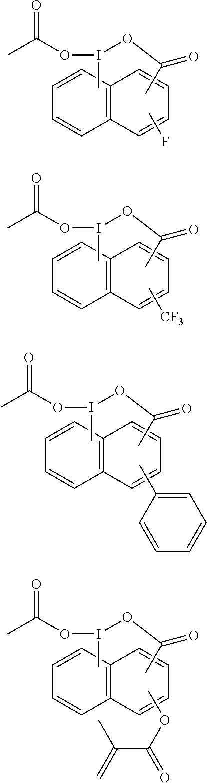

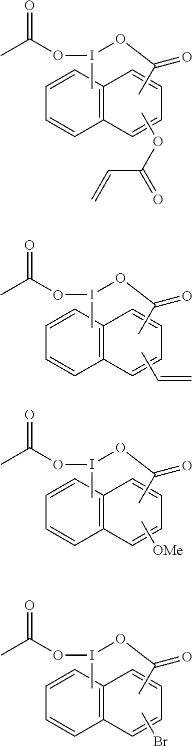

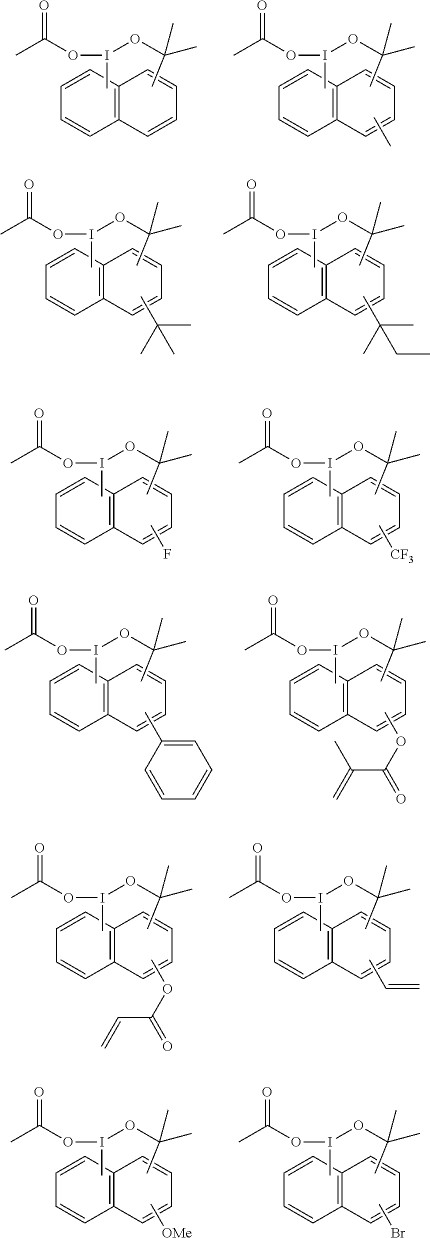

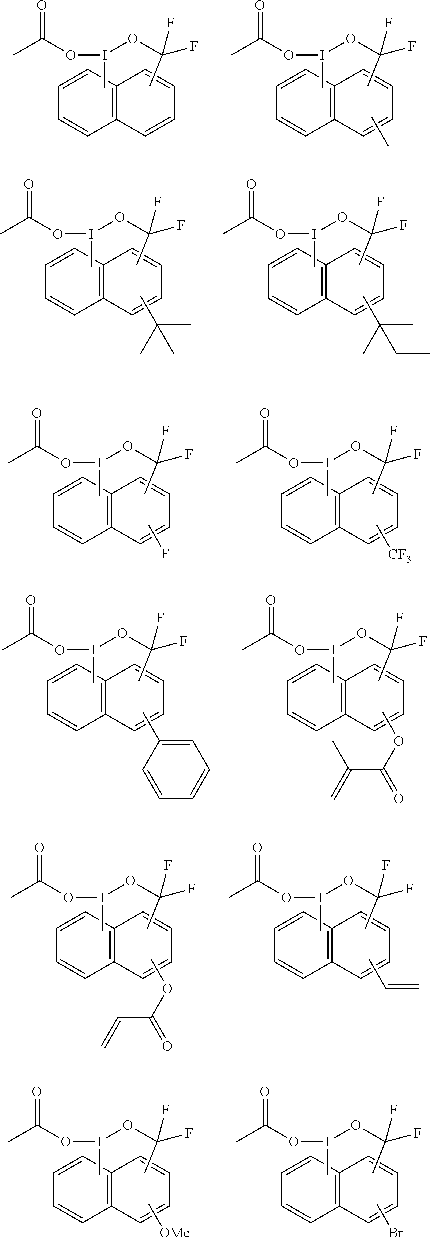

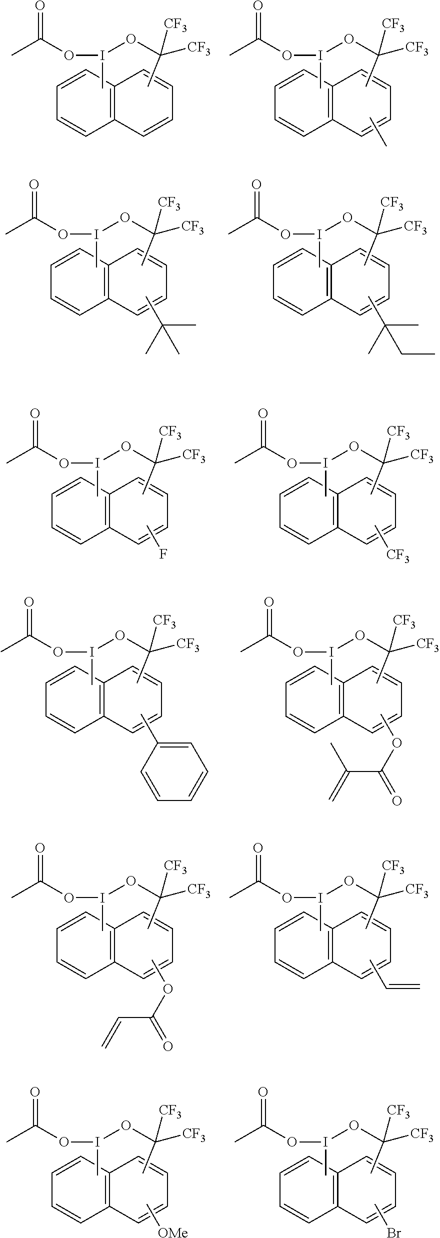

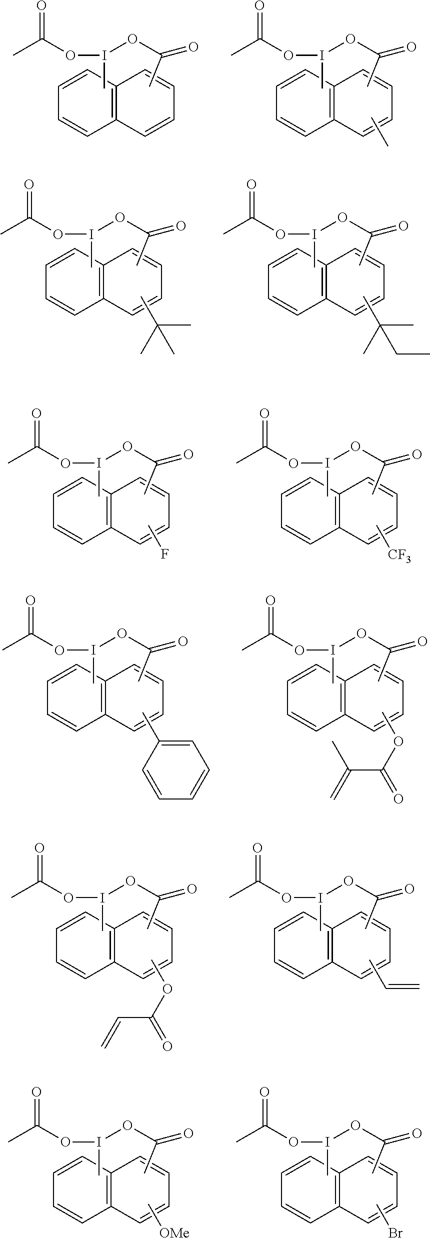

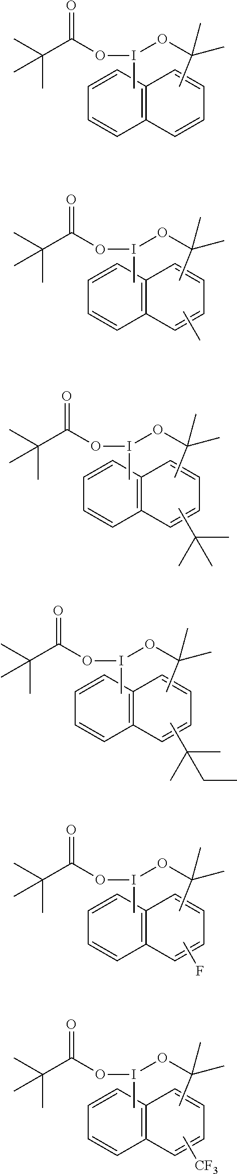

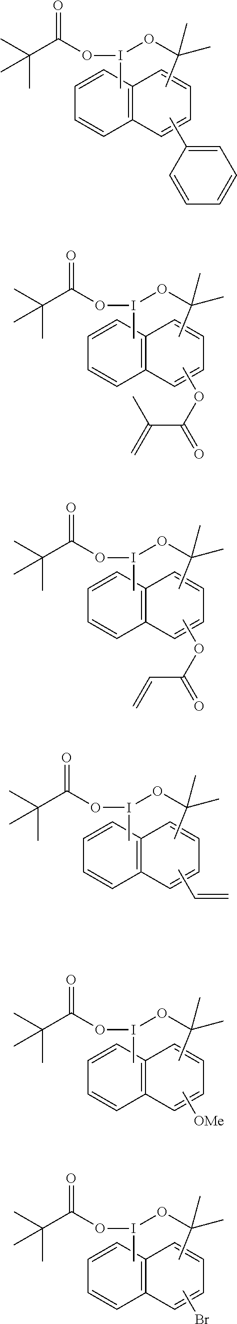

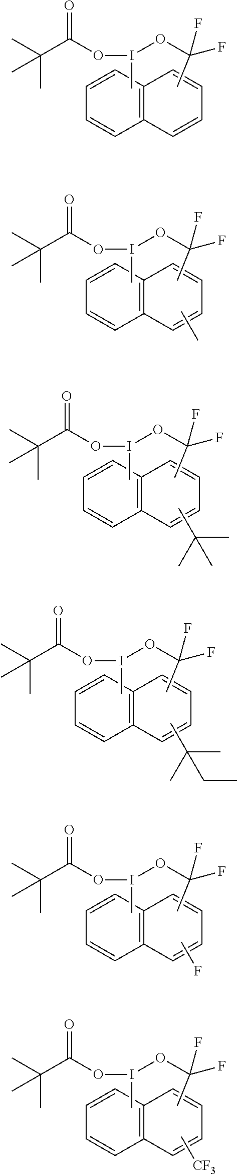

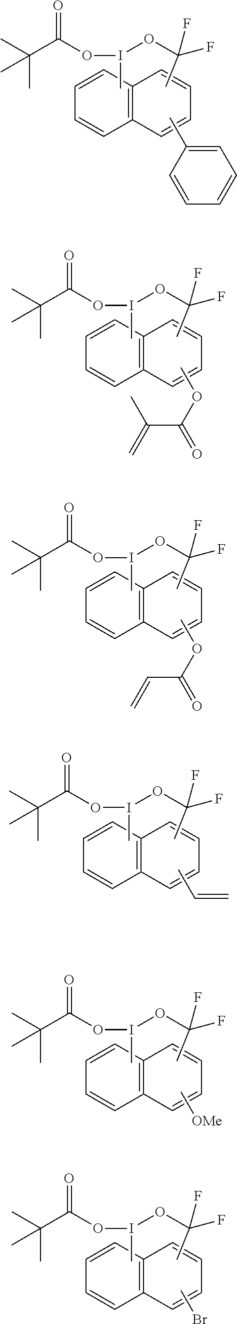

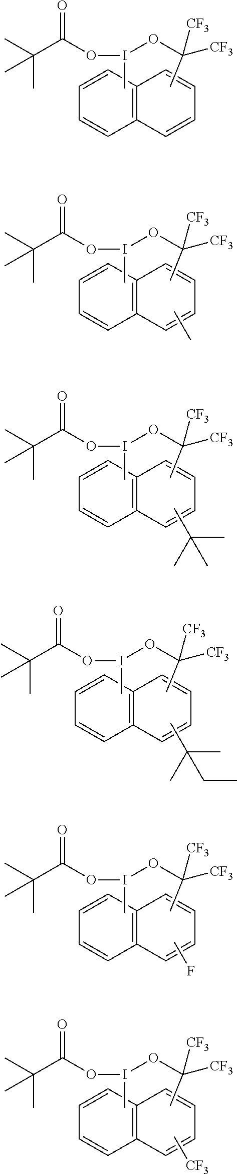

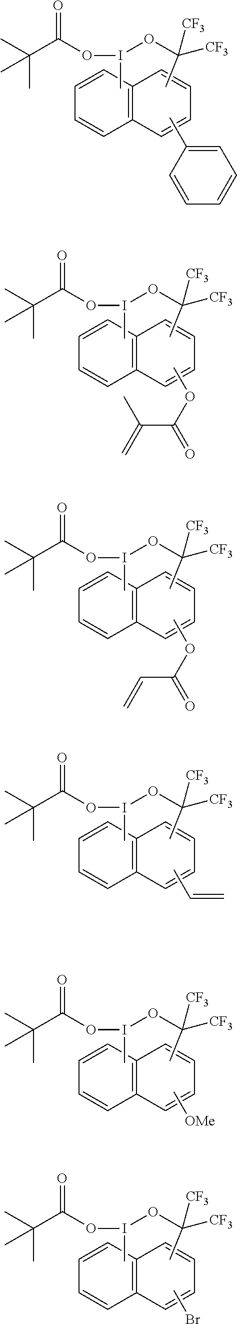

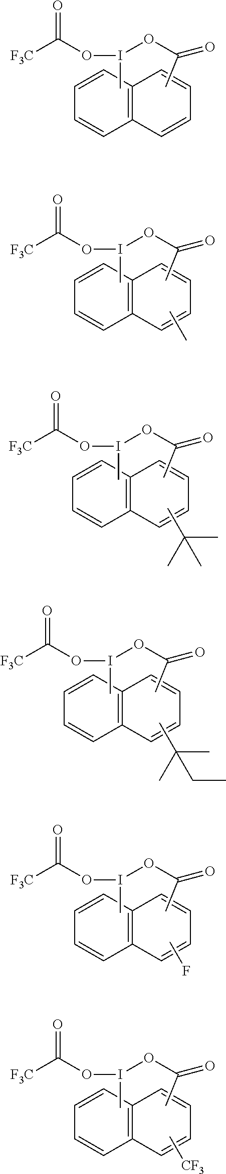

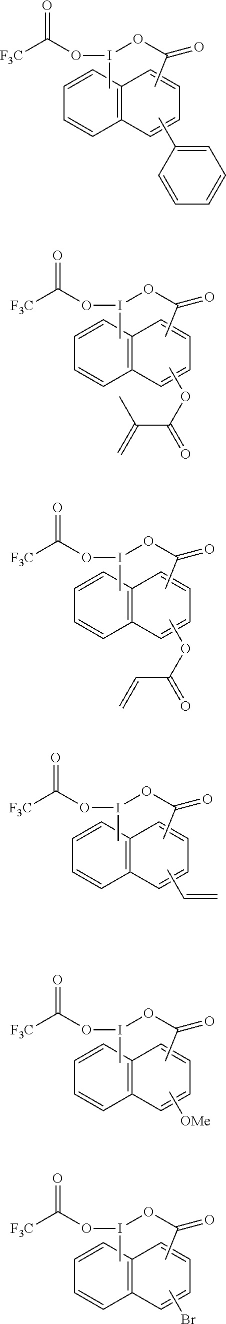

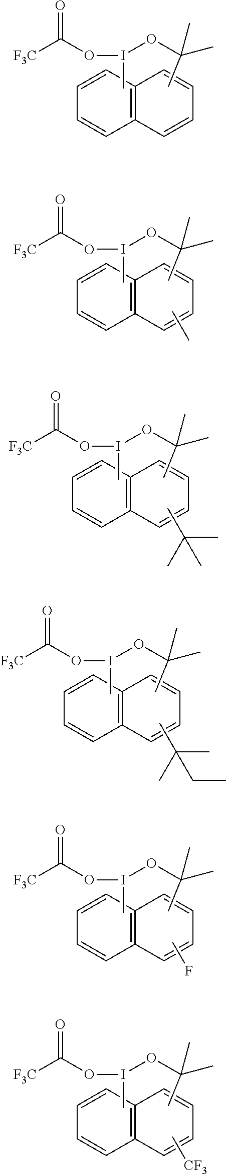

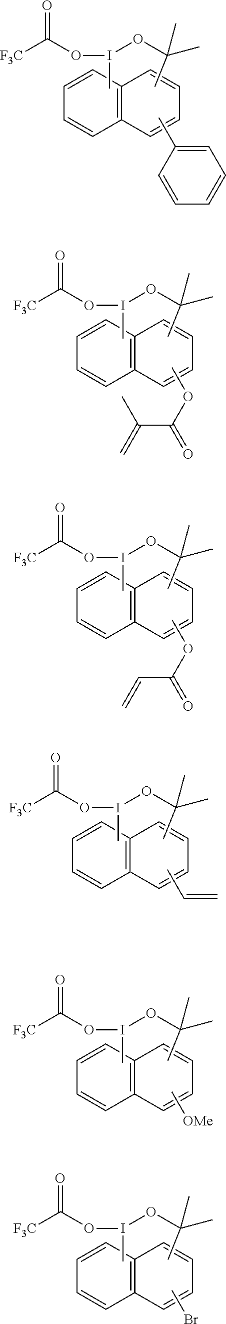

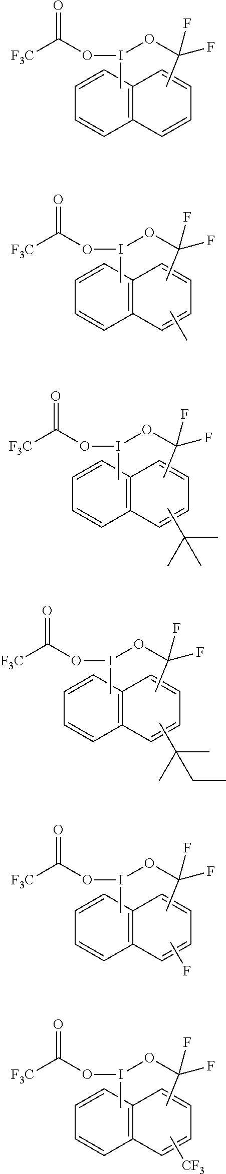

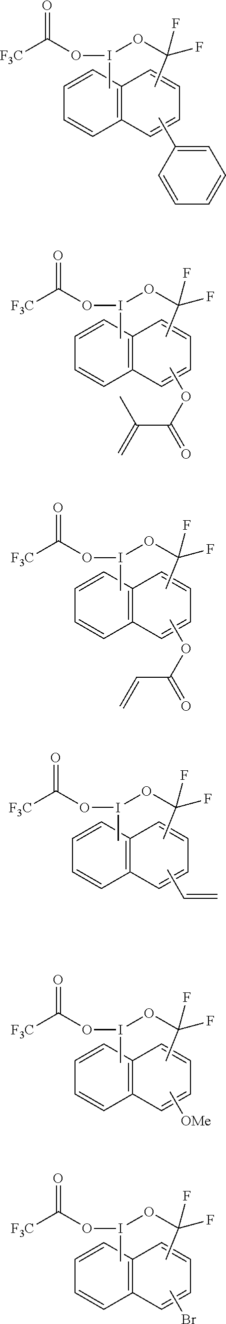

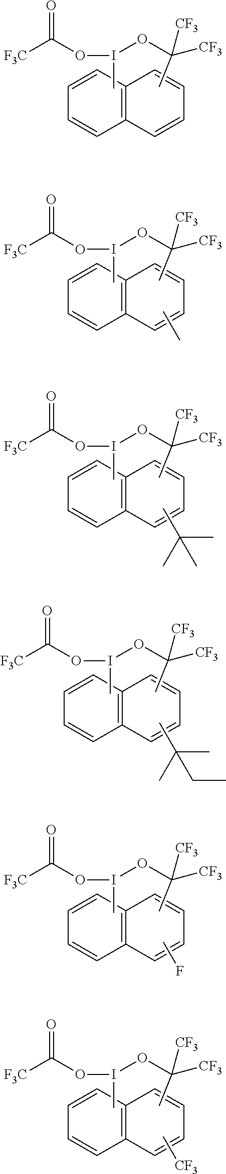

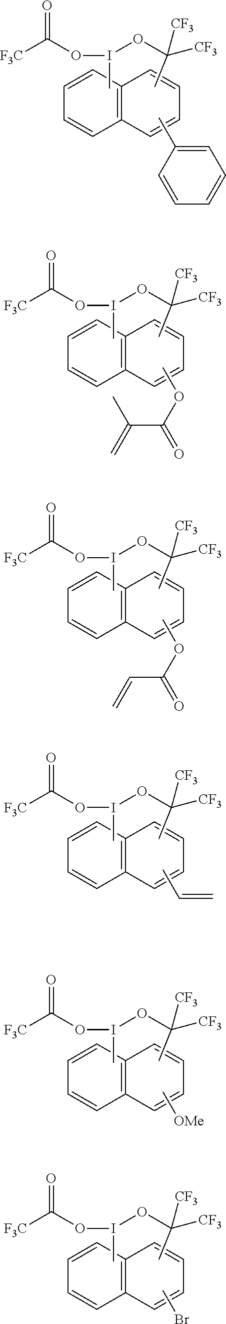

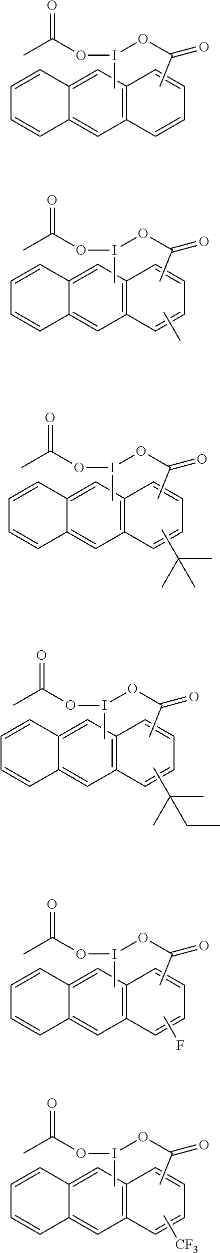

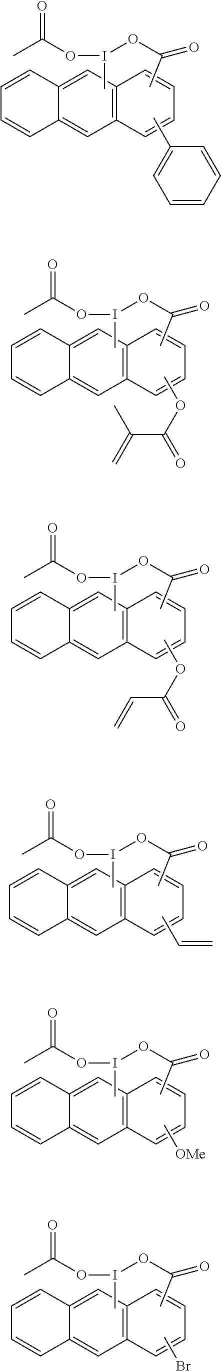

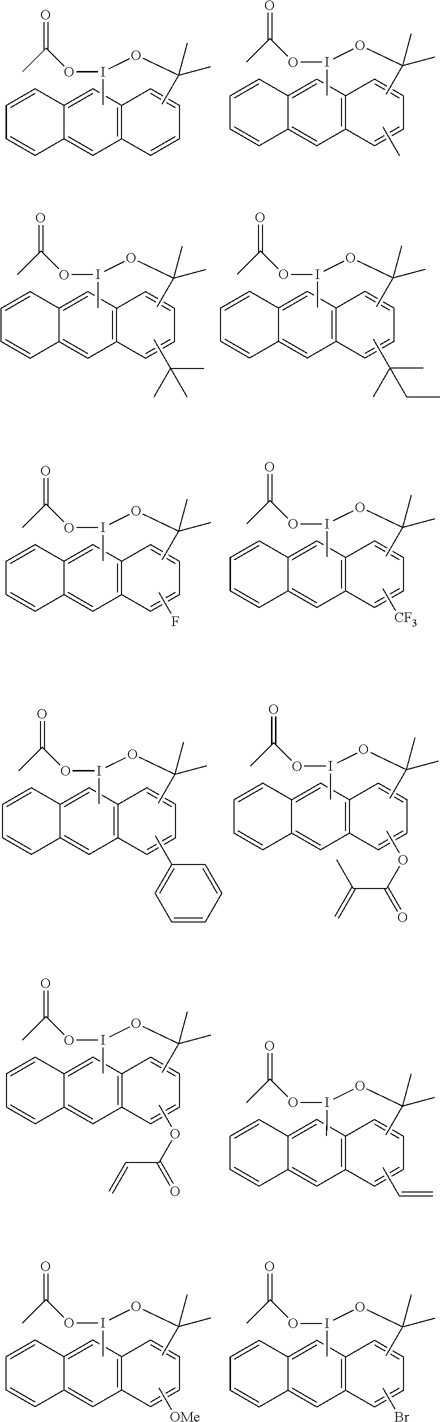

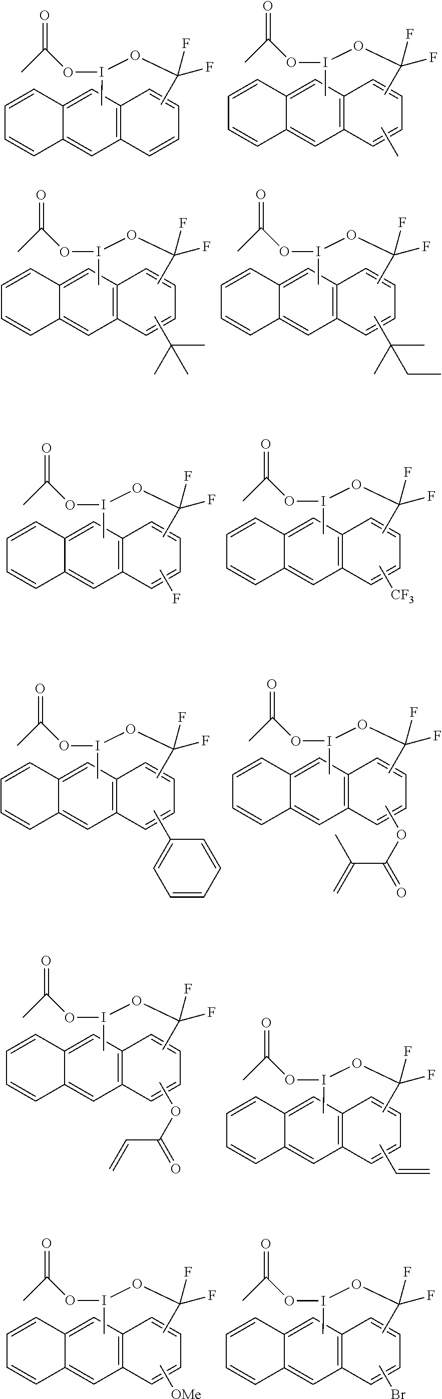

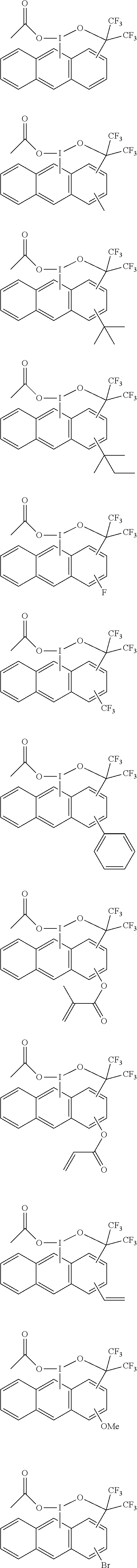

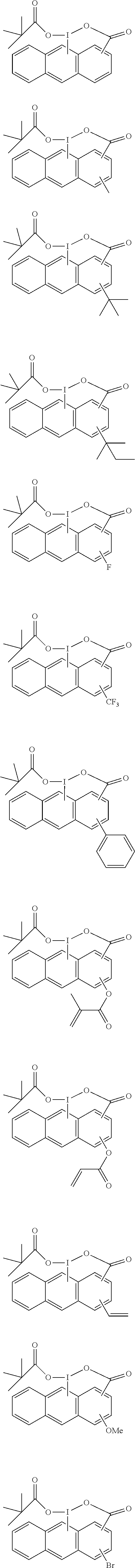

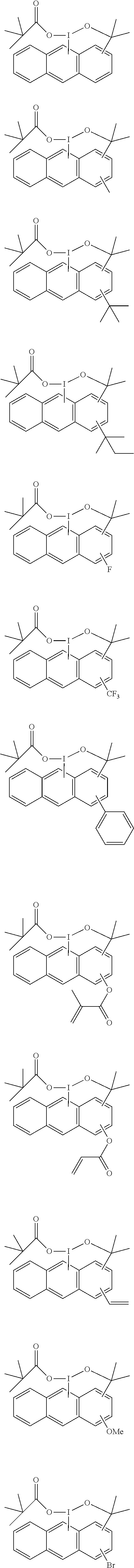

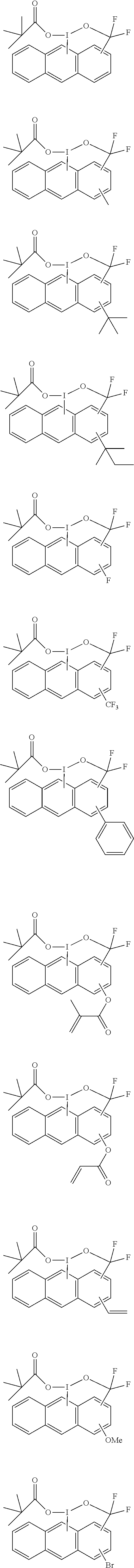

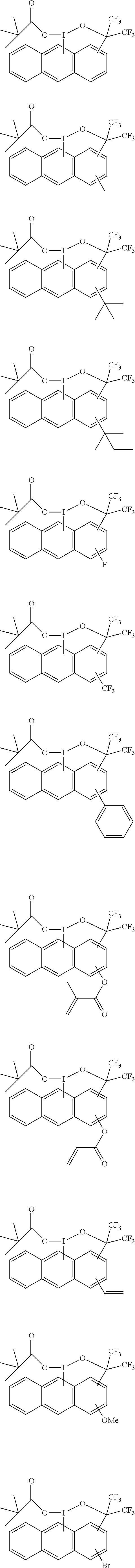

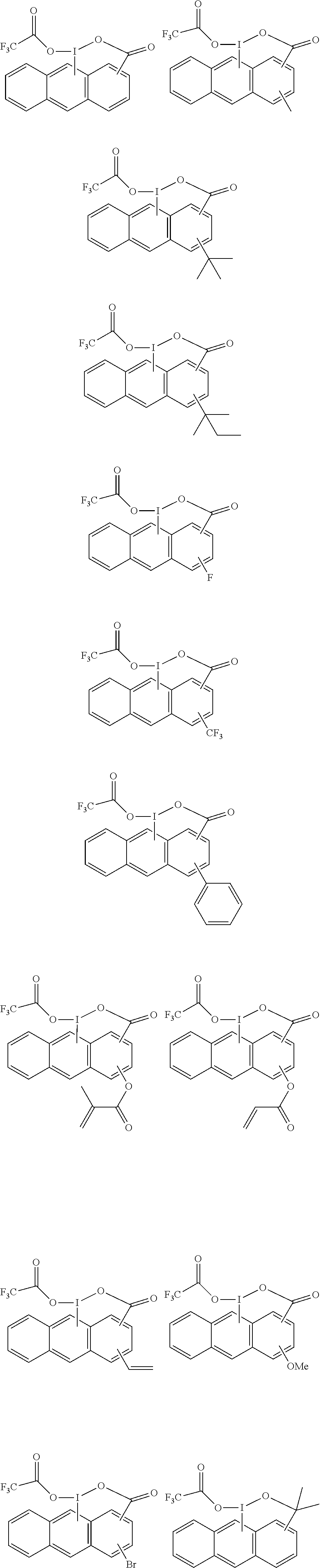

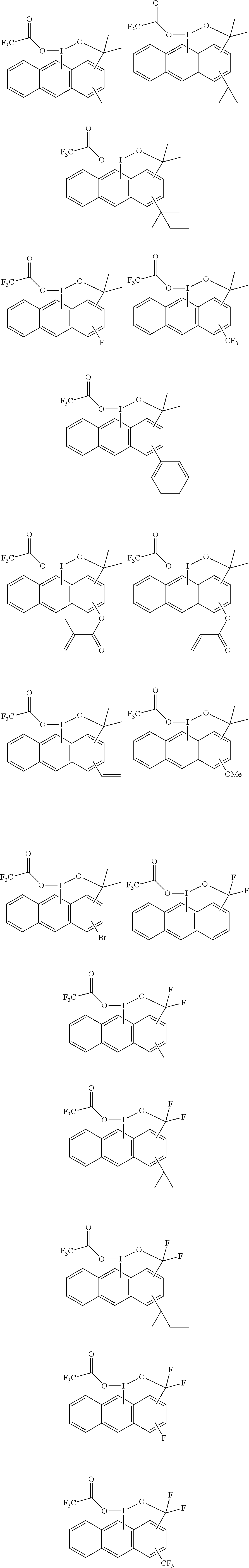

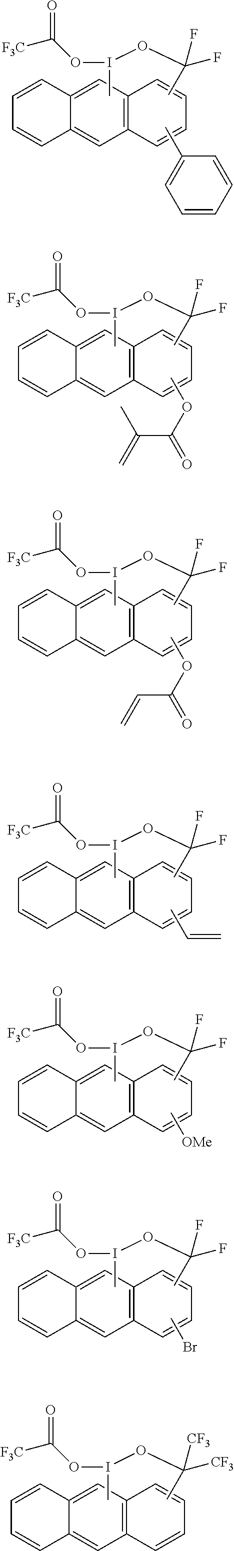

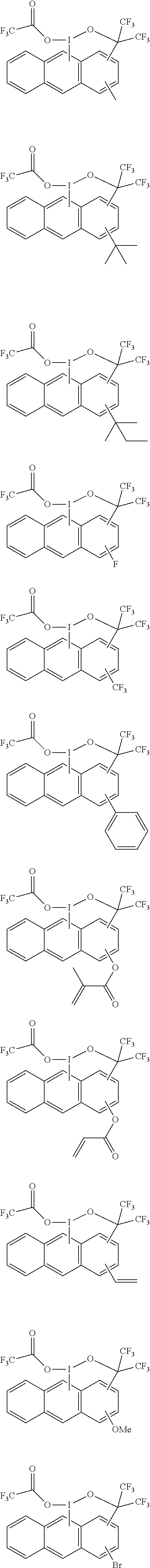

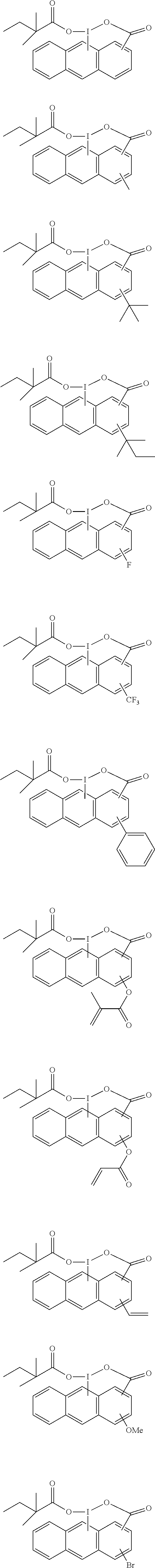

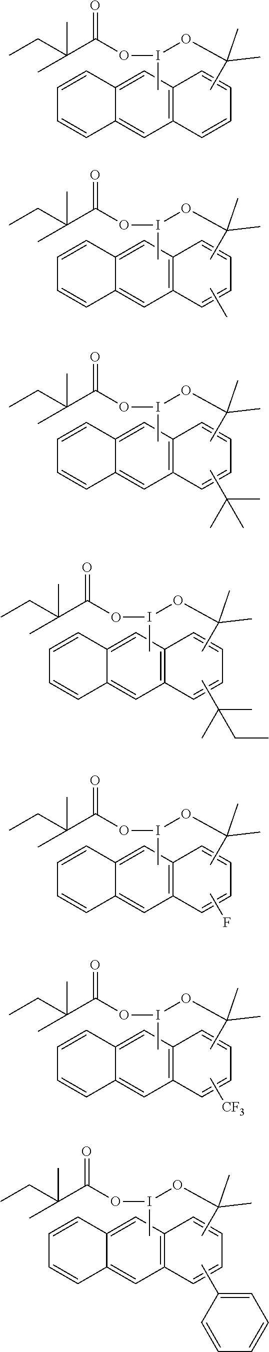

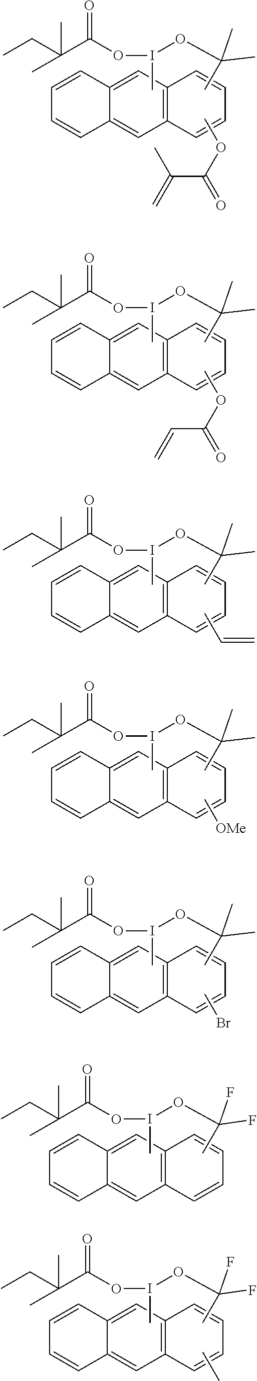

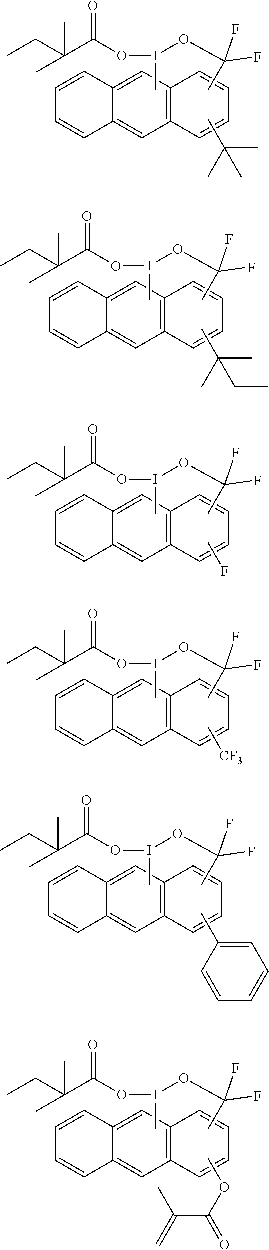

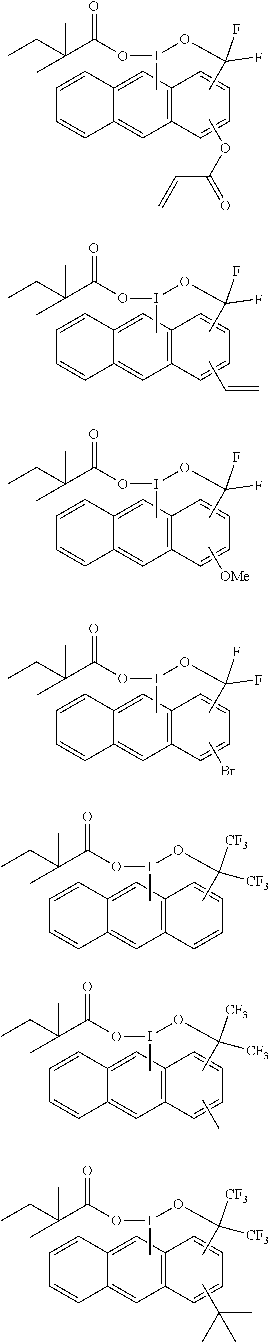

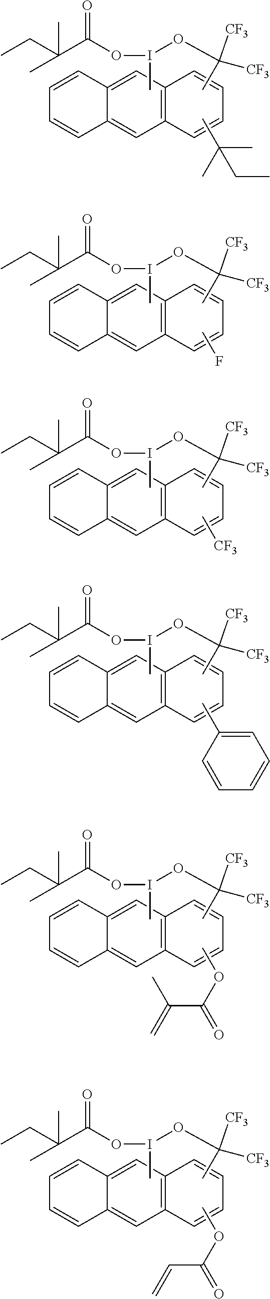

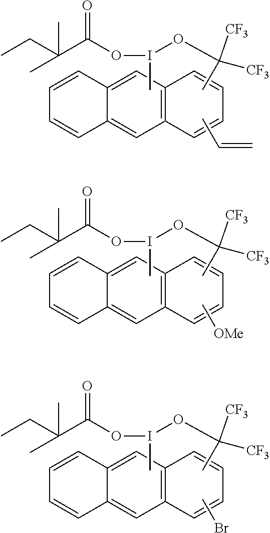

In the general formula (2), “m1” represents an integer of 0 to 2.

When “ml” is 0, “n1” represents an integer of 1 to 3, “n2” represents an integer of 0 to 5, and 1≤(n1+n2)≤6 is satisfied.

When “ml” is 1, “n1” represents an integer of 1 to 3, “n2” represents an integer of 0 to 7, and 1≤(n1+n2)≤8 is satisfied.

When “m1” is 2, “n1” represents an integer of 1 to 3, “n2” represents an integer of 0 to 9, and 1≤(n1+n2)≤10 is satisfied.

In the general formula (2), R¹¹ and R¹² each independently represent a halogen atom or a hydrocarbyl group having 1 to 10 carbon atoms and optionally containing a heteroatom, the R¹¹ and the R¹² optionally being bonded to each other to form a ring together with the carbon atoms bonded thereto and the atoms between the carbon atoms. Examples of the halogen atom include a fluorine atom, a chlorine atom, a bromine atom, and an iodine atom. The hydrocarbyl group having 1 to 10 carbon atoms may be saturated or unsaturated, and may be linear, branched, or cyclic. Specific examples thereof include: alkyl groups having 1 to 10 carbon atoms, such as a methyl group, an ethyl group, a propyl group, an isopropyl group, an n-butyl group, an isobutyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups having 3 to 10 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, and an adamantyl group; alkenyl groups, such as a vinyl group and an allyl group; aryl groups having 6 to 10 carbon atoms, such as a phenyl group and a naphthyl group; and groups obtained by combining these groups. Furthermore, part or all of the hydrogen atoms of the hydrocarbyl groups may be substituted with a group containing a heteroatom, such as an oxygen atom, a sulfur atom, a nitrogen atom, or a halogen atom, and part of the —CH₂— of the hydrocarbyl groups may be substituted with a group containing a heteroatom such as an oxygen atom, a sulfur atom, or a nitrogen atom. The resulting hydrocarbyl groups may contain a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, a carboxylic acid anhydride (—C(═O)—O—C(═O)—), etc. As R¹¹ and R¹², a hydrocarbyl group having 1 to 4 carbon atoms is preferable.

In the general formula (2), R¹³ represents a halogen atom or a hydrocarbyl group having 1 to 40 carbon atoms and optionally containing a heteroatom. Examples of the halogen atom include a fluorine atom, a chlorine atom, a bromine atom, and an iodine atom. The hydrocarbyl group having 1 to 40 carbon atoms may be saturated or unsaturated, and may be linear, branched, or cyclic. Specific examples thereof include: alkyl groups having 1 to 40 carbon atoms, such as a methyl group, an ethyl group, a propyl group, an isopropyl group, an n-butyl group, an isobutyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups having 3 to 40 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group, and an adamantylmethyl group; and aryl groups having 6 to 40 carbon atoms, such as a phenyl group, a naphthyl group, and an anthracenyl group. Furthermore, part or all of the hydrogen atoms of the hydrocarbyl groups may be substituted with a group containing a heteroatom, such as an oxygen atom, a sulfur atom, a nitrogen atom, or a halogen atom, and part of the —CH₂— of the hydrocarbyl groups may be substituted with a group containing a heteroatom such as an oxygen atom, a sulfur atom, or a nitrogen atom. The resulting hydrocarbyl groups may contain a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, a carboxylic acid anhydride (—C(═O)—O—C(═O)—), etc. When “n2” is 2 to 9, the R¹³s may be identical to or different from each other, and the R¹³s may be bonded to each other to form a ring together with the carbon atoms of the aromatic ring bonded thereto.

Specific examples of the hypervalent iodine compound represented by the general formula (2) include the following, but are not limited thereto.

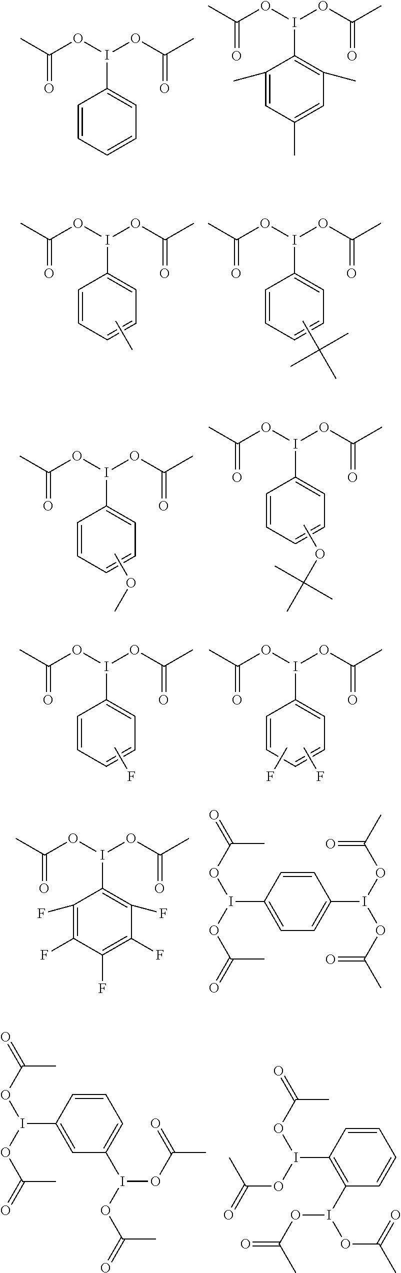

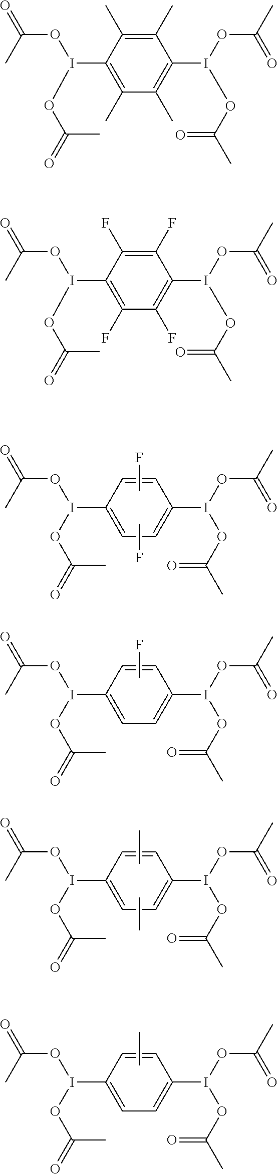

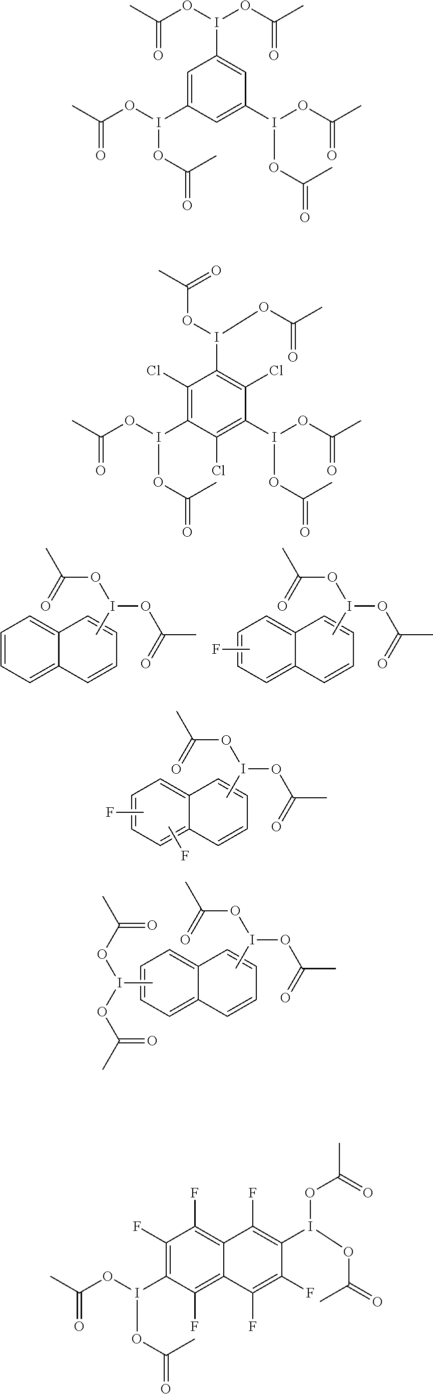

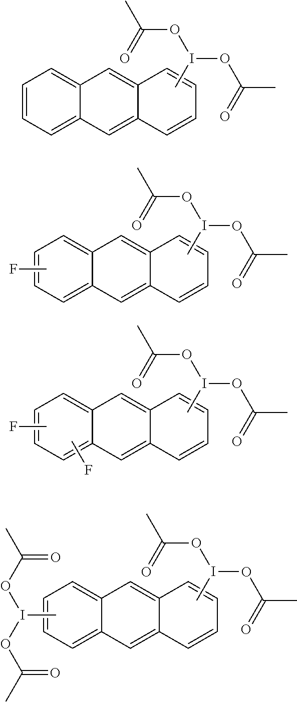

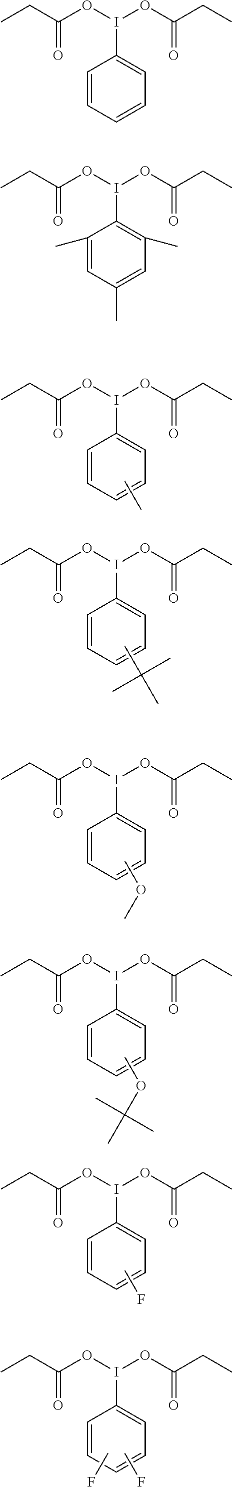

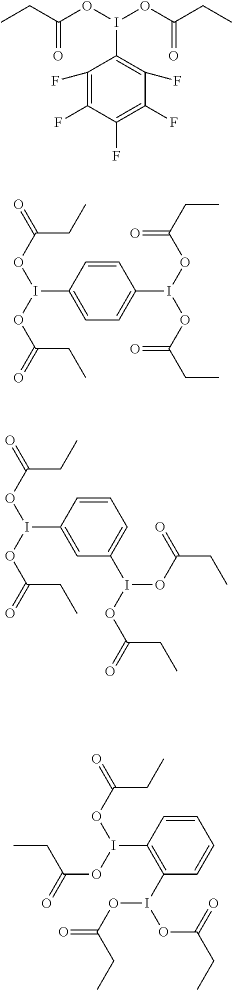

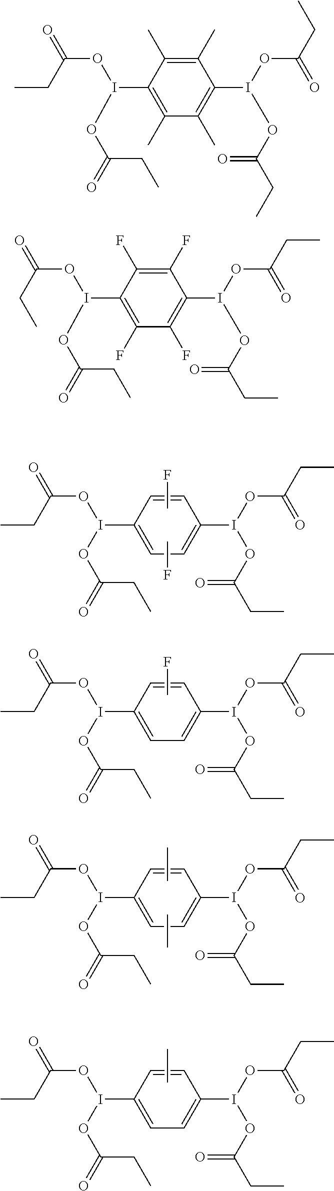

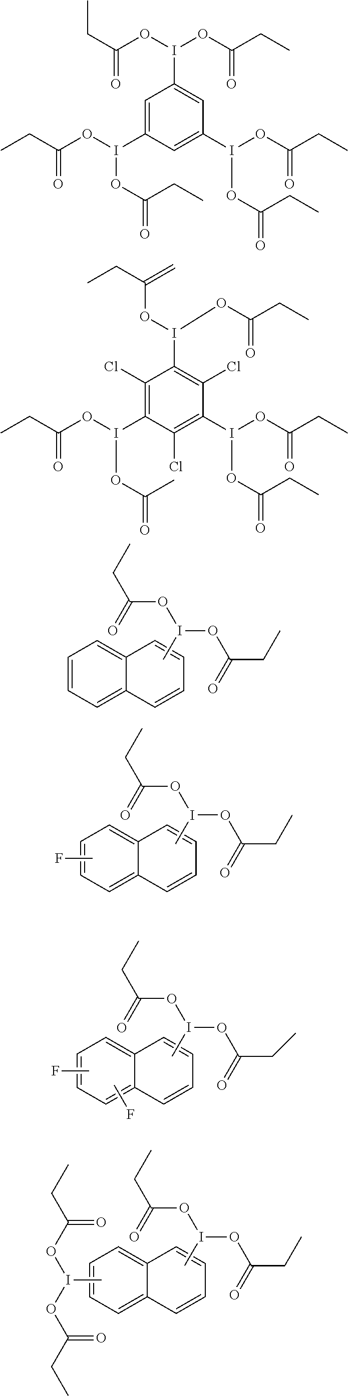

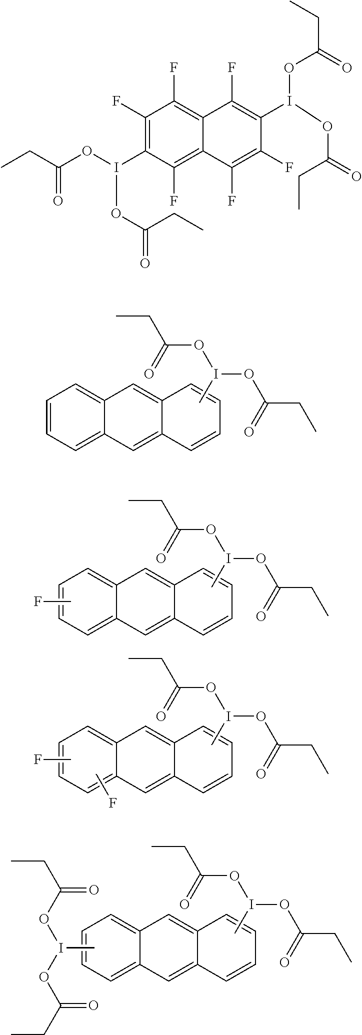

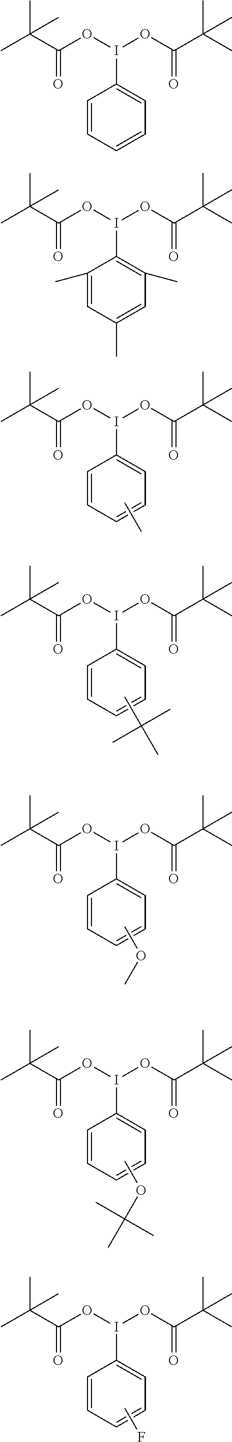

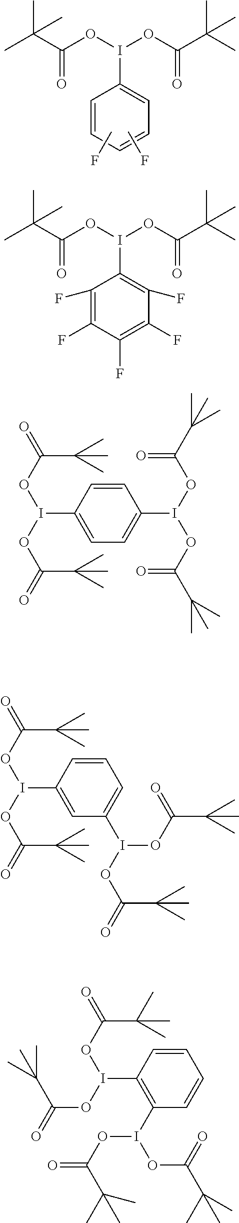

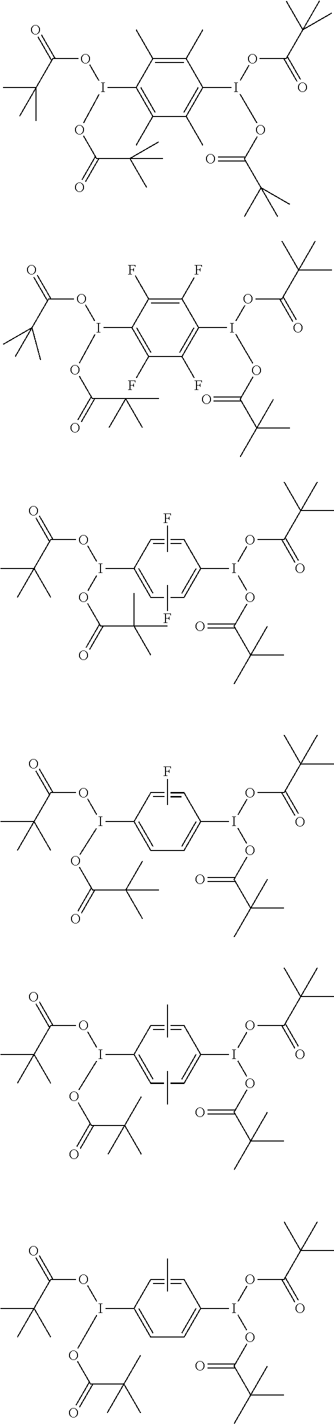

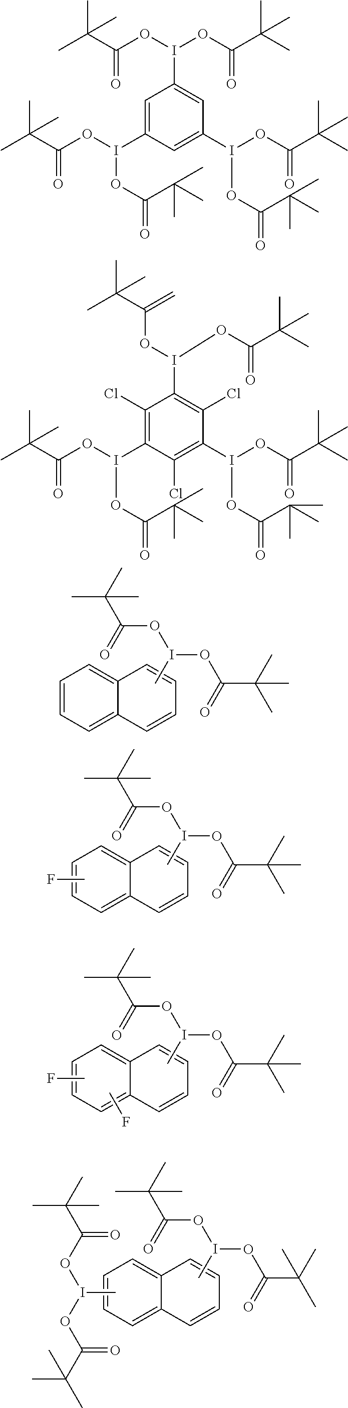

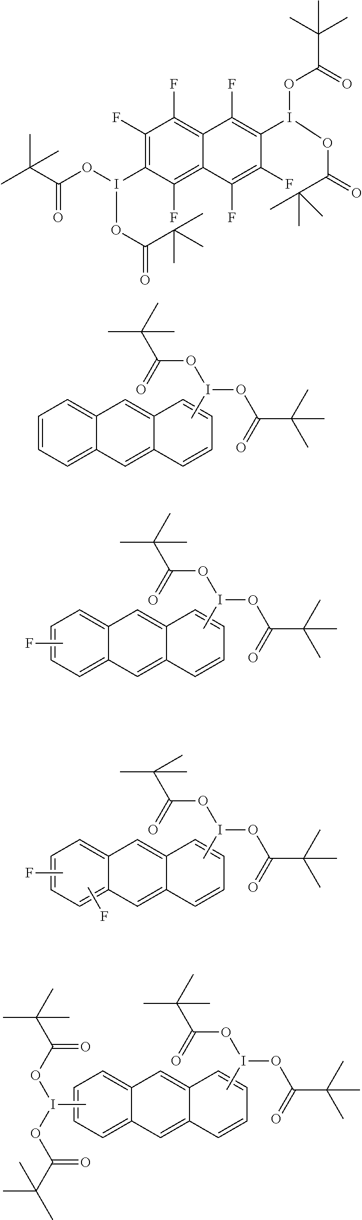

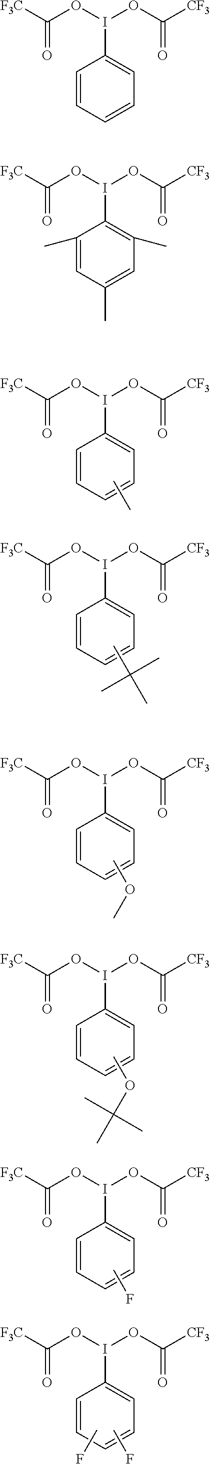

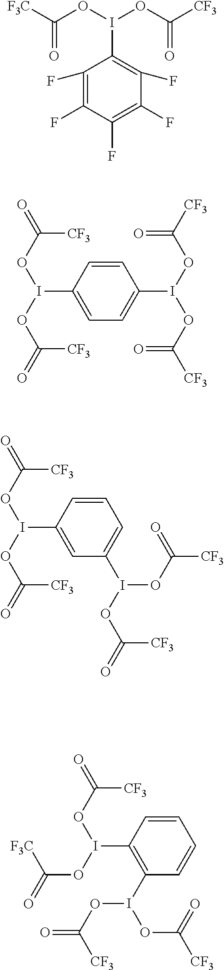

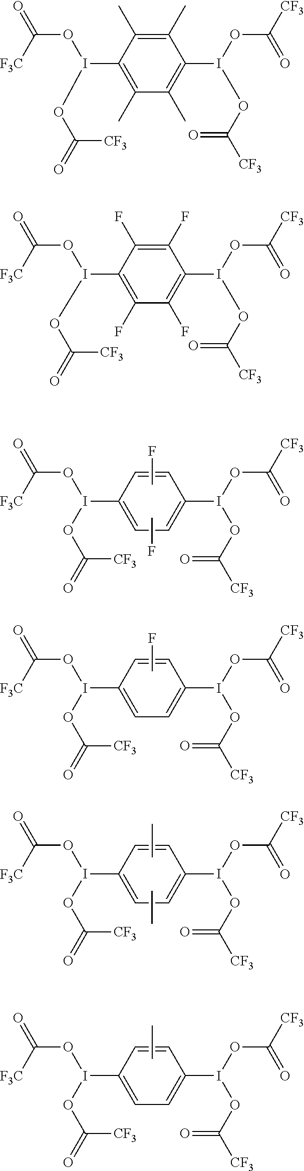

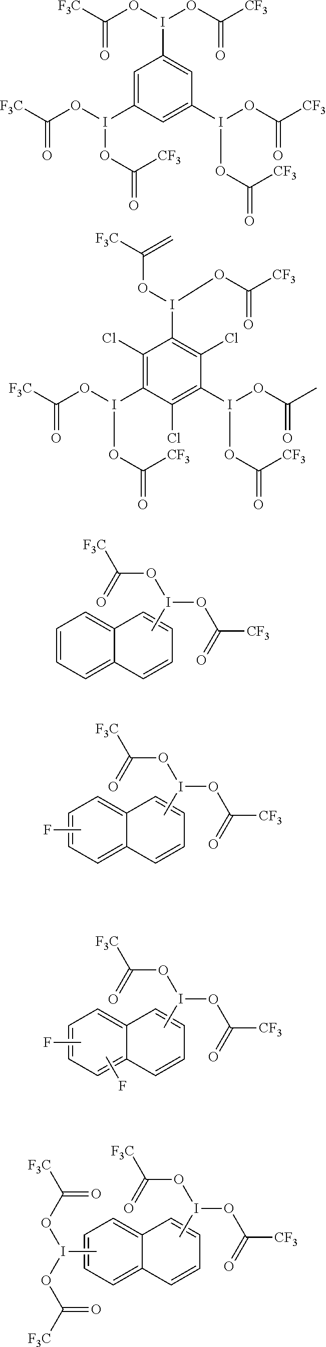

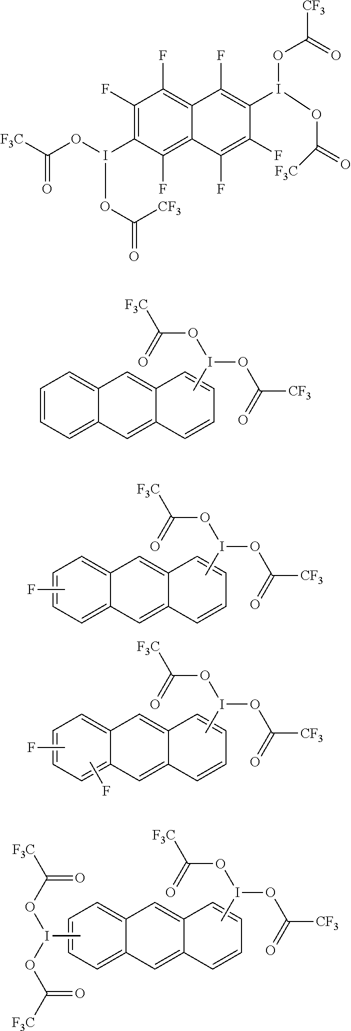

As the hypervalent iodine compound used in the step (i) of the inventive manufacturing method, a hypervalent iodine compound represented by the general formula (1) alone may be used, a hypervalent iodine compound represented by the general formula (2) alone may be used, or a combination of a hypervalent iodine compound represented by the general formula (1) and a hypervalent iodine compound represented by the general formula (2) may be used. Furthermore, one kind of each of the hypervalent iodine compound represented by the general formula (1) and the hypervalent iodine compound represented by the general formula (2) may be used, or a combination of two or more different kinds thereof may be used.

### [Carboxy-Group-Containing Polymer]

The carboxy-group-containing polymer used in the step (i) of the inventive manufacturing method preferably includes a carboxy-group-containing repeating unit. As the carboxy-group-containing repeating unit, those represented by the following general formula (3) are particularly preferable.

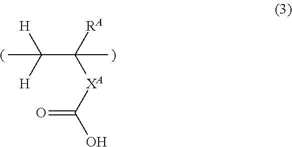

In the formula, R^{A} represents a hydrogen atom, a halogen atom, a methyl group, or a trifluoromethyl group; and

X^{A} represents a single bond, a phenylene group, a naphthylene group, or *—C(═O)—O—X^{A1}—, X^{A1} represents a saturated hydrocarbylene group having 1 to 10 carbon atoms, a phenylene group, or a naphthylene group, the saturated hydrocarbylene group optionally containing at least one selected from a hydroxy group, an ether bond, an ester bond, and a lactone ring, and “*” represents an attachment point to the carbon atom of the main chain.

In the general formula (3), R^{A} represents a hydrogen atom, a halogen atom, a methyl group, or a trifluoromethyl group. X^{A} represents a single bond, a phenylene group, a naphthylene group, or *—C(═O)—O—X^{A1}—. X^{A1} represents a saturated hydrocarbylene group having 1 to 10 carbon atoms, a phenylene group, or a naphthylene group, the saturated hydrocarbylene group optionally containing at least one selected from a hydroxy group, an ether bond, an ester bond, and a lactone ring. “*” represents an attachment point to the carbon atom of the main chain.

Specific examples of the carboxy-group-containing repeating unit include the following, but are not limited thereto. Note that, in the following formulae, R^{A} is as defined above.

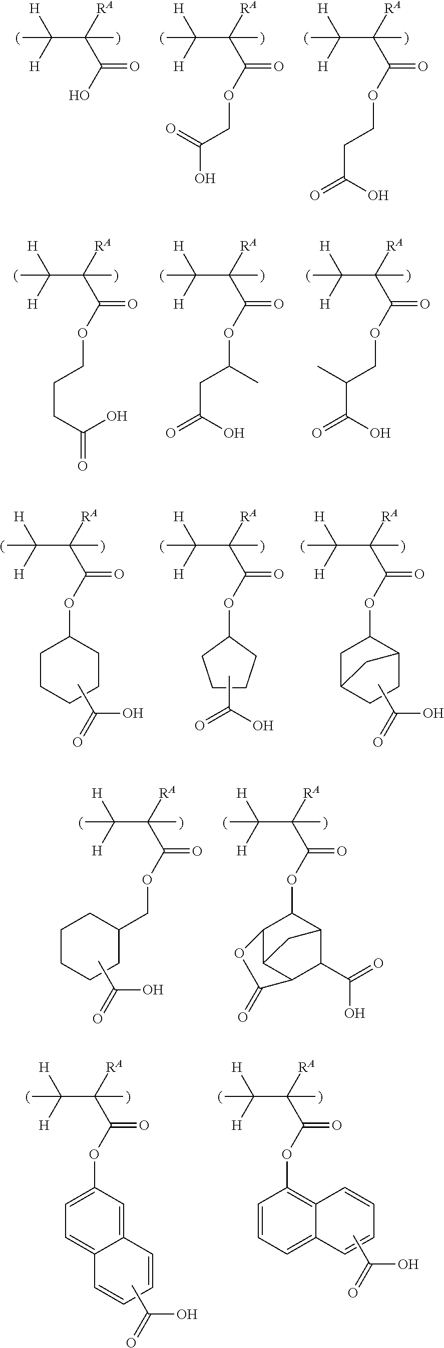

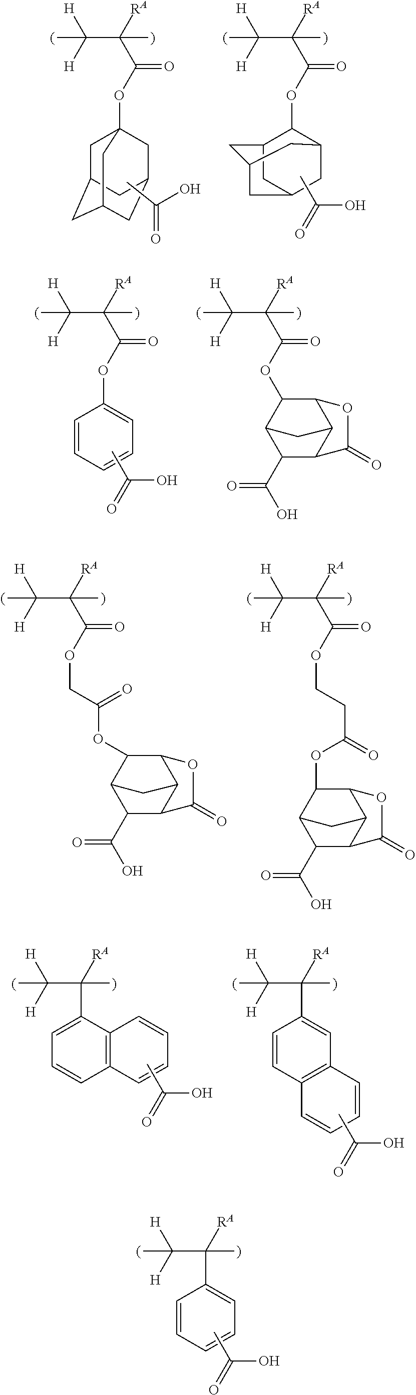

The carboxy-group-containing polymer may further include repeating units (hereinafter, also referred to as other repeating units) other than the carboxy-group-containing repeating unit. The other repeating units are not particularly limited, but preferable are those that may enhance the solvent solubility of a polymer that is hardly soluble in a solvent when having only a repeating unit having a carboxy group. As such a repeating unit, preferable is a repeating unit having a hydrocarbyl group having 1 to 20 carbon atoms and optionally containing at least one selected from a halogen atom, a hydroxy group, a cyano group, a carbonyl group, a nitro group, a sulfonic acid group, an amino group, an isocyanate group, an amide bond, an imide bond, an ester bond, an ether bond, a sulfide bond, a carbonate bond, a lactone ring, and a sultone ring.

Specific examples of the other repeating units include the following, but are not limited thereto. Note that, in the following formulae, R^{A} is as defined above, and each X^{B} independently represent —CH₂— or —O—.

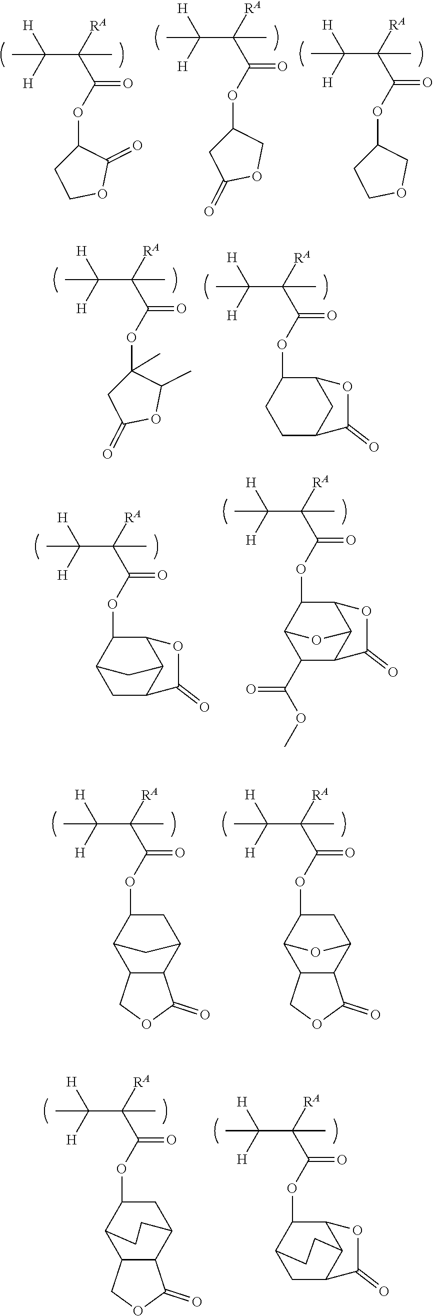

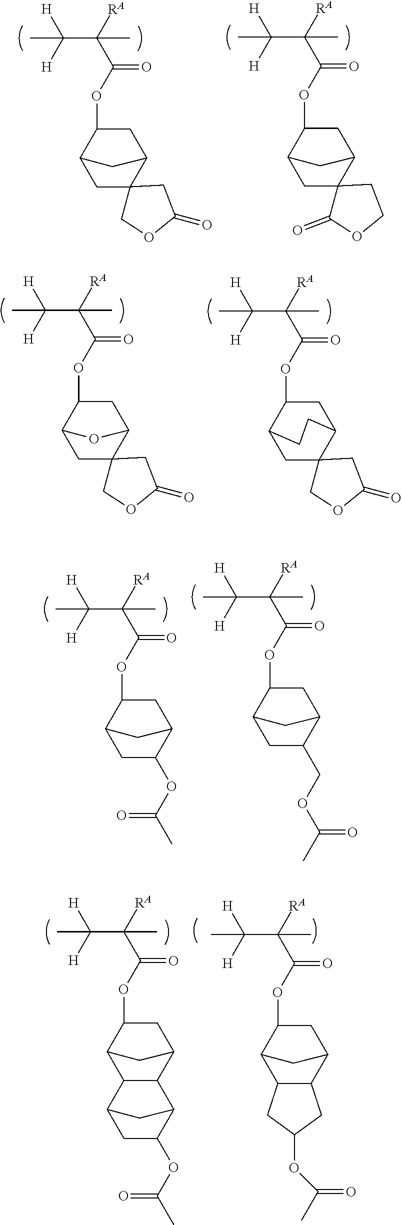

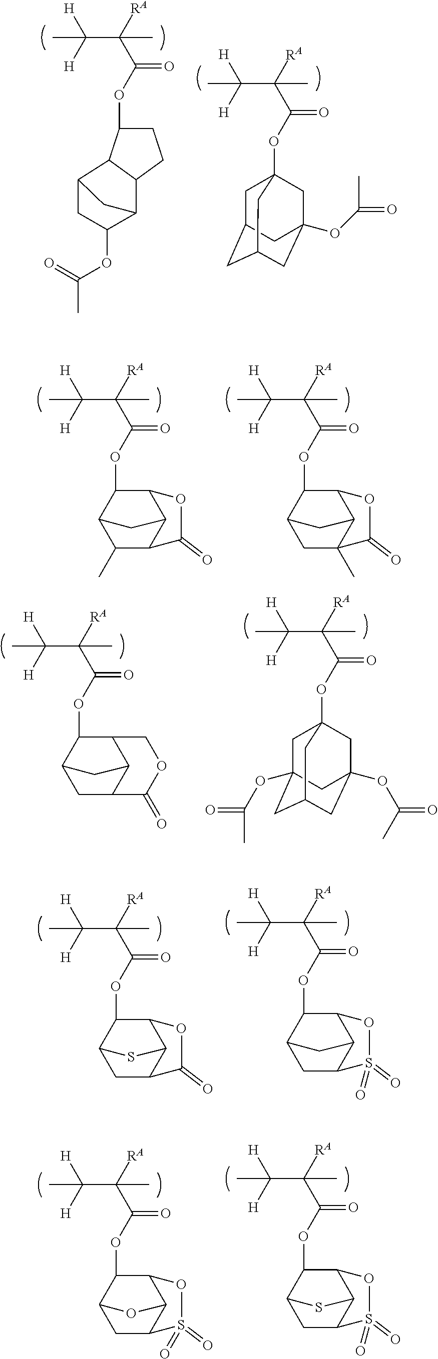

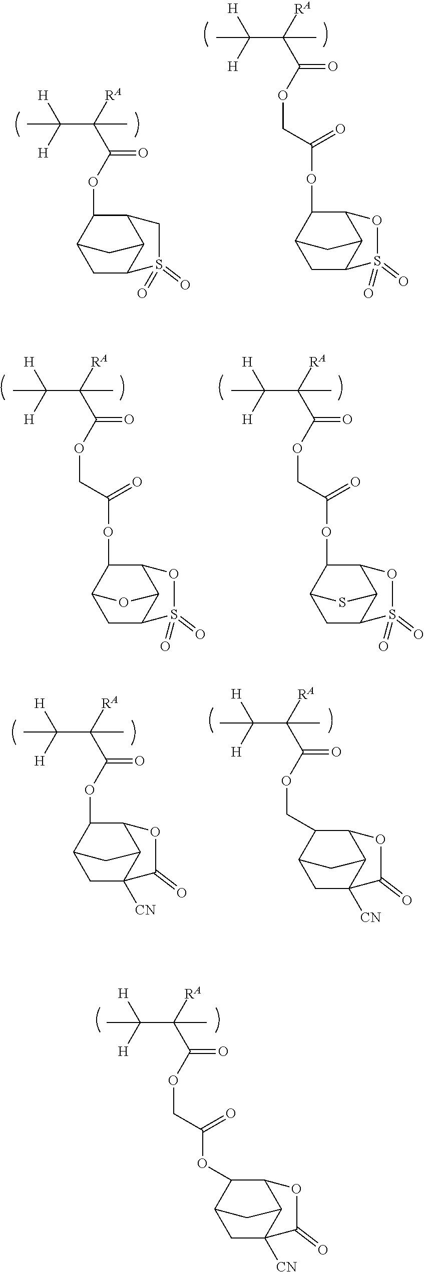

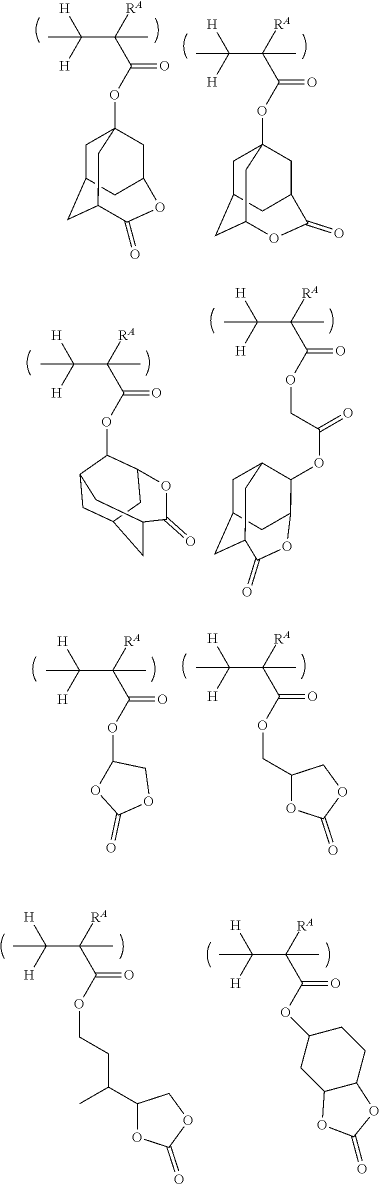

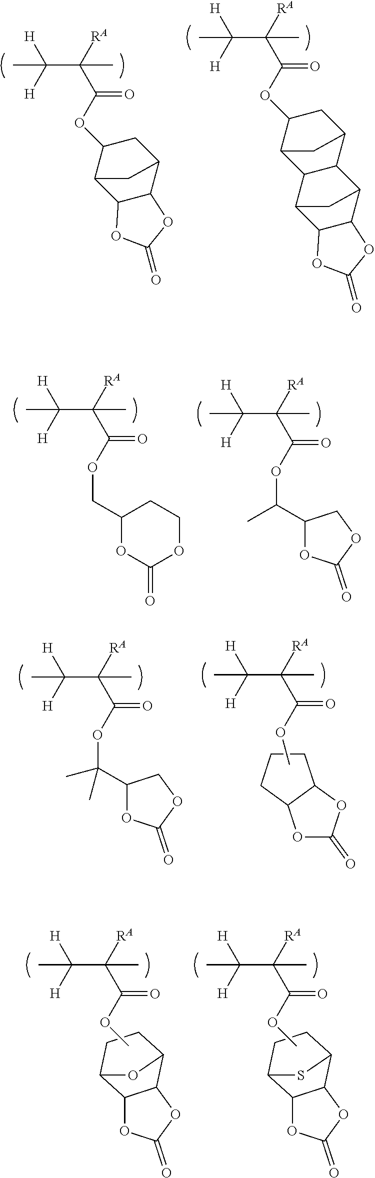

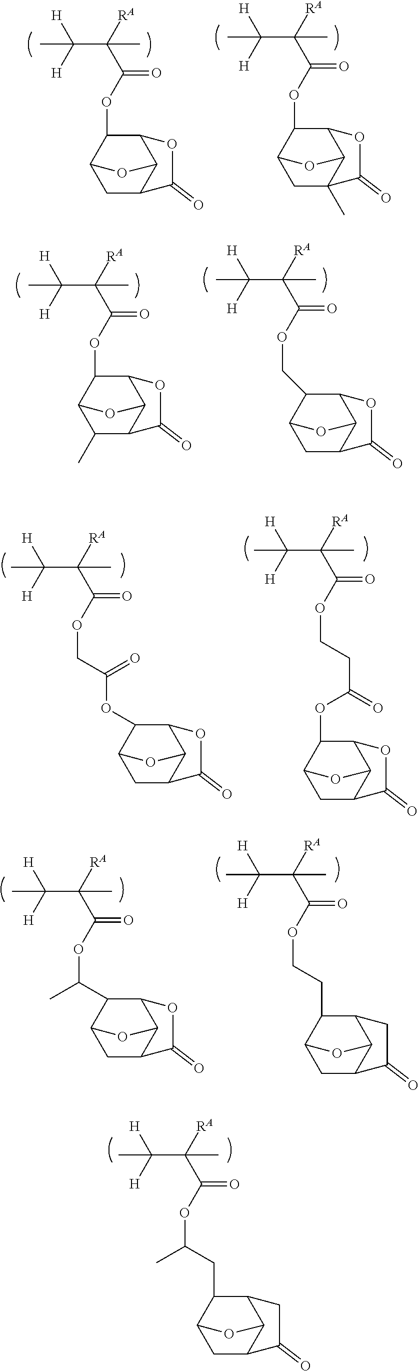

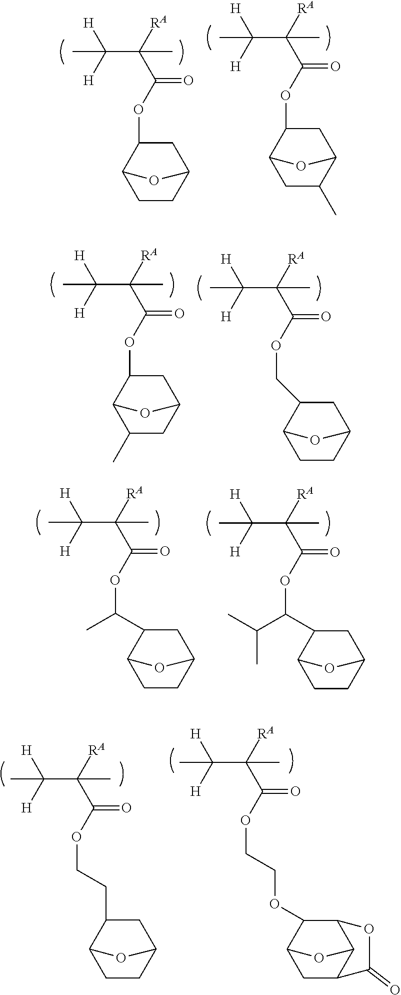

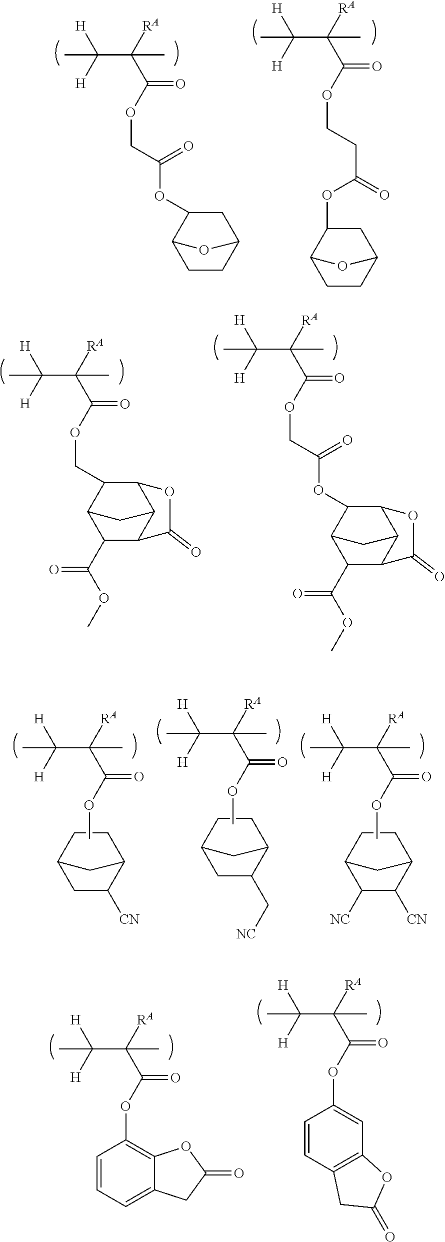

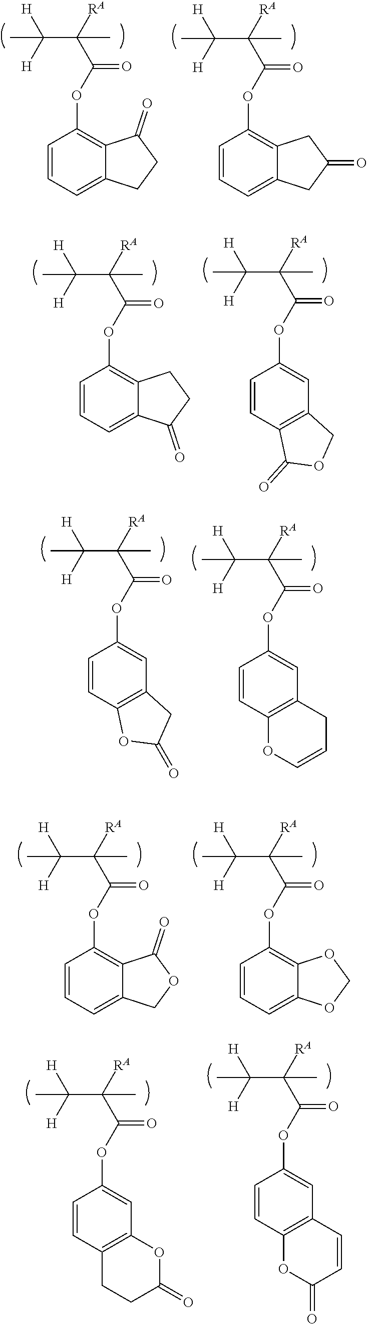

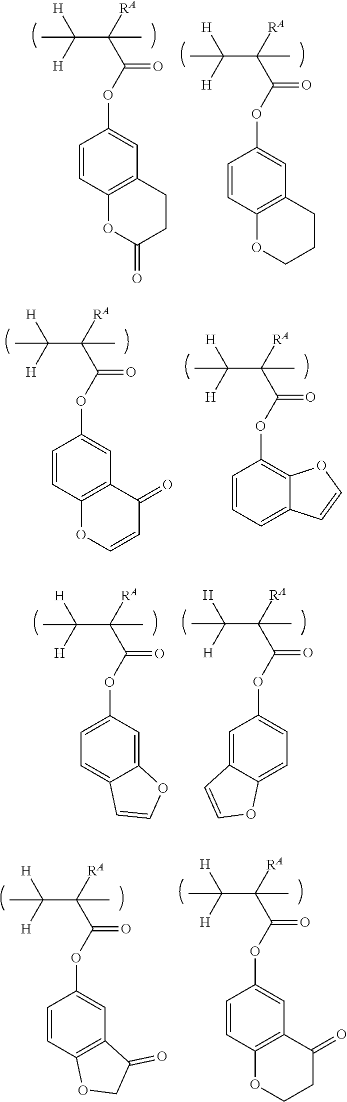

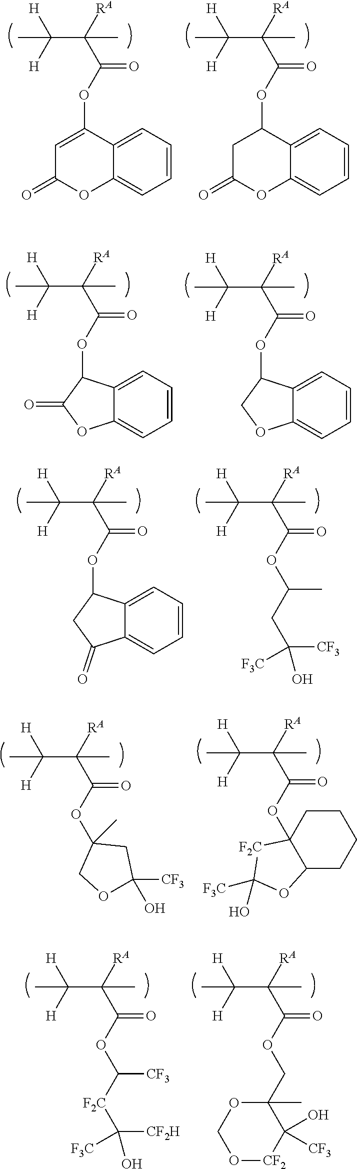

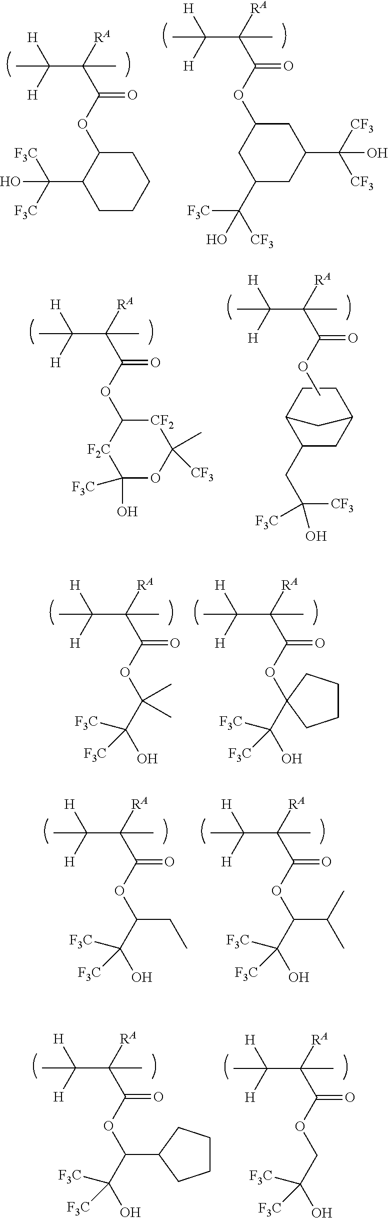

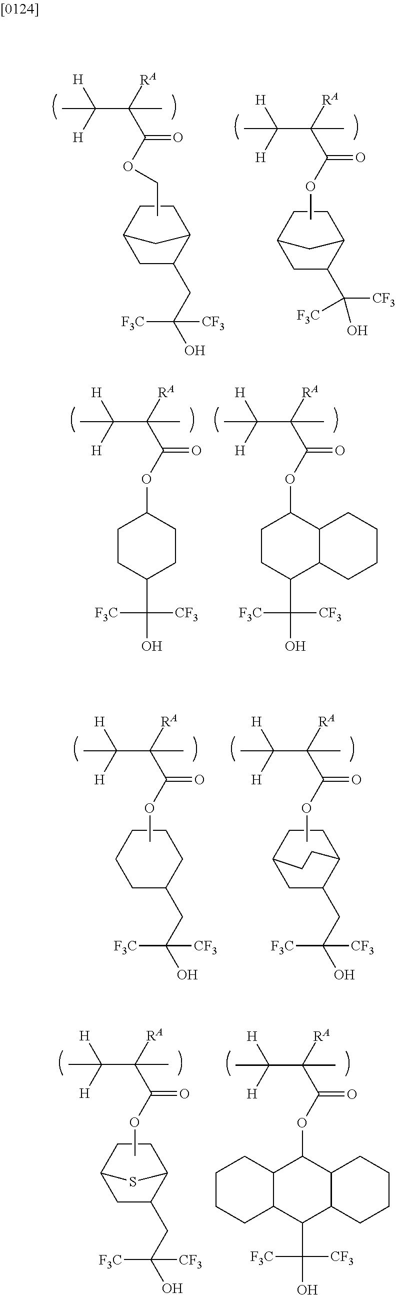

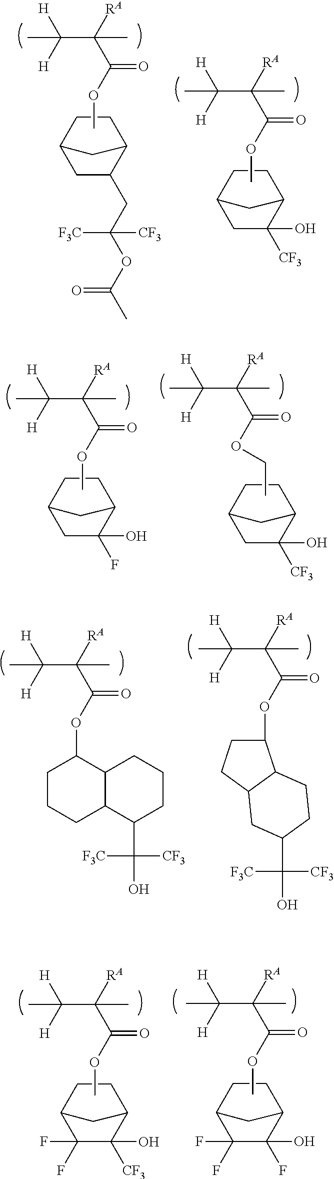

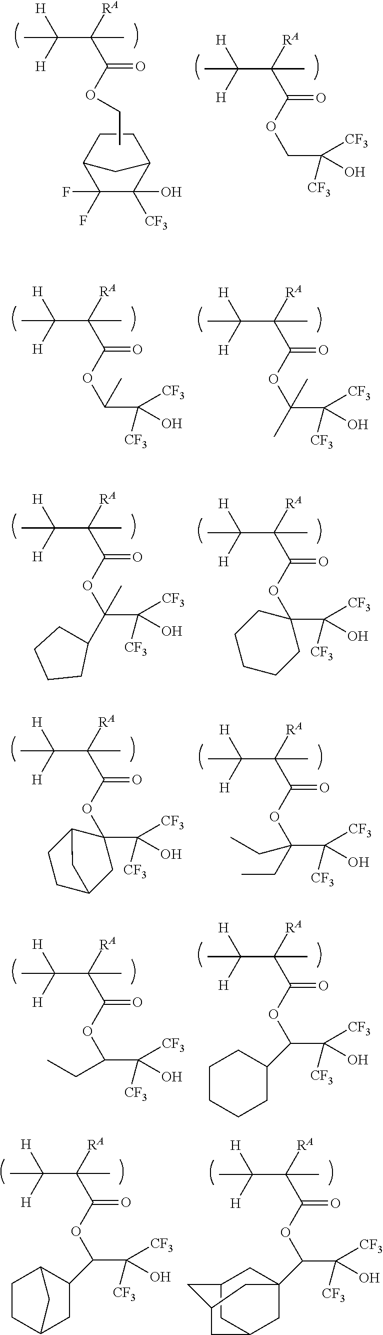

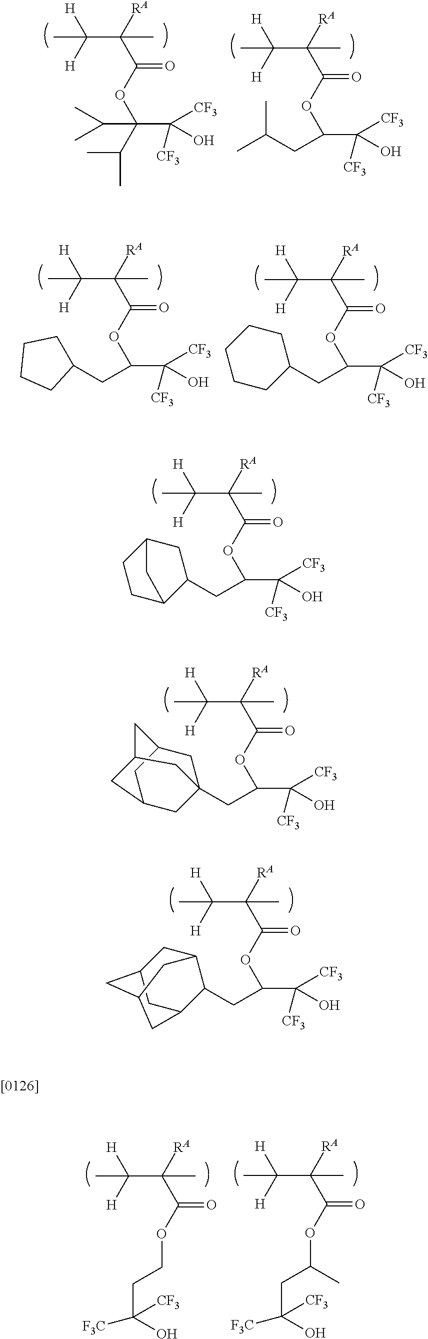

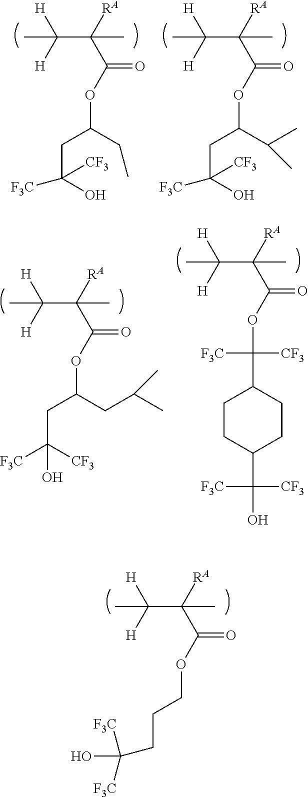

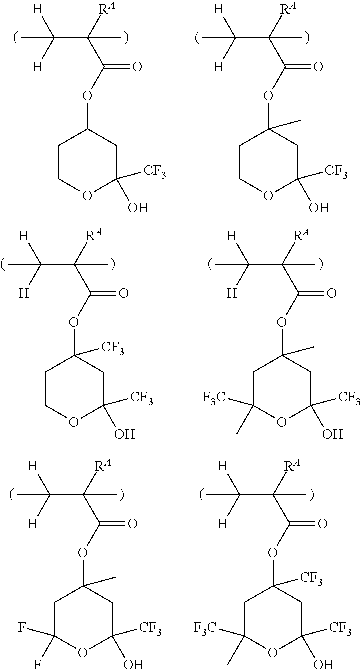

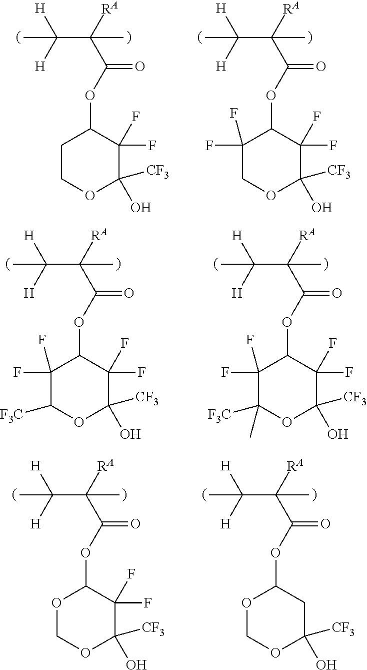

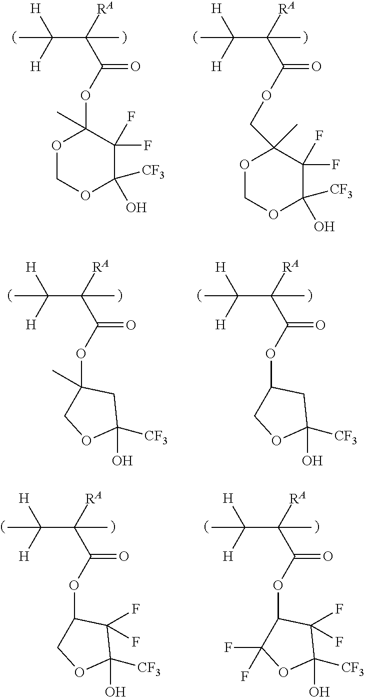

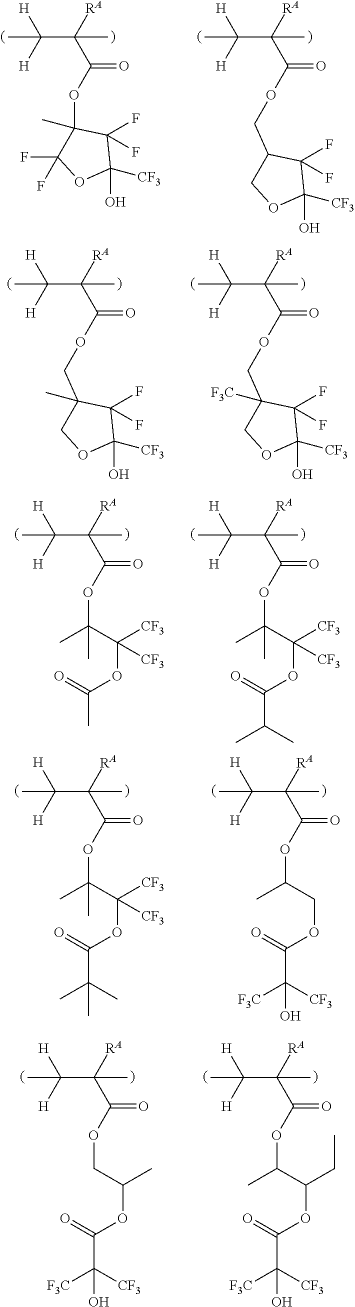

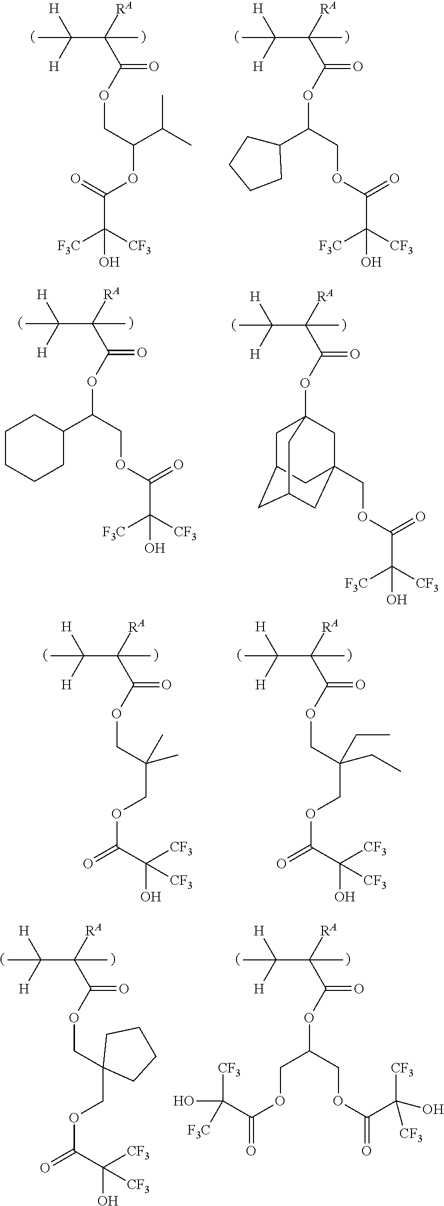

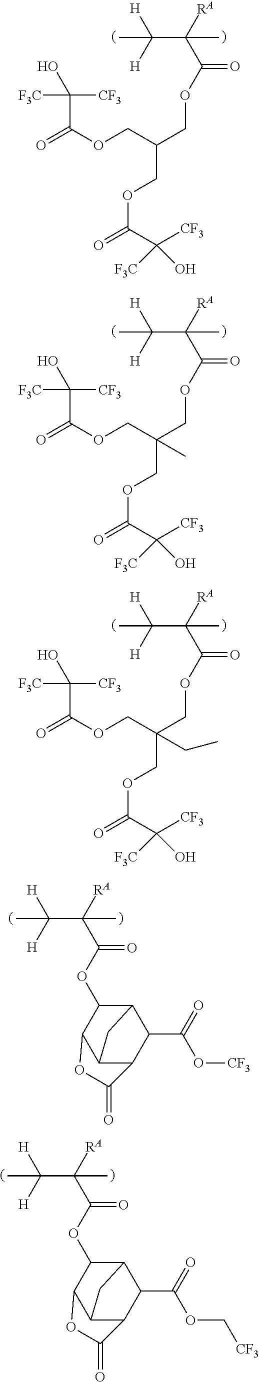

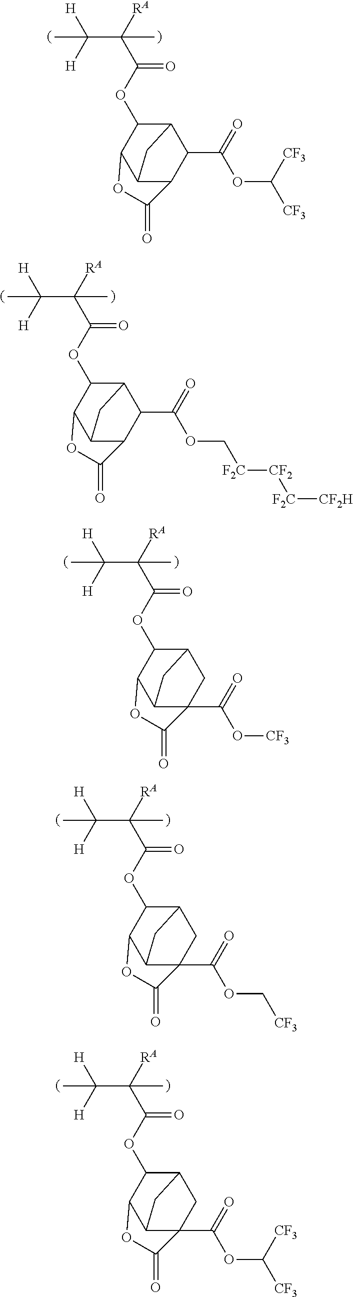

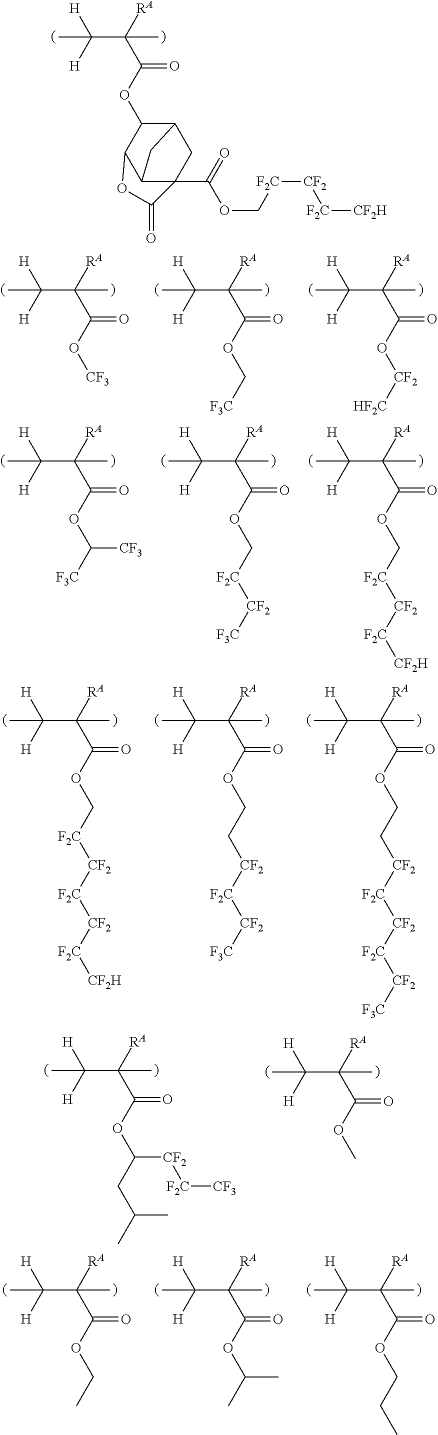

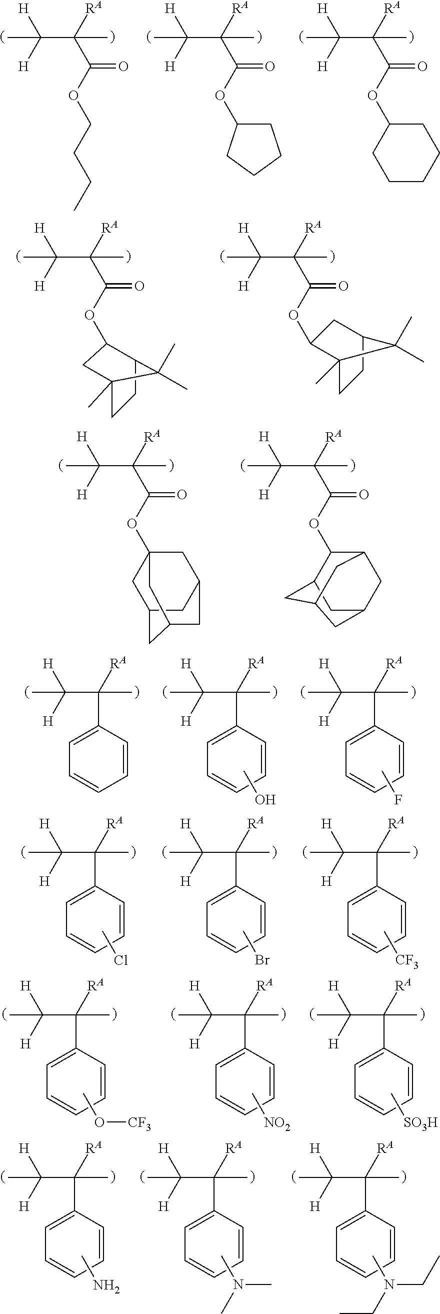

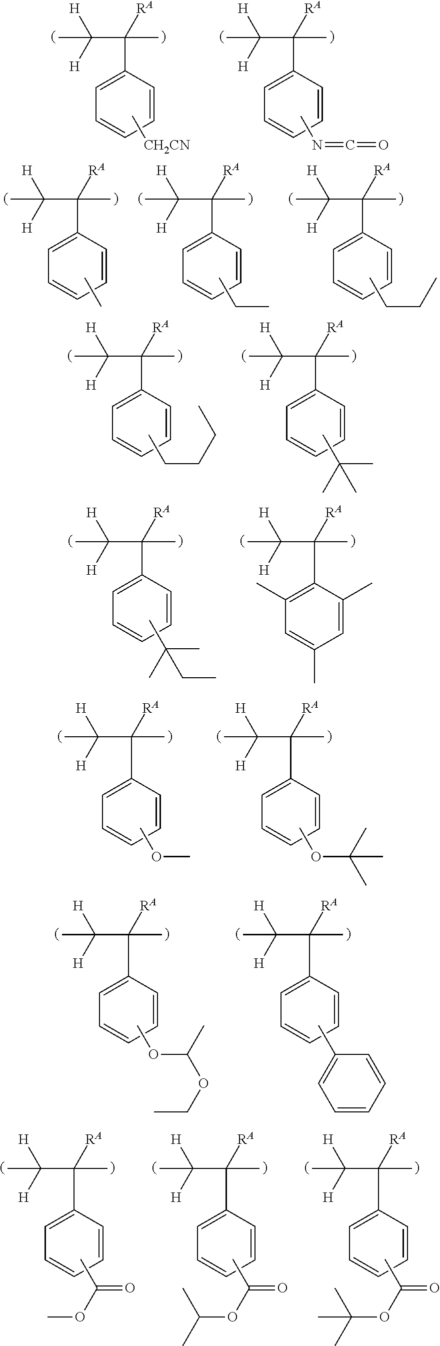

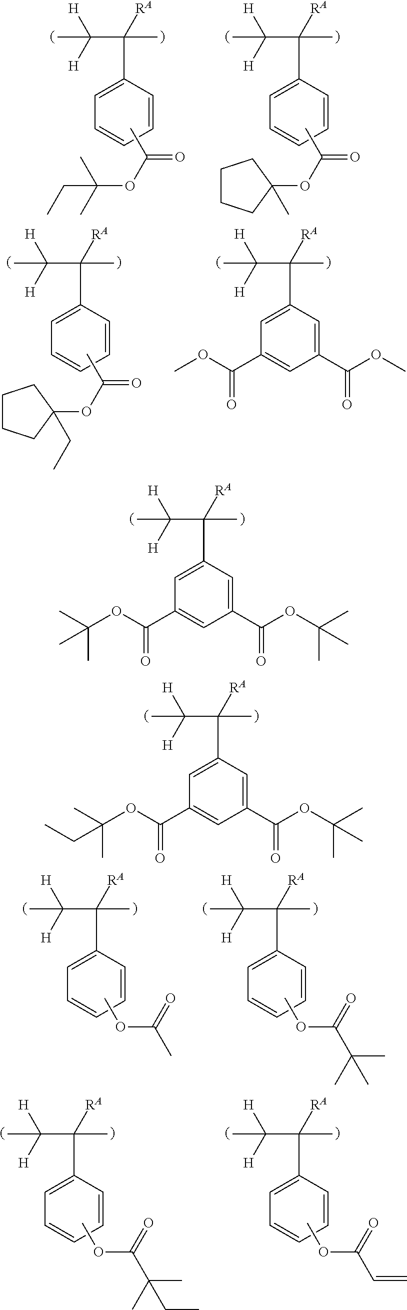

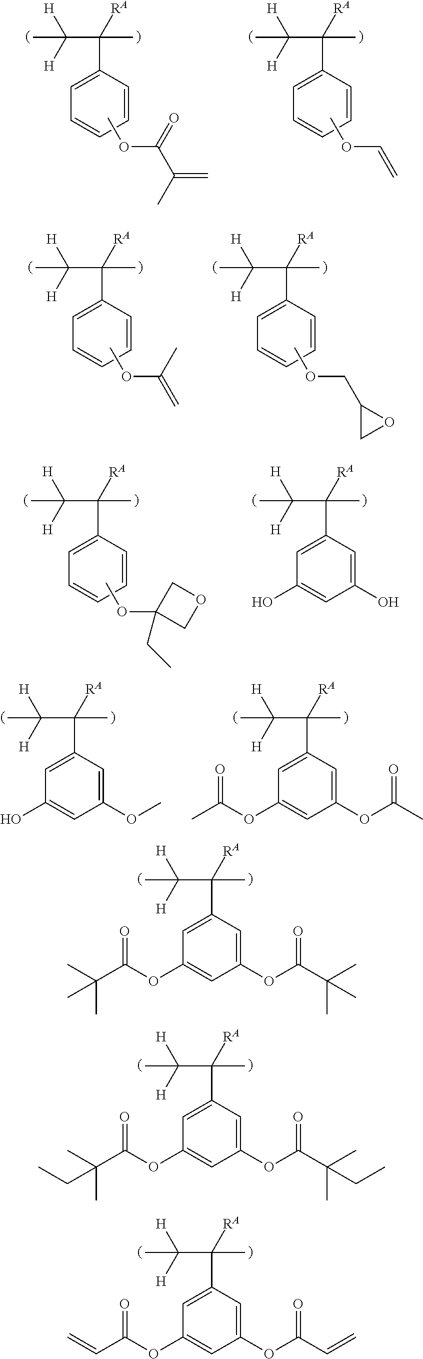

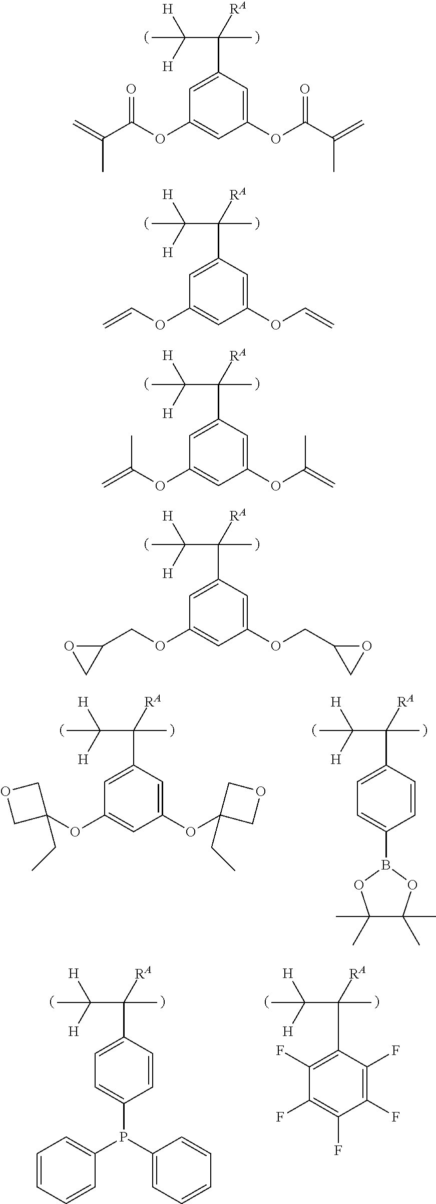

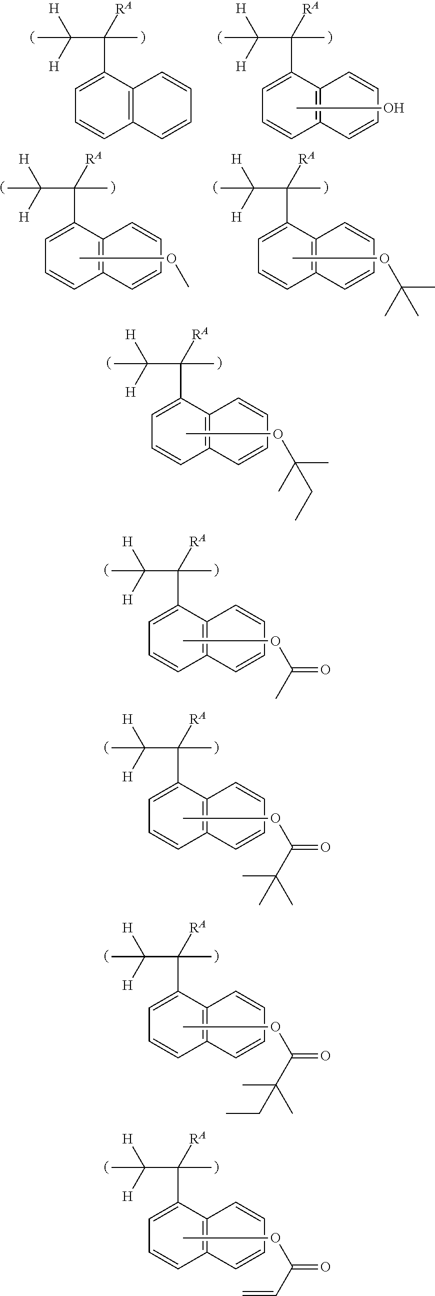

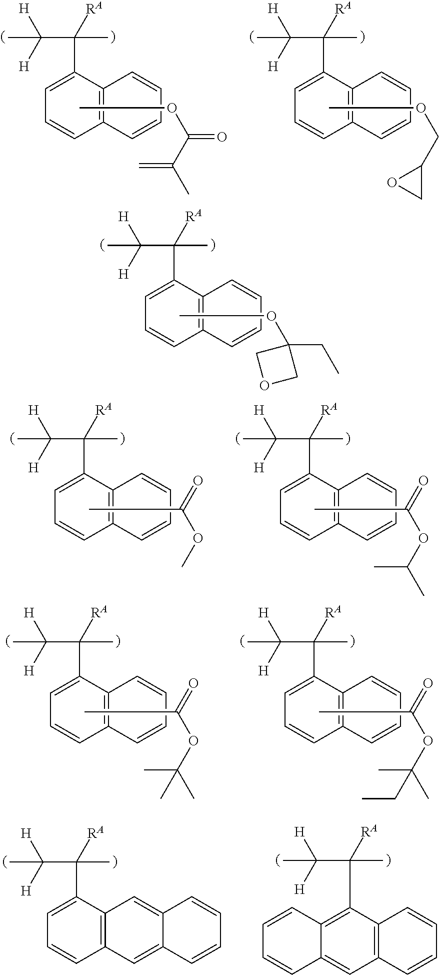

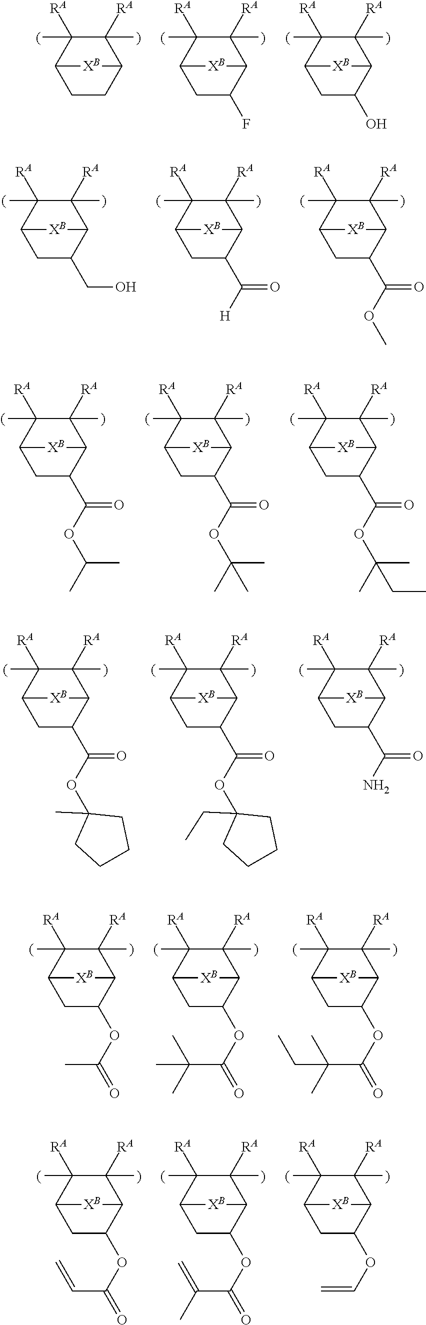

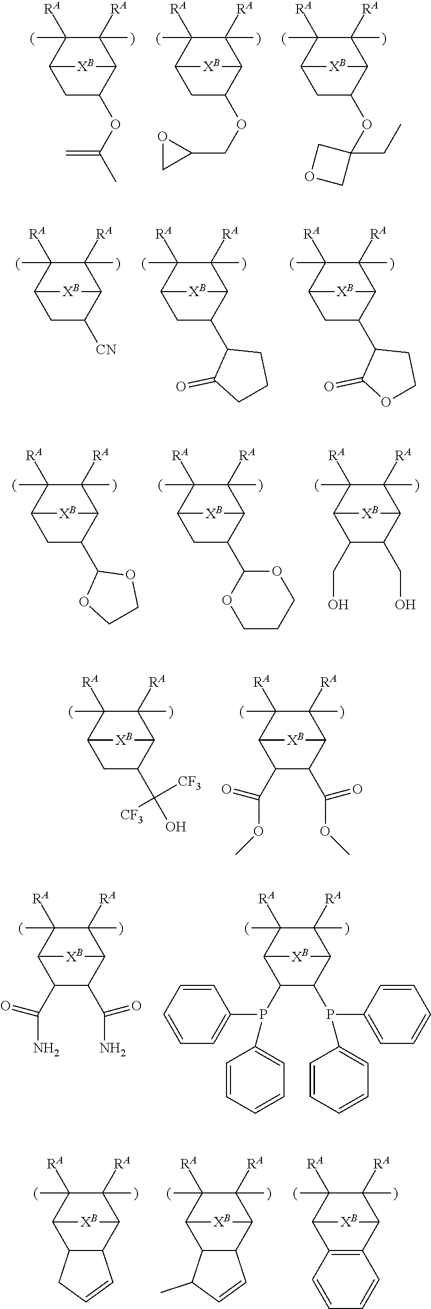

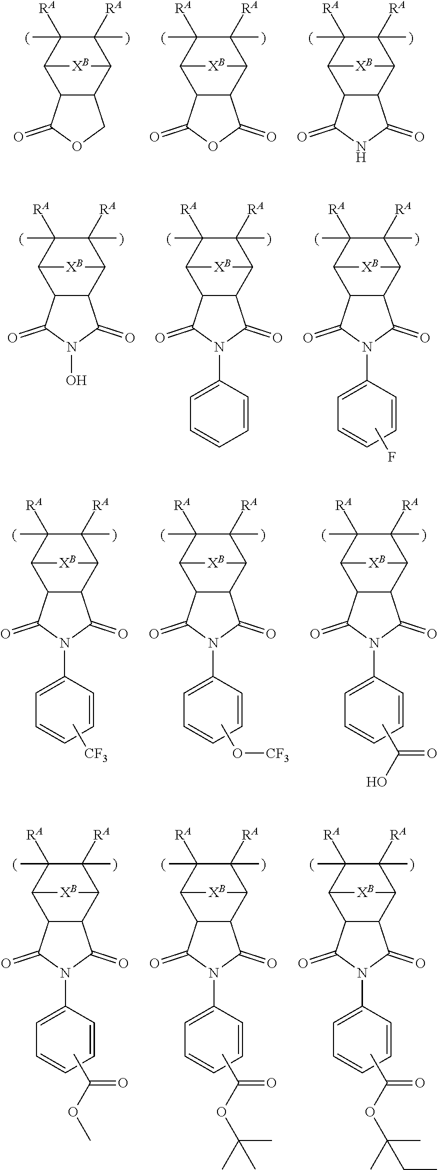

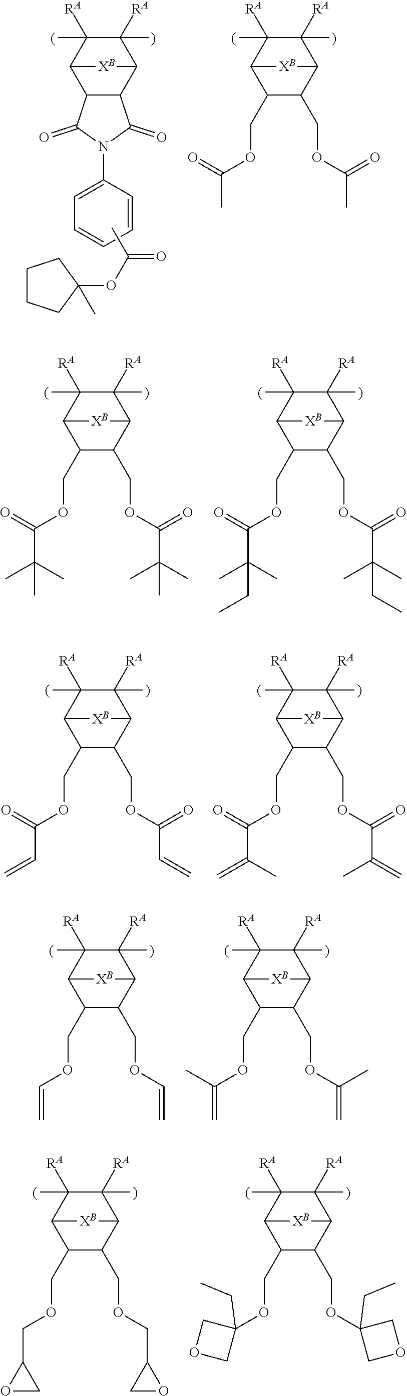

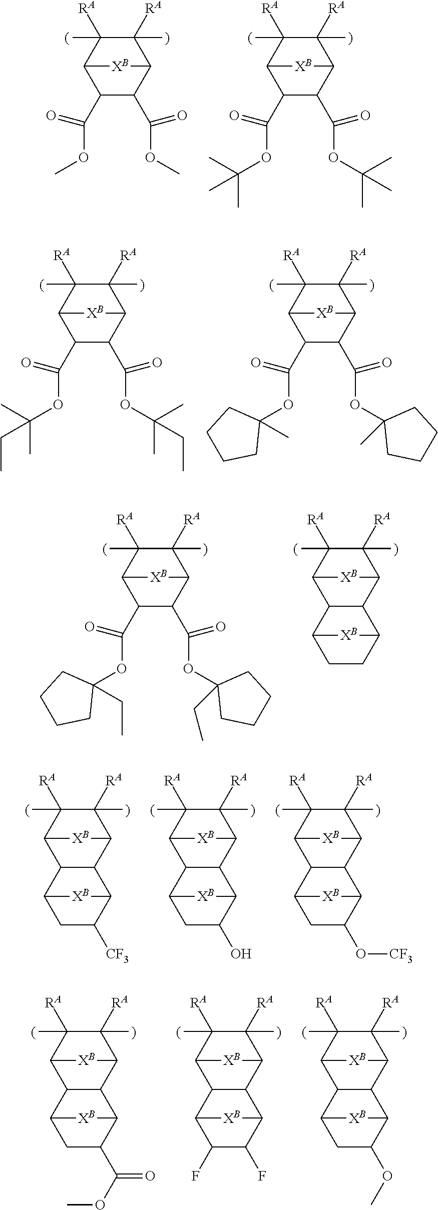

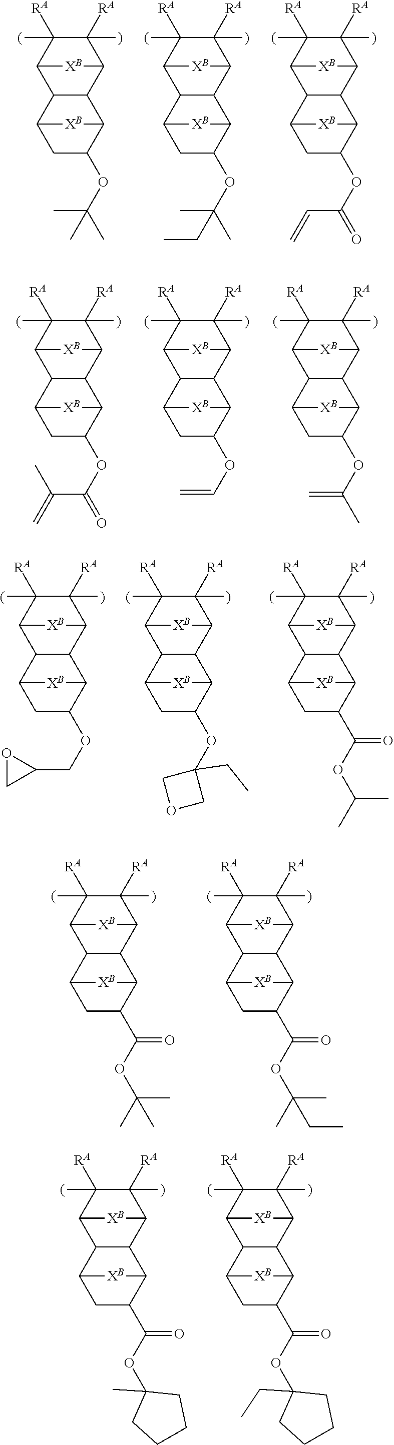

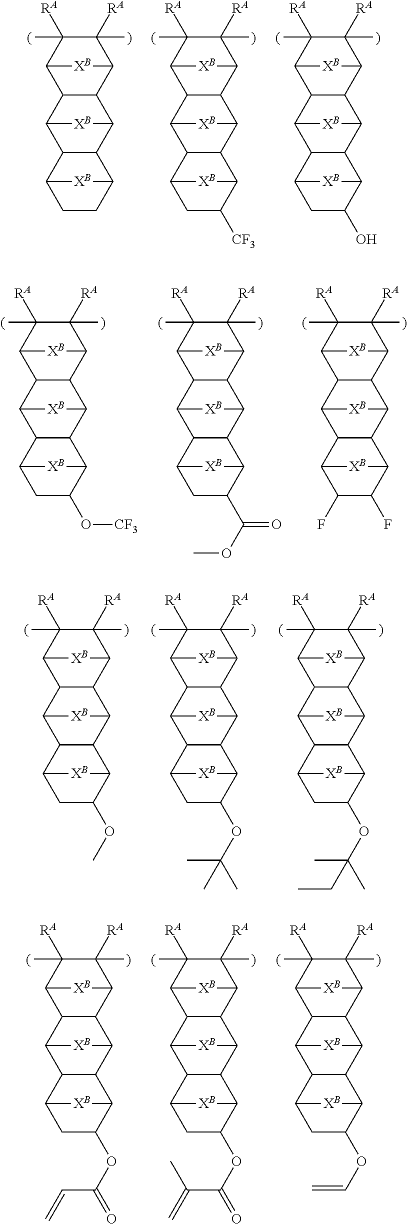

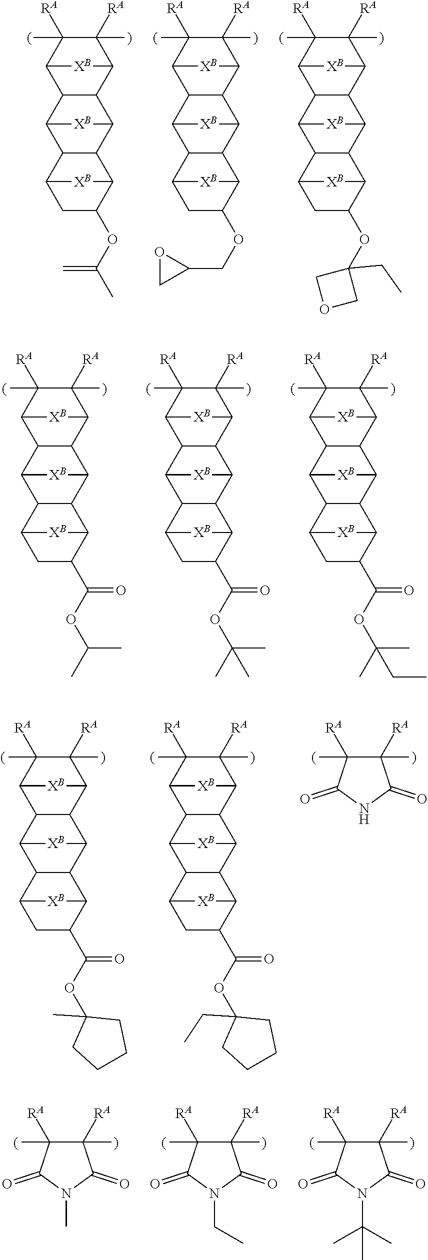

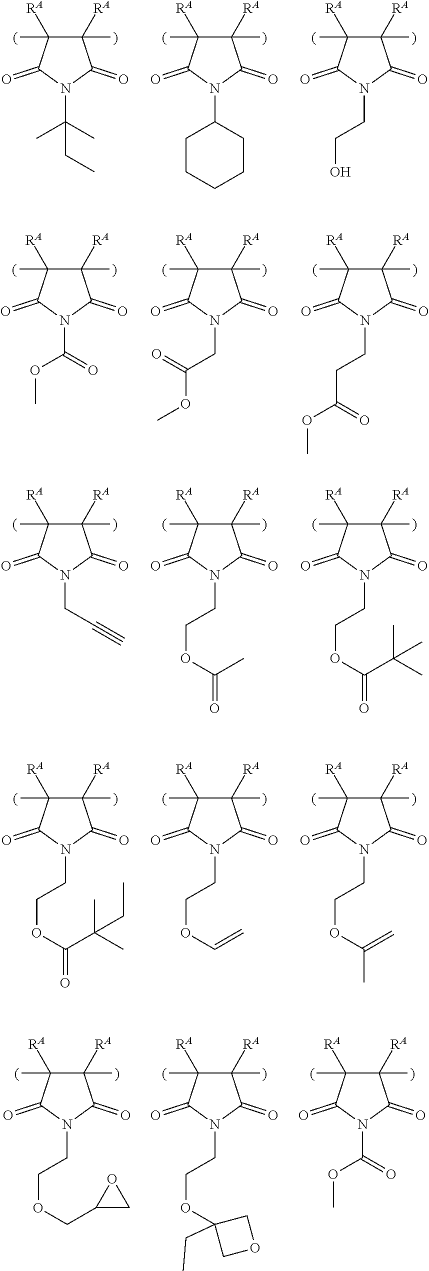

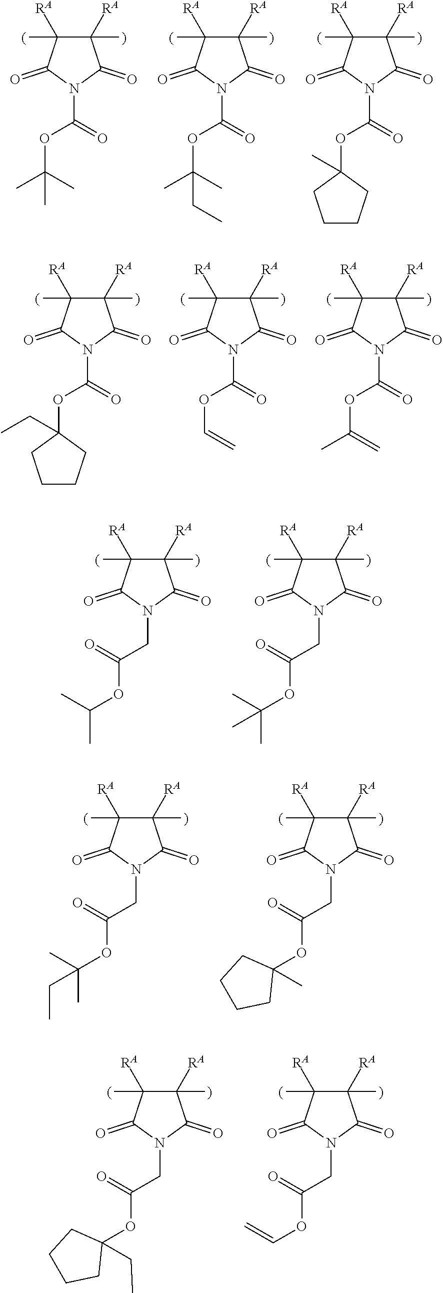

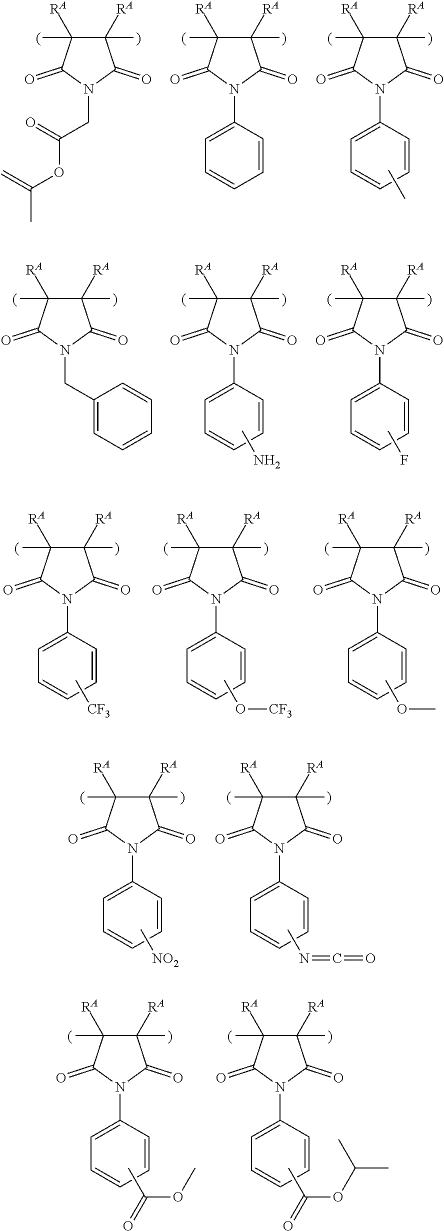

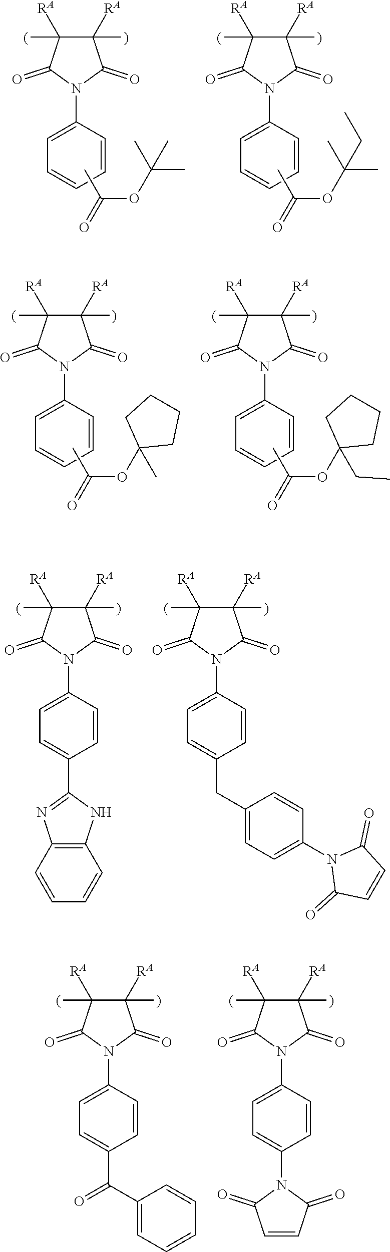

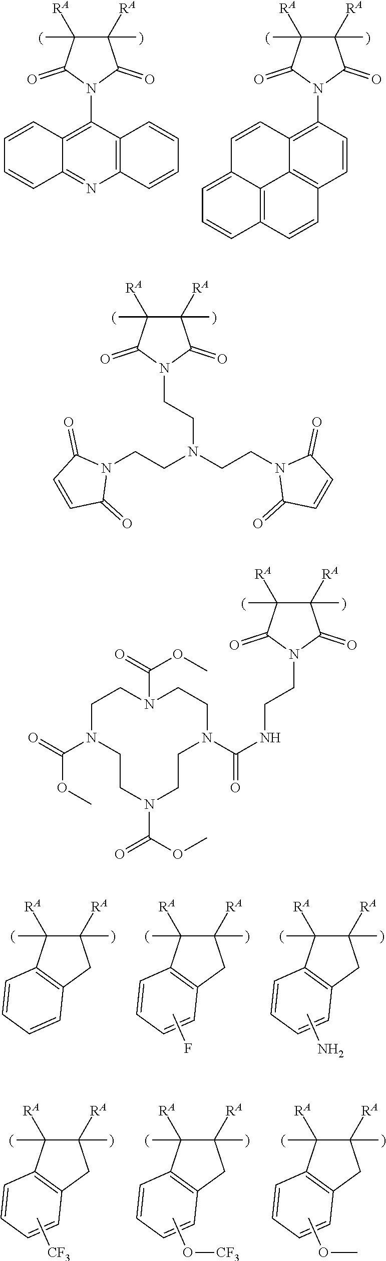

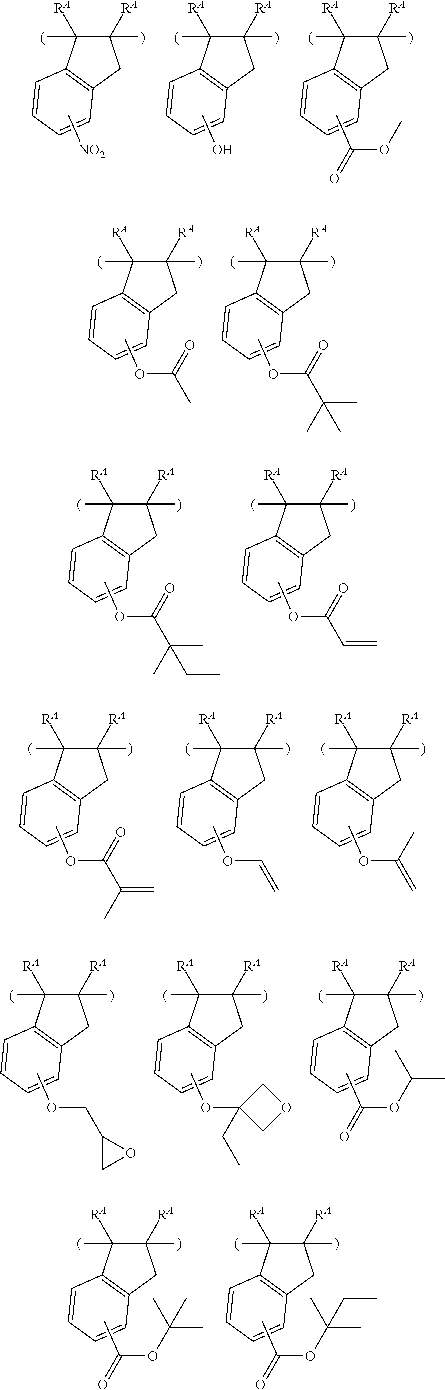

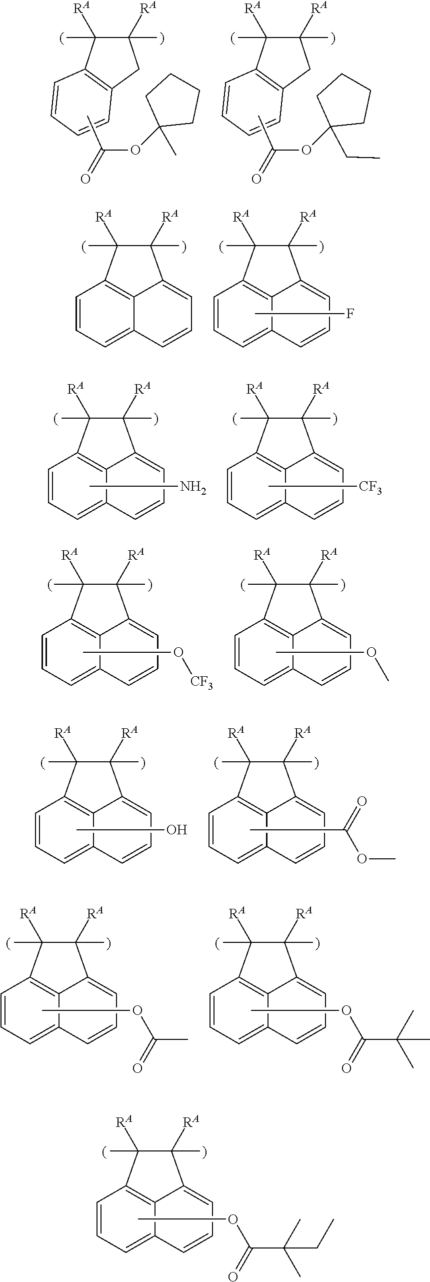

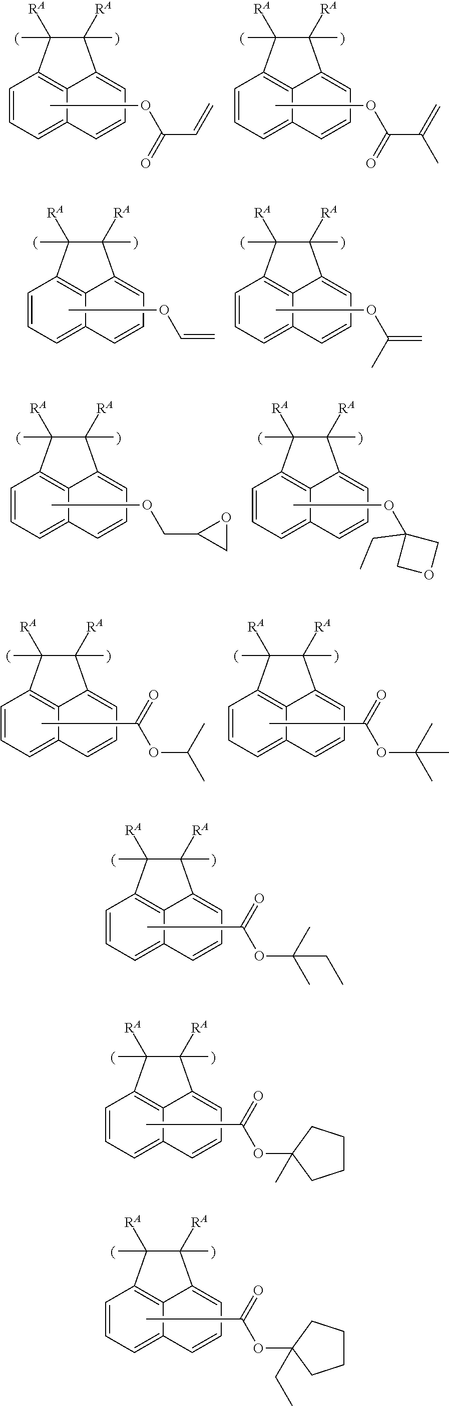

In the carboxy-group-containing polymer, the content ratio (molar ratio) of the carboxy-group-containing repeating unit to the other repeating units is preferably “carboxy-group-containing repeating unit”:“other repeating units”=10:90 to 90:10, more preferably 15:85 to 85:15, and further preferably 20:80 to 80:20.

The carboxy-group-containing polymer preferably has a weight-average molecular weight (Mw) of 1,000 to 500,000, more preferably 3,000 to 100,000. Note that, in the present invention, Mw is a value measured in terms of polystyrene by gel permeation chromatography (GPC) using tetrahydrofuran (THF) as a solvent.

Furthermore, when the carboxy-group-containing polymer has a narrow molecular weight distribution (Mw/Mn), the amount of polymers present having a lower molecular weight or a higher molecular weight than the Mw is small, and therefore, foreign substances are hardly found on the pattern after exposure, and the pattern shape is hardly degraded. Accordingly, as pattern rule is miniaturized, the influence of Mw and Mw/Mn is likely to be greater, and therefore, to obtain a resist composition that can be used suitably for a fine pattern size, the carboxy-group-containing polymer preferably has a narrow dispersity Mw/Mn of 1.0 to 2.0.

Examples of methods for synthesizing the carboxy-group-containing polymer include a method of polymerizing a monomer to give a repeating unit described above by heating in an organic solvent in the presence of a radical polymerization initiator.

Specific examples of the organic solvent to be used in the polymerization reaction include toluene, benzene, THE, diethyl ether, dioxane, cyclohexane, cyclopentane, methyl ethyl ketone (MEK), propylene glycol monomethyl ether acetate (PGMEA), and γ-butyrolactone (GBL). Specific examples of the polymerization initiator include 2,2′-azobisisobutyronitrile (AIBN), 2,2′-azobis(2,4-dimethylvaleronitrile), dimethyl-2,2′-azobis(2-methylpropionate), 1,1′-azobis(1-acetoxy-1-phenylethane), benzoyl peroxide, and lauroyl peroxide. The amount of the polymerization initiator to be added is preferably 0.01 to 25 mol % of the total amount of the monomers to be polymerized. The reaction temperature is preferably 50 to 150° C., more preferably 60 to 100° C. The reaction time is preferably 2 to 24 hours, and from the viewpoint of production efficiency, more preferably 2 to 12 hours.

The polymerization initiator may be added to the solution of the monomer and supplied to the reaction vessel, or a solution of the initiator may be prepared separately from the solution of the monomer, and each may be supplied to the reaction vessel independently. There is a possibility that the polymerization reaction may progress due to radicals generated from the initiator during waiting time and an ultra-high molecular weight polymer may be generated, and therefore, from the viewpoint of quality control, it is preferable to prepare each of the monomer solution and the initiator solution independently and add the solutions dropwise. An acid-labile group introduced into the monomer may be used as it is, or may be protected or partially protected after polymerization. Furthermore, to adjust the molecular weight, a known chain transfer agent, such as dodecyl mercaptan and 2-mercaptoethanol may also be used. In this case, the amount of the chain transfer agent to be added is preferably 0.01 to 20 mol % of the total amount of the monomers to be polymerized.

Note that the amount of each monomer in the monomer solution can be, for example, set appropriately to achieve the preferable content ratios of the above-described repeating units.

In a resist composition manufactured by the inventive method for manufacturing a resist composition, the hypervalent iodine compound and the carboxy-group-containing polymer are preferably contained in such a manner that the content ratio of the hypervalent iodine compound to the carboxy-group-containing repeating unit in the polymer is 10:90 to 90:10, more preferably 20:80 to 80:20, and further preferably 30:70 to 70:30 in molar ratio. One kind of the hypervalent iodine compound may be used, or two or more kinds thereof may be used in combination. One kind of the carboxy-group-containing polymer may be used, or two or more kinds thereof having different composition ratios, Mw, and/or Mw/Mn may be used in combination.

### [Solvent]

A resist composition manufactured by the inventive method for manufacturing a resist composition contains a solvent. The solvent used in the step (i) of the inventive manufacturing method is not particularly limited as long as the solvent dissolves the hypervalent iodine compound, the carboxy-group-containing polymer, and other components described later and allows film formation. As such a solvent, organic solvents are preferable, and specific examples thereof include: ketones, such as cyclohexanone, methyl-2-n-pentyl ketone, and methyl isoamyl ketone; alcohols, such as 3-methoxybutanol, 3-methyl-3-methoxybutanol, 1-methoxy-2-propanol, 1-ethoxy-2-propanol, diacetone alcohol, 4-methyl-2-pentanol, and methyl 2-hydroxyisobutyrate; ethers, such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters, such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; carboxylic acids, such as formic acid, acetic acid, and propionic acid; lactones, such as γ-butyrolactone; and mixed solvents thereof.

In the resist composition manufactured by the inventive method for manufacturing a resist composition, the amount of the solvent contained is preferably such an amount that the concentration of the solid contents in the resist composition is 0.1 to 20 mass %, more preferably 0.1 to 15 mass %, and further preferably 0.1 to 10 mass. Note that, in the present invention, solid contents is a general term for the components other than the solvent out of all the components of the resist composition. One kind of the solvent may be used, or two or more kinds thereof may be used in mixture.

### [Other Components]

In the inventive manufacturing method, in addition to the carboxy-group-containing polymer, the hypervalent iodine compound, and the solvent, other components other than these may be added to the container. Examples of the other components include a surfactant, a crosslinking agent, and a radical scavenger. Note that the other components may be added to the container in the step (i), or may be added in a step other than the step (i) and not in the step (i).

### [Surfactant]

As the surfactant, a fluorine-based and/or silicone-based surfactant is preferable. Specific examples of such a surfactant include surfactants disclosed in paragraph of US2008/0248425A1. Furthermore, it is also possible to use a surfactant disclosed in paragraph of US2008/0248425A1, other than the fluorine-based and/or silicone-based surfactants.

When a resist composition manufactured by the inventive method for manufacturing a resist composition contains the surfactant, the contained amount is preferably 0.0001 to 2 mass % of all the solid contents. One kind of the surfactant may be used, or two or more kinds thereof may be used in combination.

### [Radical Scavenger]

Specific examples of the radical scavenger include hindered phenols, quinones, hindered amines, and thiol compounds.

Specifically, specific examples of the hindered phenols include dibutylhydroxytoluene (BHT) and 2,2′-methylenebis(4-methyl-6-tert-butylphenol).

Specific examples of the quinones include 4-methoxyphenol (methoquinone) and hydroquinone.

Specific examples of the hindered amines include 2,2,6,6-tetramethylpiperidine and 2,2,6,6-tetramethylpiperidine-N-oxy radical.

Specific examples of the thiol compounds include dodecanethiol and hexadecanethiol.

When a resist composition manufactured by the inventive method for manufacturing a resist composition contains the radical scavenger, the contained amount is preferably 0.01 to 10 mass % of all the solid contents. One kind of the radical scavenger may be used, or two or more kinds thereof may be used in combination.

### [Crosslinking Agent]

Specific examples of the crosslinking agent include compounds having a carbon-carbon unsaturated bond as a functional group, such as a vinyl group, a (meth)acrylate group, an allyl group, an alkynyl group, and an aromatic ring.

Specifically, specific examples of compounds having a vinyl group include chain alkenes, branched alkenes, and cyclic alkenes, each optionally having a substituent.

Specific examples of compounds having a (meth)acrylate group include acrylic acid, methacrylic acid, acrylic acid ester, and methacrylic acid ester, each optionally having a substituent.

Specific examples of compounds having an allyl group include allyl alcohol, allyl ether, allyl ester, allyl amide, allylamine, and allyl-group-containing isocyanurates, each optionally having a substituent.

Specific examples of compounds having an alkynyl group include chain alkynes, branched alkynes, cyclic alkynes, alkynyl alcohols, alkynyl ethers, alkynyl esters, alkynyl amides, alkynyl amines, and alkynyl-group-containing isocyanurates, each optionally having a substituent.

Specific examples of compounds having an aromatic ring include arenes, heteroarenes, styrene, stilbene, phenylacetylene, acenaphthylene, and chalcone, each optionally having a substituent.

The crosslinking agent may have only one of the functional groups, or may have a plurality of the groups. The number of the functional groups contained in the crosslinking agent is preferably 1 or more and 10 or less, more preferably 2 or more and 8 or less.

When a resist composition manufactured by the inventive method for manufacturing a resist composition contains the crosslinking agent, the contained amount is preferably 0.01 to 50 mass % of all the solid contents. One kind of the crosslinking agent may be used, or two or more kinds thereof may be used in combination.

[Step (ii)]

In the inventive method for manufacturing a resist composition, after the step (i), performed is a step (ii) of collecting part of the fundamental resist composition prepared in the step (i), forming a resist film on a test substrate by using the collected fundamental resist composition, and evaluating a film physical property of the resist film.

The film physical property to be evaluated in the step (ii) is not particularly limited, but is preferably at least one of sensitivity, film thickness, contact angle (e. g. contact angle with water), complex refractive index, transmittance, and refractive index, more preferably at least one of sensitivity and film thickness, and particularly preferably sensitivity.

The method for evaluating the film physical property in the step (ii) is not particularly limited, and a known method for evaluating a film physical property can be applied. When sensitivity is evaluated as the film physical property, the kind of high-energy beam for irradiation is not particularly limited. Examples include ultraviolet ray, deep ultraviolet ray, EB, EUV, X-ray, soft X-ray, excimer laser beam, γ-ray, and synchrotron radiation, and among these, KrF excimer laser beam, EB, and EUV are preferable, and EB and EUV are particularly preferable.

As the test substrate used in the step (ii), the same substrate as that used in the patterning process described later can be used.

[Step (iii)]

In the inventive method for manufacturing a resist composition, after the step (ii), performed is a step (iii) of adding an additional material to the fundamental resist composition and mixing together to achieve a target film physical property based on an evaluation result of the step (ii). The kind of the additional material is not particularly limited, but is preferably at least one of a carboxy-group-containing polymer, a hypervalent iodine compound, a solvent, a surfactant, a crosslinking agent, and a radical scavenger, more preferably at least one of a carboxy-group-containing polymer, a hypervalent iodine compound, and a solvent, and particularly preferably a hypervalent iodine compound.

To adjust the sensitivity, for example, a hypervalent iodine compound may be added.

To adjust the film thickness, for example, a solvent may be added.

To adjust the contact angle, for example, a carboxy-group-containing polymer may be added.

To adjust the complex refractive index, for example, a hypervalent iodine compound may be added.

To adjust the transmittance, for example, a hypervalent iodine compound may be added.

To adjust the refractive index, for example, a carboxy-group-containing polymer may be added.

In the inventive method for manufacturing a resist composition, after the step (i), the step (ii) is performed, and then the step (iii) is performed. In this case, each of the steps (i) to (iii) may be performed continuously from the previous step, or may be performed after a period of time after the previous step. The addition of the additional material in the step (iii) may be performed on the fundamental resist composition contained in the container used in the step (i), or may be performed in the fundamental resist composition that has been transferred to a different container or the like. In the step (iii), when the additional material is added, the fundamental resist composition may be being stirred, or may not be being stirred, but is preferably being stirred. In the inventive manufacturing method, the inside of the container may be continuously stirred from the beginning of the step (i) to the completion of the step (iii). Furthermore, the inside of the container may also be stirred after the completion of the step (iii) (after the addition of the additional material has been completed).

The amount (when multiple kinds of materials are added, the total amount) of the additional material added in the step (iii) is preferably 0.001 to 100 mass %, more preferably 0.001 to 50 mass %, and further preferably 0.001 to 30 mass % of the total amount of the hypervalent iodine compound, the carboxy-group-containing polymer, and the solvent placed in the container in the step (i).

In a case where the film physical property measured in the step (ii) is already the desired film physical property, stirring alone may be performed without adding an additional material in the step (iii). In this case, the step (iii) can be said to be a step of making a decision not to add an additional material to the fundamental resist composition to achieve the target film physical property based on the evaluation result of the step (ii).

The reason why the present invention can solve the above-described problems is not necessarily clear, but the present inventors consider as follows.

It can be assumed that when the hypervalent iodine compound used in the present invention is mixed with a carboxylic acid compound, a reaction by which a ligand on an iodine atom is exchanged with a carboxylic acid compound occurs as an equilibrium reaction. In this event, if the original ligand can be removed by some method, a hypervalent iodine compound having a new ligand is generated. For example, when 1-acetoxy-1,2-benziodoxol-3-(1H)-one, which is a hypervalent iodine compound that can be acquired comparatively easily, and a carboxylic acid compound having a high molecular weight are mixed together and the generated acetic acid, having a low boiling point, is removed, ligand exchange is completed. Here, in a case where the carboxylic acid compound is a carboxy-group-containing polymer, a high-molecular-weight hypervalent iodine compound in which the carboxy-group-containing polymer and the hypervalent iodine compound are bonded to each other is obtained.

The high-molecular-weight hypervalent iodine compound is generated at the time of film formation. This is because such a high-molecular-weight hypervalent iodine compound is insoluble in many organic solvents, and therefore, a solution cannot be prepared even if the compound is synthesized beforehand. This is conjectured to be because the hypervalent iodine compound, originally having low solvent solubility due to high polarization, contains the carboxy-group-containing polymer, being a high-molecular-weight polymer, as a ligand, and thus, solubility is even more degraded. Accordingly, in this step, it is desirable to remove the original low-molecular-weight carboxylic acid component at the time of film formation and in the subsequent baking process, thus completing the ligand exchange reaction and also forming a resist film.

The resist film thus formed on the substrate changes in polarity by the hypervalent iodine compound, being the main component of the resist film, being decomposed by light, and a pattern is formed by a development process. Incidentally, by selecting the developer appropriately, a positive or negative pattern can be formed.

From the above-described conjecture, the resist composition manufactured by the present invention can be said to be a non-chemically amplified resist composition. Furthermore, as described above, the resist film is formed by reacting the hypervalent iodine compound and the carboxy-group-containing polymer in the resist composition at the time of film formation, and therefore, the film physical properties (e. g. sensitivity, film thickness, contact angle, complex refractive index, transmittance, or refractive index) vary depending on the mixing ratio of the hypervalent iodine compound and the carboxy-group-containing polymer in the resist composition. That is, by adjusting the proportion of each component in the resist composition by using the method of the present invention for manufacturing a resist, it is possible to manufacture a non-chemically amplified resist composition whose quality is controlled to be constant.

As a non-chemically amplified resist composition with which a fine pattern can be formed, reported is a metal resist that mainly contains a compound of tin, which is a metal having a high absorbance of EUV light in the same manner as iodine atoms (e. g. Patent Document 1). However, as described above, such a metal resist is usually constituted from only a single functional component and a solvent, and therefore, the quality of the resist cannot be adjusted. On the other hand, according to the inventive method for manufacturing a non-chemically amplified resist composition, the manufactured non-chemically amplified resist composition is constituted from multiple components, and therefore, by adjusting the proportions of the components, a non-chemically amplified resist composition whose quality is controlled to be constant can be manufactured. From these points, the method of the present invention for manufacturing a non-chemically amplified resist can be said to be more advantageous than conventional methods for manufacturing a non-chemically amplified resist.

JP2023-167368A proposes a non-chemically amplified resist composition containing a hypervalent iodine compound, but there is no mention whatsoever regarding the possibility that a film physical property may be adjusted by adjusting the proportion of each component in the non-chemically amplified resist composition, or regarding specific methods for manufacturing a non-chemically amplified resist composition. Accordingly, it is considered that a method for manufacturing a non-chemically amplified resist composition whose quality is controlled to be constant like that of the present invention cannot be conceived from this Patent Document. That is, it can be said that the present invention provides a clearly novel method for manufacturing a non-chemically amplified resist composition.

### [Patterning Process]

A non-chemically amplified resist composition manufactured by the inventive manufacturing method described above can be used, for example, for patterning in the manufacturing process of a semiconductor device or the like. When a non-chemically amplified resist composition manufactured by the inventive manufacturing method is used for manufacturing various integrated circuits, a known lithography technique can be applied.

That is, the present invention provides a patterning process including the steps of:
forming a resist film by using a resist composition manufactured by the above-described manufacturing method on a substrate or on an underlayer film of a substrate on which the underlayer film has been laminated;
exposing the resist film by using a high-energy beam; and
developing the exposed resist film by using a developer.

In the following, each step of the inventive patterning process will be described in detail.

Firstly, a resist composition manufactured by the inventive manufacturing method is applied onto a substrate for manufacturing an integrated circuit, on an underlayer film of a substrate (Si, SiO₂, SiN, SiON, TiN, WSi, BPSG, SOG, organic antireflective film, etc.) on which the underlayer film has been laminated, on a substrate for manufacturing a mask circuit, or on an underlayer film of a substrate (Cr, Cro, CrON, MoSi₂, SiO₂, etc.) on which the underlayer film has been laminated by an appropriate coating process such as spin coating, roll coating, flow coating, dip coating, spray coating, or doctor coating. The composition is preferably applied so that the thickness of the coating film is 0.01 to 2 μm. The resultant is prebaked on a hot plate preferably at 60 to 200° C. for 10 seconds to 30 minutes, more preferably 80 to 180° C. for 30 seconds to 20 minutes. Thus, a resist film is formed. Note that an underlayer film means a film formed between the substrate and the resist film in a multilayer resist process. The underlayer film is not particularly limited, and a conventionally known film can be used. Furthermore, before application, the resist composition is preferably filtered through a filter as necessary. The pore size of the filter is preferably 0.1 μm or less, more preferably 0.05 μm or less, and further preferably 0.03 μm or less. Furthermore, the filter is preferably made of polytetrafluoroethylene, polyethylene, or nylon.

Subsequently, the resist film is exposed by using a high-energy beam. Examples of the high-energy beam include ultraviolet ray, deep ultraviolet ray, EB (electron beam), EUV (extreme ultraviolet ray), X-ray, soft X-ray, excimer laser beam, γ-ray, and synchrotron radiation. When ultraviolet ray, deep ultraviolet ray, EUV, X-ray, soft X-ray, excimer laser beam, γ-ray, synchrotron radiation, or the like is employed as the high-energy beam, the irradiation is performed directly or while using a mask for forming a target pattern at an exposure dose of preferably about 1 to 300 mJ/cm², more preferably about 10 to 200 mJ/cm². When an EB is employed as the high-energy beam, the writing is performed directly or while using a mask for forming a target pattern at an exposure dose of preferably about 0.1 to 2000 μC/cm², more preferably about 0.5 to 1500 μC/cm². Note that the resist composition manufactured by the inventive manufacturing method is particularly suitable for fine patterning with an EB or EUV, among the high-energy beams.

After the exposure, PEB is performed as necessary. In this event, the PEB is preferably performed after the exposure on a hot plate or in an oven under the conditions of 30 to 150° C. for 10 seconds to 30 minutes, more preferably 60 to 120° C. for 30 seconds to 20 minutes.

After the exposure or after the PEB, development is performed by using a developer to perform patterning. Examples of the developer used in this event include: aqueous alkaline solutions, such as an aqueous solution of tetramethylammonium hydroxide; and organic solvents, such as 2-octanone, 2-nonanone, 2-heptanone, 3-heptanone, 4-heptanone, 2-hexanone, 3-hexanone, diisobutyl ketone, methylcyclohexanone, acetophenone, methylacetophenone, isopropyl alcohol, isoamyl alcohol, n-butanol, n-pentanol, cyclohexanol, propyl acetate, butyl acetate, isobutyl acetate, pentyl acetate, butenyl acetate, isopentyl acetate, cyclohexyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, phenylmethyl acetate, phenylethyl acetate, benzyl formate, phenylethyl formate, methyl 3-phenylpropionate, benzyl propionate, 2-phenylethyl acetate, 2-propanol, 3-methoxybutanol, 3-methyl-3-methoxybutanol, 1-methoxy-2-propanol, 1-ethoxy-2-propanol, diacetone alcohol and 4-methyl-2-pentanol. One kind of these developers may be used, or two or more kinds thereof may be used in mixture.

After the development, rinsing is performed as necessary. The rinsing liquid is preferably a solvent that is miscible with the developer but does not dissolve the resist film. As such a solvent, it is preferable to use an alcohol having 3 to 10 carbon atoms, an ether compound having 8 to 12 carbon atoms, an alkane, alkene, alkyne, and aromatic solvent, each having 6 to 12 carbon atoms.

The rinsing can reduce resist pattern collapse and defect formation. Meanwhile, the rinsing is not necessarily essential, and the amount of the solvent used can be reduced by not performing the rinsing.

Furthermore, an etching treatment of the substrate may be carried out while using the pattern formed by the patterning process as a mask. That is, the substrate (or the underlayer film and the substrate) may be processed while using the pattern formed by the patterning process as a mask, thereby forming a pattern in the substrate.

The method for processing the substrate (or the underlayer film and the substrate) is not particularly limited, but preferable is a method in which a pattern is formed in a substrate by subjecting the substrate (or the underlayer film and the substrate) to dry etching while using the pattern formed in the above-described step as a mask.

The dry etching may be one-stage etching or multi-stage etching. In a case where the etching is etching including multiple stages, the etching at the respective stages maybe the same treatment or different treatments.

For etching, any of known methods can be used, and various conditions and the like are appropriately determined according to the type of a substrate, usage, etc. Etching can be carried out, for example, in accordance with The International Society for Optical Engineering (Proc. of SPIE), Vol. 6924, 692420 (2008), JP2009-267112A, and the like. In addition, etching can also be carried out in accordance with a method disclosed in “Chapter 4 Etching” in “Semiconductor Process Text Book, 4th Ed., published in 2007, publisher: SEMI Japan”.

The resist composition manufactured by the inventive manufacturing method and various materials (e. g. carboxy-group-containing polymer, hypervalent iodine compound, solvent, surfactant, crosslinking agent, radical scavenger, developer, and rinsing liquid) used in the present invention preferably do not contain impurities such as metal. The amount of impurities contained in these materials is preferably 1 ppm by mass or less, more preferably 10 ppb by mass or less, further preferably 100 ppt by mass or less, particularly preferably 10 ppt by mass or less, and most preferably 1 ppt by mass or less. Here, examples of metal impurities include Na, K, Ca, Fe, Cu, Mn, Mg, Al, Li, Cr, Ni, Sn, Ag, As, Au, Ba, Cd, Co, Mo, Zr, Pb, Ti, V, W, and Zn.

Examples of methods for removing an impurity, such as metal, from the resist composition and various materials include filtration using a filter. The filter pore size is preferably 0.20 μm or less, more preferably 0.05 μm or less, and further preferably 0.01 μm or less.

As the material of the filter, preferable are: fluororesins, such as polytetrafluoroethylene (PTFE) and perfluoroalkoxy alkane (PFA); polyolefin resins, such as polypropylene and polyethylene; polyamide resins, such as nylon 6 and nylon 66, and polyimide resins. As the filter, one cleaned with an organic solvent beforehand may be used. In the filter filtration process, multiple filters or multiple kinds of filters may be connected and used in series or in parallel. When multiple kinds of filters are used, filters having different pore sizes and/or materials may be used in combination. Furthermore, the various materials may be filtered multiple times, and the process of filtering multiple times may be a cycle filtration process.

Besides filter filtration, the removal of impurities by using an adsorbent may be performed, and filter filtration and an adsorbent may be employed in combination. As the adsorbent, a known adsorbent can be used, and for example, it is possible to use an inorganic adsorbent, such as silica gel or zeolite, or an organic adsorbent such as activated carbon. Examples of metal adsorbents include those disclosed in JP2016-206500A.

Furthermore, examples of methods for reducing the impurities, such as metal, contained in the resist composition and the various materials include methods such as: selecting a raw material having a low metal content as the raw materials that constitute the resist composition and the various materials; performing filter filtration on the raw materials that constitute the resist composition and the various materials; or lining or coating the inside of the apparatus with fluororesin or the like and performing distillation under conditions where contamination has been suppressed as much as possible. Preferable conditions in the filter filtration to be performed on the raw materials that constitute the resist composition and the various materials are the same as the above-described conditions.

The various materials may be diluted with the solvent used in the resist composition and used.

### Examples

Hereinafter, the present invention will be specifically described with reference to Synthesis Examples, Examples, and Comparative Example. However, the present invention is not limited to the following Examples.

### [1] Resist Composition

The constitutions of the resist compositions (resists 1 and 2) used in the Examples are shown in Table 1.

TABLE 1

| | | | Carboxy-group- | | | |
|---|---|---|---|---|---|---|
| | | Hypervalent | containing | Other | | |
| Resist | | iodine compound | polymer | components | Solvent 1 | Solvent 2 |
| composition | | (parts by mass) | (parts by mass) | (parts by mass) | (parts by mass) | (parts by mass) |
| Resist 1 | Standard | I-1: lot A | P-1: lot B | — | HBM: lot C | AA: lot D |
| | lot | (5) | (15) | | (800) | (200) |
| | Previous | I-1: lot E | P-1: lot B | — | HBM: lot F | AA: lot G |
| | lot | (5) | (15) | | (800) | (200) |
| | New lot | I-1: lot H | P-1: lot I | — | HBM: lot J | AA: lot K |
| | | (5) | (15) | | (800) | (200) |
| Resist 2 | Standard | I-2: lot L | P-2: lot M | T-1: lot N | PGMEA: lot O | PA: lot P |
| | lot | (5) | (9) | (1) | (800) | (200) |
| | Previous | I-2: lot L | P-2: lot Q | T-1: lot R | PGMEA: lot S | PA: lot T |
| | lot | (5) | (9) | (1) | (800) | (200) |
| | New lot | I-2: lot U | P-2: lot V | T-1: lot W | PGMEA: lot X | PA: lot Y |
| | | (5) | (9) | (1) | (800) | (200) |

Here, the <standard lot> is the lot manufactured 11 months before the new lot was prepared, and the <previous lot> is the lot manufactured 2 months before the new lot was prepared.

### [2] Hypervalent Iodine Compound

The structures of the hypervalent iodine compounds (I-1 to I-2) used in the Examples are shown below.

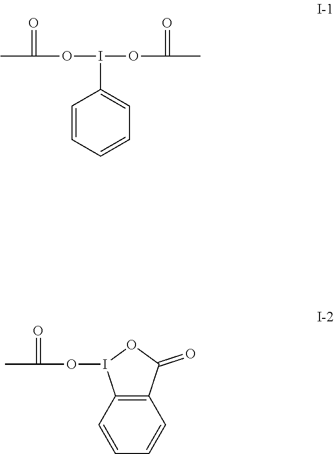

### [3] Carboxy-Group-Containing Polymer

The structures of the carboxy-group-containing polymers (P-1 to P-2) used in the Examples are shown below.

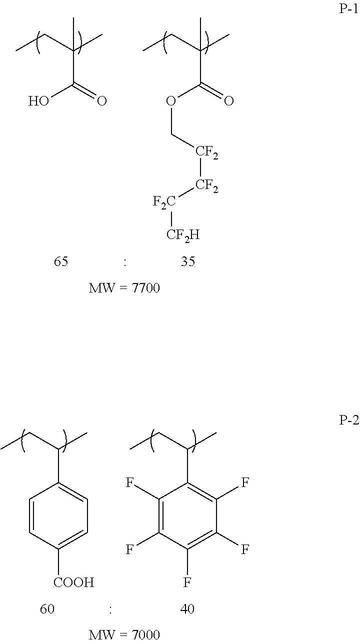

### [4] Solvent

The solvents used in the Examples and Comparative Example are shown below.
HBM: methyl 2-hydroxyisobutyrate
PGMEA: propylene glycol monomethyl ether acetate
PA: propionic acid
AA: acetic acid

### [5] Other Components

The structure of the radical scavenger T-1 used in the Examples is shown below.

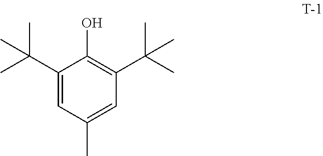 [SMILES: Cc1cc(C(C)(C)C)c(O)c(C(C)(C)C)c1]

### [6] Method for Manufacturing Resist Composition

### EXAMPLE

Step (i): in the amounts shown in Table 1, the carboxy-group-containing polymer, the hypervalent iodine compound, the solvent, and the other component were placed in a stirred tank (volume: 100 L), and the contents of the stirred tank were stirred with stirring blades for 2 hours under conditions of 23° C. and 150 rpm. Thus, fundamental resist compositions were obtained.

Step (ii): 0.1 kg of the fundamental resist composition after performing the step (i) was collected as the <new lot>. Using this <new lot>, the physical properties shown below were evaluated.

### —Evaluation of Film Physical Property—

Each of a fraction of the collected 0.1 kg and the <standard lot> and the <previous lot> of the two standard resist compositions prepared for reference was respectively applied onto a Si substrate by spin-coating, prebaked (PAB) by using a hot plate at 130° C. for 60 seconds. Thus, 40-nm thick resist films were prepared. Regarding the obtained resist film, sensitivity and film thickness were evaluated in the following manner.

### Sensitivity

The wafer having the formed resist film was exposed by using an electron beam exposure apparatus (manufactured by ELIONIX INC., ELS-F125, acceleration voltage: 125 keV) to have a 1:1 line-and-space pattern having a line width of 20 nm, and then the wafer was baked (PEB) at a temperature of 90° C. for 60 seconds. After that, development was performed for 30 seconds with a butyl acetate developer, and spin-drying was performed. The LS pattern for sensitivity evaluation thus obtained was observed using CD-SEM (CG-4000) manufactured by Hitachi High-Technologies Corporation, and the optimum exposure dose Eop (μC/cm²) at which the LS pattern having a space width of 20 nm and a pitch of 40 nm was obtained was determined as sensitivity.

### Film Thickness

The resist film was measured in multiple points with a film thickness meter (VM-3210 manufactured by SCREEN Semiconductor Solutions Co., Ltd.), and the average value was determined as the film thickness.

The obtained results are shown in Table 2.

TABLE 2

| | | Coating film |
|---|---|---|
| | | thickness at |
| | Sensitivity | 1500 rpm |
| Resist composition | (μC/cm²) | (nm) |

| | | | |
|---|---|---|---|
| Resist 1 | Standard lot | 1000 | 40 |
| | Previous lot | 1002 | 40 |
| | New lot | 976 | 35 |
| Resist 2 | Standard lot | 800 | 40 |
| | Previous lot | 803 | 41 |
| | New lot | 815 | 46 |

As a result, it was observed that the <resist 1/new lot> had a coating film thickness 5 nm thinner for the same rotational rate and a sensitivity higher by 2% or more compared to the <resist 1/standard lot> and the <resist 1/previous lot>. Meanwhile, it was observed that the <resist 2/new lot> had a coating film thickness thicker by 5 nm or more for the same rotational rate and a sensitivity lower by 18 or more compared to the <resist 2/standard lot> and the <resist 2/previous lot>.

Step (iii): to the fundamental resist composition in the stirred tank, the additional materials shown in Table 3 were added. The inside of the container was continuously stirred with stirring blades from the beginning of the step (i) to the end of the step (iii). In addition, after the step (iii) was completed (after all the additional materials were added), stirring of the fundamental resist composition was continued for 4 hours.

TABLE 3

| | Additional | Additional | Additional |
|---|---|---|---|
| Resist | material 1 | material 2 | material 3 |
| composition | (parts by mass) | (parts by mass) | (parts by mass) |
| Resist 1 | I-1: lot H | — | — |
| | (0.1) | | |
| Resist 2 | P-2: lot U | PGMEA: lot X | PA: lot Y |
| | (0.1) | (12) | (3) |

From the fundamental resist composition thus finely adjusted, 0.1 kg was collected, and the new lot resists 1 and 2 were evaluated again according to the methods shown above. The results are shown in Table 4.

TABLE 4

| | | Coating film |
|---|---|---|
| | | thickness at |
| | Sensitivity | 1500 rpm |
| Resist composition | (μC/cm²) | (nm) |

| | | | |
|---|---|---|---|
| Resist 1 | Standard lot | 1000 | 40 |
| | Previous lot | 1002 | 40 |
| | New lot | 1001 | 41 |
| Resist 2 | Standard lot | 800 | 40 |
| | Previous lot | 803 | 41 |
| | New lot | 801 | 40 |

As a result, the finely adjusted new lot resists 1 and 2 had almost equivalent values to the <standard lot> and the <previous lot> regarding both film thickness and sensitivity.

The constitution of the resist composition (Comparative Example 1) used in the Comparative Example is shown in Table 5.

TABLE 5

| | | Resist raw | | |
|---|---|---|---|---|
| | | material | Solvent 1 | Solvent 2 |
| | | (parts by | (parts by | (parts by |
| Resist composition | | mass) | mass) | mass) |
| Comparative | Standard | R-1: lot 1 | PGMEA: lot 2 | AA: lot 3 |
| Example 1 | lot | (10) | (800) | (200) |
| | Previous | R-1: lot 1 | PGMEA: lot 4 | AA: lot 5 |
| | lot | (10) | (800) | (200) |
| | New lot | R-1: lot 6 | PGMEA: lot 7 | AA: lot 8 |
| | | (10) | (800) | (200) |

In Table 5, R-1 (tin compound) used in the Comparative Example 1 was synthesized according to Angewandte Chemie, International Edition (2017), 56 (34), 10140-10144. The structure of R-1 is as follows.

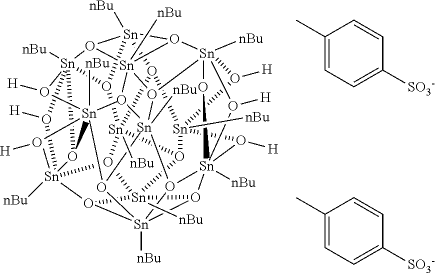

### Comparative Example

Step (i): in the amounts shown in Table 5, the resist raw material and the solvent were placed in a stirred tank (volume: 100 L), and the contents of the stirred tank were stirred with stirring blades for 2 hours under conditions of 23° C. and 150 rpm. Thus, a resist composition was obtained.

Step (ii): 0.1 kg of the resist composition after performing the step (i) was collected as the <new lot>. Using this <new lot>, the physical properties were evaluated in the same manner as in the Examples.

The obtained results are shown in Table 6.

TABLE 6

| | | Coating film |
|---|---|---|
| | | thickness at |
| | Sensitivity | 1500 rpm |
| Resist composition | (μC/cm²) | (nm) |

| | | | |
|---|---|---|---|
| Comparative | Standard lot | 999 | 40 |
| Example 1 | Previous lot | 870 | 31 |
| | New lot | 1120 | 53 |

As a result, the values of both the film thickness and the sensitivity varied greatly between the <new lot>, the <standard lot>, and the <previous lot> regarding the non-chemically amplified resist composition prepared in the Comparative Example.

From the above results, it was found that, by employing the inventive manufacturing method, it is possible to obtain a non-chemically amplified resist composition whose quality is controlled to be constant.

The present description includes the following embodiments.

[1]: A method for manufacturing a non-chemically amplified resist composition, comprising, in the following order, the steps of:
(i) placing a carboxy-group-containing polymer, a hypervalent iodine compound, and a solvent in a container and mixing together to prepare a fundamental resist composition;
(ii) collecting part of the fundamental resist composition, forming a resist film on a test substrate by using the collected fundamental resist composition, and evaluating a film physical property of the resist film; and
(iii) adding an additional material to the fundamental resist composition and mixing together to achieve a target film physical property based on an evaluation result of the step (ii).

[2]: The method for manufacturing a non-chemically amplified resist composition according to [1], wherein the film physical property is sensitivity.

[3]: The method for manufacturing a non-chemically amplified resist composition according to [1] or [2], wherein the additional material is at least one of the carboxy-group-containing polymer, the hypervalent iodine compound, and the solvent.

[4]: The method for manufacturing a non-chemically amplified resist composition according to any one of [1] to [3], wherein the hypervalent iodine compound includes at least one of compounds represented by the following general formulae (1) and (2),

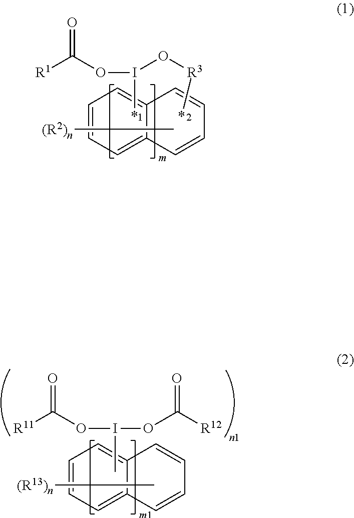

wherein “m” and “ml” each represent an integer of 0 to 2;
“n” represents an integer of 0 to 4 when “m” is 0, an integer of 0 to 6 when “m” is 1, and an integer of 0 to 8 when “m” is 2;
when “m1” is 0, “n1” represents an integer of 1 to 3, “n2” represents an integer of 0 to 5, and 1≤(n1+n2)≤6 is satisfied;
when “ml” is 1, “n1” represents an integer of 1 to 3, “n2” represents an integer of 0 to 7, and 1≤(n1+n2)≤8 is satisfied;
when “ml” is 2, “n1” represents an integer of 1 to 3, “n2” represents an integer of 0 to 9, and 1≤(n1+n2)≤10 is satisfied;
R¹ represents a halogen atom or a hydrocarbyl group having 1 to 10 carbon atoms and optionally containing a heteroatom;
R² represents a halogen atom or a hydrocarbyl group having 1 to 40 carbon atoms and optionally containing a heteroatom, when “n” is 2 to 8, the R²s being identical to or different from each other, and the R²s optionally being bonded to each other to form a ring together with the carbon atoms of the aromatic ring bonded thereto;
R³ represents a carbonyl group or a hydrocarbylene group having 1 to 10 carbon atoms and optionally containing a heteroatom;
“*1” and “*2” each represent an attachment point to a carbon atom of the aromatic ring in the formula, provided that “*1” and “*2” are bonded to adjacent carbon atoms of the aromatic ring;
R¹¹ and R¹² each independently represent a halogen atom or a hydrocarbyl group having 1 to 10 carbon atoms and optionally containing a heteroatom, the R¹¹ and the R¹² optionally being bonded to each other to form a ring together with the carbon atoms bonded thereto and the atoms between the carbon atoms; and
R¹³ represents a halogen atom or a hydrocarbyl group having 1 to 40 carbon atoms and optionally containing a heteroatom, when “n2” is 2 to 9, the R¹³s being identical to or different from each other, and the R¹³s optionally being bonded to each other to form a ring together with the carbon atoms of the aromatic ring bonded thereto.

[5]: The method for manufacturing a non-chemically amplified resist composition according to any one of [1] to [4], wherein the carboxy-group-containing polymer includes a repeating unit represented by the following general formula (3),

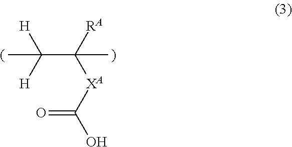

wherein R^{A} represents a hydrogen atom, a halogen atom, a methyl group, or a trifluoromethyl group; and
X^{A} represents a single bond, a phenylene group, a naphthylene group, or *—C(═O)—O—X^{A1}—, X^{A1} represents a saturated hydrocarbylene group having 1 to 10 carbon atoms, a phenylene group, or a naphthylene group, the saturated hydrocarbylene group optionally containing at least one selected from a hydroxy group, an ether bond, an ester bond, and a lactone ring, and “*” represents an attachment point to the carbon atom of the main chain.

[6]: A patterning process comprising the steps of:
forming a resist film by using a resist composition manufactured by the manufacturing method according to any one of [1] to [5] on a substrate or on an underlayer film of a substrate on which the underlayer film has been laminated;
exposing the resist film by using a high-energy beam; and
developing the exposed resist film by using a developer.

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1. A method for manufacturing a non-chemically amplified resist composition, comprising, in the following order, the steps of:
(i) placing a carboxy-group-containing polymer, a hypervalent iodine compound, and a solvent in a container and mixing together to prepare a fundamental resist composition;
(ii) collecting part of the fundamental resist composition, forming a resist film on a test substrate by using the collected fundamental resist composition, and evaluating a film physical property of the resist film; and
(iii) adding an additional material to the fundamental resist composition and mixing together to achieve a target film physical property based on an evaluation result of the step (ii).

2. The method for manufacturing a non-chemically amplified resist composition according to claim 1, wherein the film physical property is sensitivity.

3. The method for manufacturing a non-chemically amplified resist composition according to claim 1, wherein the additional material is at least one of the carboxy-group-containing polymer, the hypervalent iodine compound, and the solvent.

4. The method for manufacturing a non-chemically amplified resist composition according to claim 2, wherein the additional material is at least one of the carboxy-group-containing polymer, the hypervalent iodine compound, and the solvent.

5. The method for manufacturing a non-chemically amplified resist composition according to claim 1, wherein the hypervalent iodine compound includes at least one of compounds represented by the following general formulae (1) and (2), 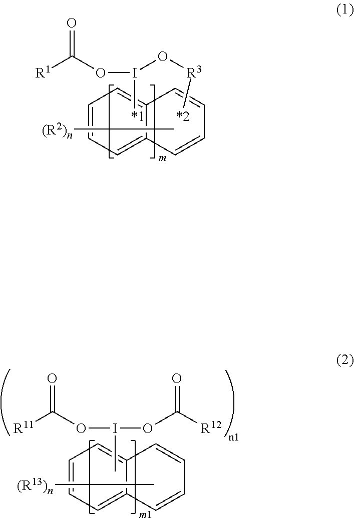
wherein “m” and “m1” each represent an integer of 0 to 2;
“n” represents an integer of 0 to 4 when “m” is 0, an integer of 0 to 6 when “m” is 1, and an integer of 0 to 8 when “m” is 2;
when “m1” is 0, “n1” represents an integer of 1 to 3, “n2” represents an integer of 0 to 5, and 1≤(n1+n2)≤6 is satisfied;
when “m1” is 1, “n1” represents an integer of 1 to 3, “n2” represents an integer of 0 to 7, and 1≤(n1+n2)≤8 is satisfied;
when “m1” is 2, “n1” represents an integer of 1 to 3, “n2” represents an integer of 0 to 9, and 1≤ (n1+n2)≤10 is satisfied;
R¹ represents a halogen atom or a hydrocarbyl group having 1 to 10 carbon atoms and optionally containing a heteroatom;
R² represents a halogen atom or a hydrocarbyl group having 1 to 40 carbon atoms and optionally containing a heteroatom, when “n” is 2 to 8, the R²s being identical to or different from each other, and the R²s optionally being bonded to each other to form a ring together with the carbon atoms of the aromatic ring bonded thereto;
R³ represents a carbonyl group or a hydrocarbylene group having 1 to 10 carbon atoms and optionally containing a heteroatom;
“*1” and “*2” each represent an attachment point to a carbon atom of the aromatic ring in the formula, provided that “*1” and “*2” are bonded to adjacent carbon atoms of the aromatic ring;
R¹¹ and R¹² each independently represent a halogen atom or a hydrocarbyl group having 1 to 10 carbon atoms and optionally containing a heteroatom, the R¹¹ and the R¹² optionally being bonded to each other to form a ring together with the carbon atoms bonded thereto and the atoms between the carbon atoms; and
R¹³ represents a halogen atom or a hydrocarbyl group having 1 to 40 carbon atoms and optionally containing a heteroatom, when “n2” is 2 to 9, the R¹³s being identical to or different from each other, and the R¹³s optionally being bonded to each other to form a ring together with the carbon atoms of the aromatic ring bonded thereto.

6. The method for manufacturing a non-chemically amplified resist composition according to claim 2, wherein the hypervalent iodine compound includes at least one of compounds represented by the following general formulae (1) and (2), 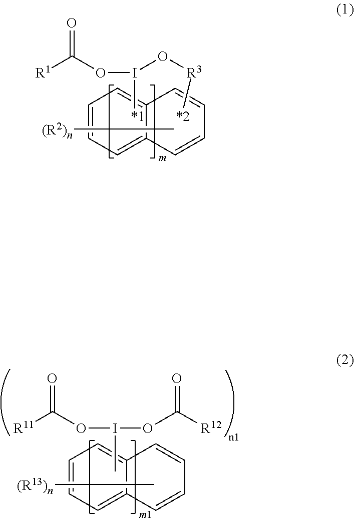
wherein “m” and “m1” each represent an integer of 0 to 2;
“n” represents an integer of 0 to 4 when “m” is 0, an integer of 0 to 6 when “m” is 1, and an integer of 0 to 8 when “m” is 2;
when “m1” is 0, “n1” represents an integer of 1 to 3, “n2” represents an integer of 0 to 5, and 1≤(n1+n2)≤6 is satisfied;
when “m1” is 1, “n1” represents an integer of 1 to 3, “n2” represents an integer of 0 to 7, and 1≤(n1+n2)≤8 is satisfied;
when “m1” is 2, “n1” represents an integer of 1 to 3, “n2” represents an integer of 0 to 9, and 1≤(n1+n2)≤10 is satisfied;
R¹ represents a halogen atom or a hydrocarbyl group having 1 to 10 carbon atoms and optionally containing a heteroatom;
R² represents a halogen atom or a hydrocarbyl group having 1 to 40 carbon atoms and optionally containing a heteroatom, when “n” is 2 to 8, the R²s being identical to or different from each other, and the R²s optionally being bonded to each other to form a ring together with the carbon atoms of the aromatic ring bonded thereto;
R³ represents a carbonyl group or a hydrocarbylene group having 1 to 10 carbon atoms and optionally containing a heteroatom;
“*1” and “*2” each represent an attachment point to a carbon atom of the aromatic ring in the formula, provided that “*1” and “*2” are bonded to adjacent carbon atoms of the aromatic ring;
R¹¹ and R¹² each independently represent a halogen atom or a hydrocarbyl group having 1 to 10 carbon atoms and optionally containing a heteroatom, the R¹¹ and the R¹² optionally being bonded to each other to form a ring together with the carbon atoms bonded thereto and the atoms between the carbon atoms; and
R¹³ represents a halogen atom or a hydrocarbyl group having 1 to 40 carbon atoms and optionally containing a heteroatom, when “n2” is 2 to 9, the R¹³s being identical to or different from each other, and the R¹³s optionally being bonded to each other to form a ring together with the carbon atoms of the aromatic ring bonded thereto.

7. The method for manufacturing a non-chemically amplified resist composition according to claim 3, wherein the hypervalent iodine compound includes at least one of compounds represented by the following general formulae (1) and (2), 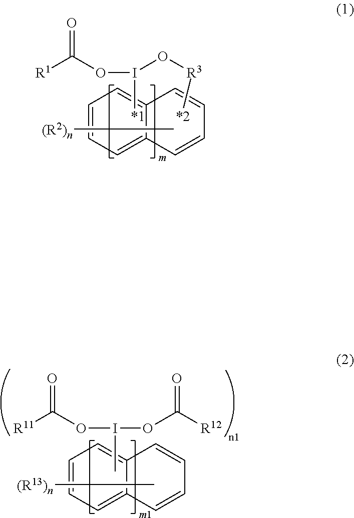
wherein “m” and “m1” each represent an integer of 0 to 2;
“n” represents an integer of 0 to 4 when “m” is 0, an integer of 0 to 6 when “m” is 1, and an integer of 0 to 8 when “m” is 2;
when “m1” is 0, “n1” represents an integer of 1 to 3, “n2” represents an integer of 0 to 5, and 1≤(n1+n2)≤6 is satisfied;
when “m1” is 1, “n1” represents an integer of 1 to 3, “n2” represents an integer of 0 to 7, and 1≤(n1+n2)≤8 is satisfied;
when “m1” is 2, “n1” represents an integer of 1 to 3, “n2” represents an integer of 0 to 9, and 1≤(n1+n2)≤10 is satisfied;
R¹ represents a halogen atom or a hydrocarbyl group having 1 to 10 carbon atoms and optionally containing a heteroatom;
R² represents a halogen atom or a hydrocarbyl group having 1 to 40 carbon atoms and optionally containing a heteroatom, when “n” is 2 to 8, the R²s being identical to or different from each other, and the R²s optionally being bonded to each other to form a ring together with the carbon atoms of the aromatic ring bonded thereto;
R³ represents a carbonyl group or a hydrocarbylene group having 1 to 10 carbon atoms and optionally containing a heteroatom;
“*1” and “*2” each represent an attachment point to a carbon atom of the aromatic ring in the formula, provided that “*1” and “*2” are bonded to adjacent carbon atoms of the aromatic ring;
R¹¹ and R¹² each independently represent a halogen atom or a hydrocarbyl group having 1 to 10 carbon atoms and optionally containing a heteroatom, the R¹¹ and the R¹² optionally being bonded to each other to form a ring together with the carbon atoms bonded thereto and the atoms between the carbon atoms; and
R¹³ represents a halogen atom or a hydrocarbyl group having 1 to 40 carbon atoms and optionally containing a heteroatom, when “n2” is 2 to 9, the R¹³s being identical to or different from each other, and the R¹³s optionally being bonded to each other to form a ring together with the carbon atoms of the aromatic ring bonded thereto.

8. The method for manufacturing a non-chemically amplified resist composition according to claim 4, wherein the hypervalent iodine compound includes at least one of compounds represented by the following general formulae (1) and (2), 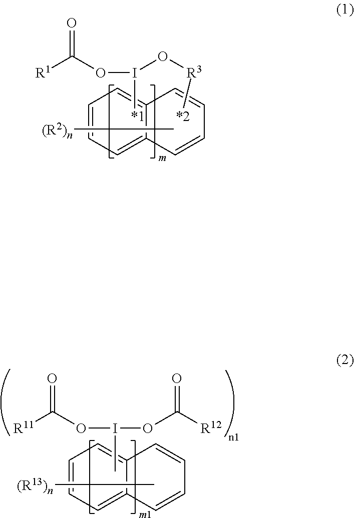
wherein “m” and “m1” each represent an integer of 0 to 2;
“n” represents an integer of 0 to 4 when “m” is 0, an integer of 0 to 6 when “m” is 1, and an integer of 0 to 8 when “m” is 2;
when “m1” is 0, “n1” represents an integer of 1 to 3, “n2” represents an integer of 0 to 5, and 1≤(n1+n2)≤6 is satisfied;
when “m1” is 1, “n” represents an integer of 1 to 3, “n2” represents an integer of 0 to 7, and 1≤(n1+n2)≤8 is satisfied;
when “m1” is 2, “n1” represents an integer of 1 to 3, “n2” represents an integer of 0 to 9, and 1≤(n1+n2)≤10 is satisfied;
R¹ represents a halogen atom or a hydrocarbyl group having 1 to 10 carbon atoms and optionally containing a heteroatom;
R² represents a halogen atom or a hydrocarbyl group having 1 to 40 carbon atoms and optionally containing a heteroatom, when “n” is 2 to 8, the R²s being identical to or different from each other, and the R²s optionally being bonded to each other to form a ring together with the carbon atoms of the aromatic ring bonded thereto;
R³ represents a carbonyl group or a hydrocarbylene group having 1 to 10 carbon atoms and optionally containing a heteroatom;
“*1” and “*2” each represent an attachment point to a carbon atom of the aromatic ring in the formula, provided that “*1” and “*2” are bonded to adjacent carbon atoms of the aromatic ring;
R¹¹ and R¹² each independently represent a halogen atom or a hydrocarbyl group having 1 to 10 carbon atoms and optionally containing a heteroatom, the R¹¹ and the R¹² optionally being bonded to each other to form a ring together with the carbon atoms bonded thereto and the atoms between the carbon atoms; and
R¹³ represents a halogen atom or a hydrocarbyl group having 1 to 40 carbon atoms and optionally containing a heteroatom, when “n2” is 2 to 9, the R¹³s being identical to or different from each other, and the R¹³s optionally being bonded to each other to form a ring together with the carbon atoms of the aromatic ring bonded thereto.

9. The method for manufacturing a non-chemically amplified resist composition according to claim 1, wherein the carboxy-group-containing polymer includes a repeating unit represented by the following general formula (3), 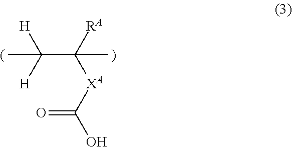
wherein R^{A} represents a hydrogen atom, a halogen atom, a methyl group, or a trifluoromethyl group; and
X^{A} represents a single bond, a phenylene group, a naphthylene group, or *—C(═O)—O—X^{A1}—, X^{A1} represents a saturated hydrocarbylene group having 1 to 10 carbon atoms, a phenylene group, or a naphthylene group, the saturated hydrocarbylene group optionally containing at least one selected from a hydroxy group, an ether bond, an ester bond, and a lactone ring, and “*” represents an attachment point to the carbon atom of the main chain.

10. The method for manufacturing a non-chemically amplified resist composition according to claim 2, wherein the carboxy-group-containing polymer includes a repeating unit represented by the following general formula (3), 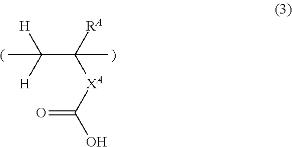
wherein R^{A} represents a hydrogen atom, a halogen atom, a methyl group, or a trifluoromethyl group; and
X^{A} represents a single bond, a phenylene group, a naphthylene group, or *—C(═O)—O—X^{A1}—, X^{A1} represents a saturated hydrocarbylene group having 1 to 10 carbon atoms, a phenylene group, or a naphthylene group, the saturated hydrocarbylene group optionally containing at least one selected from a hydroxy group, an ether bond, an ester bond, and a lactone ring, and “*” represents an attachment point to the carbon atom of the main chain.

11. The method for manufacturing a non-chemically amplified resist composition according to claim 3, wherein the carboxy-group-containing polymer includes a repeating unit represented by the following general formula (3), 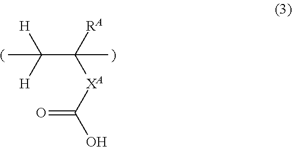
wherein R^{A} represents a hydrogen atom, a halogen atom, a methyl group, or a trifluoromethyl group; and
X^{A} represents a single bond, a phenylene group, a naphthylene group, or *—C(═O)—O—X^{A1}—, X^{A1} represents a saturated hydrocarbylene group having 1 to 10 carbon atoms, a phenylene group, or a naphthylene group, the saturated hydrocarbylene group optionally containing at least one selected from a hydroxy group, an ether bond, an ester bond, and a lactone ring, and “*” represents an attachment point to the carbon atom of the main chain.

12. The method for manufacturing a non-chemically amplified resist composition according to claim 4, wherein the carboxy-group-containing polymer includes a repeating unit represented by the following general formula (3), 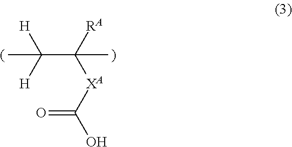
wherein R^{A} represents a hydrogen atom, a halogen atom, a methyl group, or a trifluoromethyl group; and
X^{A} represents a single bond, a phenylene group, a naphthylene group, or *—C(═O)—O—X^{A1}—, X^{A1} represents a saturated hydrocarbylene group having 1 to 10 carbon atoms, a phenylene group, or a naphthylene group, the saturated hydrocarbylene group optionally containing at least one selected from a hydroxy group, an ether bond, an ester bond, and a lactone ring, and “*” represents an attachment point to the carbon atom of the main chain.

13. A patterning process comprising the steps of:
forming a resist film by using a resist composition manufactured by the manufacturing method according to claim 1 on a substrate or on an underlayer film of a substrate on which the underlayer film has been laminated;
exposing the resist film by using a high-energy beam; and
developing the exposed resist film by using a developer.

14. A patterning process comprising the steps of:
forming a resist film by using a resist composition manufactured by the manufacturing method according to claim 2 on a substrate or on an underlayer film of a substrate on which the underlayer film has been laminated;
exposing the resist film by using a high-energy beam; and
developing the exposed resist film by using a developer.

15. A patterning process comprising the steps of:
forming a resist film by using a resist composition manufactured by the manufacturing method according to claim 3 on a substrate or on an underlayer film of a substrate on which the underlayer film has been laminated;
exposing the resist film by using a high-energy beam; and
developing the exposed resist film by using a developer.

16. A patterning process comprising the steps of:
forming a resist film by using a resist composition manufactured by the manufacturing method according to claim 4 on a substrate or on an underlayer film of a substrate on which the underlayer film has been laminated;
exposing the resist film by using a high-energy beam; and
developing the exposed resist film by using a developer.
